(19) United States
(12) Patent Application Publication
(10) Pub. No.: US 2024/0213147 A1
(43) Pub. Date: Jun. 27, 2024

(54) THREE-DIMENSIONAL MEMORY DEVICE WITH SELF-ALIGNED MEMORY BLOCK ISOLATION AND METHODS FOR FORMING THE SAME

(71) Applicant: SANDISK TECHNOLOGIES LLC, ADDISON, TX (US)

(72) Inventors: Naohiro HOSODA, Yokkaichi (JP); Tatsuya HINOUE, Yokkaichi (JP)

(21) Appl. No.: 18/355,067

(22) Filed: Jul. 19, 2023

Related U.S. Application Data
(60) Provisional application No. 63/477,271, filed on Dec. 27, 2022.

(51) Int. Cl. H01L 23/522; H01L 23/528; H10B 43/10; H10B 43/27; H10B 43/35

(52) U.S. Cl. CPC H01L 23/5226; H01L 23/5283; H10B 43/10; H10B 43/27; H10B 43/35

(57) ABSTRACT

A three-dimensional memory device may be formed by forming a vertically alternating sequence of insulating layers and sacrificial material layers over a substrate, forming memory openings, forming sacrificial memory opening fill structures in the memory openings, forming first cavities by removing a first subset of the sacrificial memory opening fill structures, forming laterally-extending cavities by performing an isotropic etch process that laterally recesses the sacrificial material layers, forming electrically conductive layers in the laterally-extending cavities, forming second cavities by removing the second subset of the sacrificial memory opening fill structures, and forming memory opening fill structures in each of the first cavities and the second cavities.

### FIELD

The present disclosure relates generally to the field of semiconductor devices, and particularly to a three-dimensional memory device containing self-aligned memory block isolation and methods of forming the same.

### BACKGROUND

A three-dimensional memory device including three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a memory device is provided, which comprises: an alternating stack of insulating layers and composite layers located over a substrate, wherein each of the composite layers comprises a respective laterally alternating sequence of electrically conductive layers and dielectric material strips, wherein the dielectric material strips laterally extend along a first horizontal direction; memory openings laterally spaced from the dielectric material strips and filled with a respective memory opening fill structure that includes a respective vertical stack of memory elements and a respective vertical semiconductor channel; and isolation openings that are adjoined to, and are laterally bounded by, a vertical stack of a respective subset of the dielectric material strips, and are filled with a respective electrically-inactive opening fill structure.

According to another aspect of the present disclosure, a memory device is provided, which comprises: an alternating stack of insulating layers and conductive layer sets located over a substrate, wherein each of the conductive layer sets comprises a respective plurality of electrically conductive layers that laterally extend along a first horizontal direction and spaced apart among one another along a second horizontal direction; finned dielectric wall structures, wherein each laterally neighboring pair of the electrically conductive layers is laterally spaced apart from each other along the second horizontal direction by a respective one of the finned dielectric wall structures, wherein each of the finned dielectric wall structures comprises a respective vertically alternating sequence of dielectric material strips and rows of insulating pillars that are interlaced along a vertical direction, and wherein each of the dielectric material strips comprises a respective row of vertically-straight and laterally-convex surface segments that are adjoined among one another and contacts a set of vertically-straight and laterally-concave surface segments of a respective one of the electrically conductive layers; and memory openings laterally spaced from the finned dielectric wall structures and filled with a respective memory opening fill structure that includes a respective vertical stack of memory elements and a respective vertical semiconductor channel.

According to yet another aspect of the present disclosure, a method of forming a three-dimensional memory device is provided. The method comprises: forming a vertically alternating sequence of insulating layers and sacrificial material layers over a substrate; forming memory openings through the vertically alternating sequence, wherein the memory openings are arranged in rows of memory openings that laterally extend along a first horizontal direction; forming sacrificial memory opening fill structures in the memory openings; forming first cavities by removing a first subset of the sacrificial memory opening fill structures without removing a second subset of the sacrificial memory opening fill structures; forming laterally-extending cavities by performing an isotropic etch process that laterally recesses the sacrificial material layers from around the first cavities selective to materials of the insulating layers and the second subset of the sacrificial memory opening fill structures; forming electrically conductive layers in the laterally-extending cavities; forming second cavities by removing the second subset of the sacrificial memory opening fill structures after forming the electrically conductive layers; and forming memory opening fill structures in each of the first cavities and the second cavities, wherein each of the memory opening fill structures comprises a respective vertical stack of memory elements and a respective vertical semiconductor channel.

### BRIEF DESCRIPTION OF THE DRAWINGS

FIG. 1 is a vertical cross-sectional view of a first exemplary structure after formation of a first alternating stack of first insulating layers and first sacrificial material layers according to a first embodiment of the present disclosure.

FIG. 2A is a vertical cross-sectional view of the first exemplary structure after formation of first-tier openings according to the first embodiment of the present disclosure.

FIG. 2B is a top-down view of the exemplary structure of FIG. 2A. The vertical plane A-A′ is a cut plane of the vertical cross-sectional view of FIG. 2A.

FIG. 2C is a vertical cross-sectional view of the first exemplary structure along the vertical plane C-C′ of FIG. 2B.

FIG. 3A is a vertical cross-sectional view of the first exemplary structure after formation of first-tier sacrificial opening fill structures according to the first embodiment of the present disclosure.

FIG. 3B is a top-down view of the exemplary structure of FIG. 3A. The vertical plane A-A′ is a cut plane of the vertical cross-sectional view of FIG. 3A.

FIG. 3C is a vertical cross-sectional view of the first exemplary structure along the vertical plane C-C′ of FIG. 3B.

FIG. 4A is a vertical cross-sectional view of the first exemplary structure after formation of a second alternating stack of second insulating layers and second sacrificial material layers, second-tier openings, and second-tier sacrificial opening fill structures according to the first embodiment of the present disclosure.

FIG. 4B is a top-down view of the exemplary structure of FIG. 4A. The vertical plane A-A′ is a cut plane of the vertical cross-sectional view of FIG. 4A.

FIG. 4C is a vertical cross-sectional view of the first exemplary structure along the vertical plane C-C′ of FIG. 4B.

FIG. 5 is a vertical cross-sectional view of the first exemplary structure after formation of an etch mask layer according to the first embodiment of the present disclosure.

FIG. 6A is a vertical cross-sectional view of the first exemplary structure after patterning the etch mask layer according to the first embodiment of the present disclosure.

FIG. 6B is a top-down view of the exemplary structure of FIG. 6A. The vertical plane A-A′ is a cut plane of the vertical cross-sectional view of FIG. 6A.

FIG. 6C is a vertical cross-sectional view of the first exemplary structure along the vertical plane C-C′ of FIG. 6B.

FIG. 7A is a vertical cross-sectional view of the first exemplary structure after removal of a first subset of the first-tier sacrificial memory opening fill structures and second-tier sacrificial memory opening fill structures according to the first embodiment of the present disclosure.

FIG. 7B is a top-down view of the exemplary structure of FIG. 7A. The vertical plane A-A′ is a cut plane of the vertical cross-sectional view of FIG. 7A.

FIG. 7C is a vertical cross-sectional view of the first exemplary structure along the vertical plane C-C′ of FIG. 7B.

FIG. 7D is a vertical cross-sectional view of the first exemplary structure along the vertical plane D-D′ of FIG. 7B.

FIG. 8A is a vertical cross-sectional view of the first exemplary structure after formation of laterally-extending cavities according to the first embodiment of the present disclosure.

FIG. 8B is a top-down view of the exemplary structure of FIG. 8A. The vertical plane A-A′ is a cut plane of the vertical cross-sectional view of FIG. 8A.

FIG. 8C is a vertical cross-sectional view of the first exemplary structure along the vertical plane C-C′ of FIG. 8B.

FIG. 8D is a vertical cross-sectional view of the first exemplary structure along the vertical plane D-D′ of FIG. 8B.

FIG. 8E is a horizontal cross-sectional view of the first exemplary structure along the horizontal plane E-E′ of FIGS. 8A, 8C, and 8D.

FIG. 8F is a magnified view of region F in FIG. 8E.

FIG. 9A is a vertical cross-sectional view of the first exemplary structure after formation of electrically conductive layers according to the first embodiment of the present disclosure.

FIG. 9B is a top-down view of the exemplary structure of FIG. 9A. The vertical plane A-A′ is a cut plane of the vertical cross-sectional view of FIG. 9A.

FIG. 9C is a vertical cross-sectional view of the first exemplary structure along the vertical plane C-C′ of FIG. 9B.

FIG. 9D is a vertical cross-sectional view of the first exemplary structure along the vertical plane D-D′ of FIG. 9B.

FIG. 9E is a horizontal cross-sectional view of the first exemplary structure along the horizontal plane E-E′ of FIGS. 9A, 9C, and 9D.

FIG. 9F is a vertical cross-sectional view of the first exemplary structure along the vertical plane F-F′ of FIGS. 9B and 9E.

FIG. 9G is a magnified view of region G in FIG. 9E.

FIG. 10 is a horizontal cross-sectional view of the first exemplary structure after formation of cavities in the memory openings and the support openings according to the first embodiment of the present disclosure.

FIGS. 11, 12, 13 and 14 are sequential vertical cross-sectional views of a region around a memory opening during formation of a memory opening fill structure according to the first embodiment of the present disclosure.

FIG. 15A is a vertical cross-sectional view of the first exemplary structure after formation of memory opening fill structures according to the first embodiment of the present disclosure.

FIG. 15B is a vertical cross-sectional view of a portion of the first exemplary structure of FIG. 15A.

FIG. 16A is a vertical cross-sectional view of a portion of the first exemplary structure including the dielectric wall structure according to the first embodiment of the present disclosure.

FIG. 16B is horizontal cross-sectional view of the first exemplary structure of FIG. 16A along horizontal plane B-B′ in FIG. 16A.

FIG. 17 is a vertical cross-sectional view of the first exemplary structure after formation of drain contact via structures and bit lines according to the first embodiment of the present disclosure.

FIG. 18A is a vertical cross-sectional view of a second exemplary structure after formation of first-tier openings according to the second embodiment of the present disclosure.

FIG. 18B is a top-down view of the exemplary structure of FIG. 18A. The vertical plane A-A′ is a cut plane of the vertical cross-sectional view of FIG. 18A.

FIG. 18C is a vertical cross-sectional view of the second exemplary structure along the vertical plane C-C′ of FIG. 18B.

FIG. 19A is a vertical cross-sectional view of the second exemplary structure after formation of first-tier sacrificial opening fill structures according to the second embodiment of the present disclosure.

FIG. 19B is a top-down view of the exemplary structure of FIG. 19A. The vertical plane A-A′ is a cut plane of the vertical cross-sectional view of FIG. 19A.

FIG. 19C is a vertical cross-sectional view of the second exemplary structure along the vertical plane C-C′ of FIG. 19B.

FIG. 20A is a vertical cross-sectional view of the second exemplary structure after formation of a second alternating stack of second insulating layers and second sacrificial material layers, second-tier openings, and second-tier sacrificial opening fill structures according to the second embodiment of the present disclosure.

FIG. 20B is a top-down view of the exemplary structure of FIG. 20A. The vertical plane A-A′ is a cut plane of the vertical cross-sectional view of FIG. 20A.

FIG. 20C is a vertical cross-sectional view of the second exemplary structure along the vertical plane C-C′ of FIG. 20B.

FIG. 21A is a vertical cross-sectional view of the second exemplary structure after removal of sacrificial isolation opening fill structures according to the second embodiment of the present disclosure.

FIG. 21B is a top-down view of the exemplary structure of FIG. 21A. The vertical plane A-A′ is a cut plane of the vertical cross-sectional view of FIG. 21A.

FIG. 21C is a vertical cross-sectional view of the second exemplary structure along the vertical plane C-C′ of FIG. 21B.

FIG. 22A is a vertical cross-sectional view of the second exemplary structure after formation of interconnected isolation cavities according the second embodiment of the present disclosure.

FIG. 22B is a top-down view of the exemplary structure of FIG. 22A. The vertical plane A-A′ is a cut plane of the vertical cross-sectional view of FIG. 22A.

FIG. 22C is a vertical cross-sectional view of the second exemplary structure along the vertical plane C-C′ of FIG. 22B.

FIG. 22D is a vertical cross-sectional view of the second exemplary structure along the vertical plane D-D′ of FIG. 22B.

FIG. 22E is a horizontal cross-sectional view of the second exemplary structure along the horizontal plane E-E′ of FIGS. 22A, 22C, and 22D.

FIG. 23A is a vertical cross-sectional view of the second exemplary structure after formation of finned dielectric wall structures according the second embodiment of the present disclosure.

FIG. 23B is a top-down view of the exemplary structure of FIG. 23A. The vertical plane A-A′ is a cut plane of the vertical cross-sectional view of FIG. 23A.

FIG. 23C is a vertical cross-sectional view of the second exemplary structure along the vertical plane C-C′ of FIG. 23B.

FIG. 23D is a vertical cross-sectional view of the second exemplary structure along the vertical plane D-D′ of FIG. 23B.

FIG. 23E is a horizontal cross-sectional view of the second exemplary structure along the horizontal plane E-E′ of FIGS. 23A, 23C, and 23D.

FIG. 24A is a vertical cross-sectional view of the second exemplary structure after formation of a patterned etch mask layer and removal of a first subset of the first-tier sacrificial memory opening fill structures and second-tier sacrificial memory opening fill structures according to the second embodiment of the present disclosure.

FIG. 24B is a top-down view of the exemplary structure of FIG. 24A. The vertical plane A-A′ is a cut plane of the vertical cross-sectional view of FIG. 24A.

FIG. 24C is a vertical cross-sectional view of the second exemplary structure along the vertical plane C-C′ of FIG. 24B.

FIG. 24D is a vertical cross-sectional view of the second exemplary structure along the vertical plane D-D′ of FIG. 24B.

FIG. 24E is a horizontal cross-sectional view of the second exemplary structure along the horizontal plane E-E′ of FIGS. 24A, 24C, and 24D.

FIG. 25A is a vertical cross-sectional view of the second exemplary structure after formation of laterally-extending cavities according to the second embodiment of the present disclosure.

FIG. 25B is a top-down view of the exemplary structure of FIG. 25A. The vertical plane A-A′ is a cut plane of the vertical cross-sectional view of FIG. 25A.

FIG. 25C is a vertical cross-sectional view of the second exemplary structure along the vertical plane C-C′ of FIG. 25B.

FIG. 25D is a vertical cross-sectional view of the second exemplary structure along the vertical plane D-D′ of FIG. 25B.

FIG. 25E is a horizontal cross-sectional view of the second exemplary structure along the horizontal plane E-E′ of FIGS. 25A, 25C, and 25D.

FIG. 26A is a vertical cross-sectional view of the second exemplary structure after formation of electrically conductive layers according to the second embodiment of the present disclosure.

FIG. 26B is a top-down view of the exemplary structure of FIG. 26A. The vertical plane A-A′ is a cut plane of the vertical cross-sectional view of FIG. 26A.

FIG. 26C is a vertical cross-sectional view of the second exemplary structure along the vertical plane C-C′ of FIG. 26B.

FIG. 26D is a vertical cross-sectional view of the second exemplary structure along the vertical plane D-D′ of FIG. 26B.

FIG. 26E is a horizontal cross-sectional view of the second exemplary structure along the horizontal plane E-E′ of FIGS. 26A, 26C, and 26D.

FIG. 26F is a vertical cross-sectional view of the second exemplary structure along the vertical plane F-F′ of FIGS. 26B and 26E.

FIG. 27A is a vertical cross-sectional view of a portion of the second exemplary structure after removal of sacrificial material from a second subset of memory openings according to the second embodiment of the present disclosure.

FIG. 27B is a horizontal cross-sectional view of the second exemplary structure of FIG. 27A along horizontal plane B-B′ in FIG. 27A.

FIG. 28A is a vertical cross-sectional view of a portion of the second exemplary structure after formation of memory opening fill structures in the memory openings according to the second embodiment of the present disclosure.

FIG. 28B is a horizontal cross-sectional view of the second exemplary structure of FIG. 28A along horizontal plane B-B′ in FIG. 28A.

### DETAILED DESCRIPTION

As discussed above, the embodiments of the present disclosure are directed to a three-dimensional memory device containing self-aligned memory block isolation and methods of forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

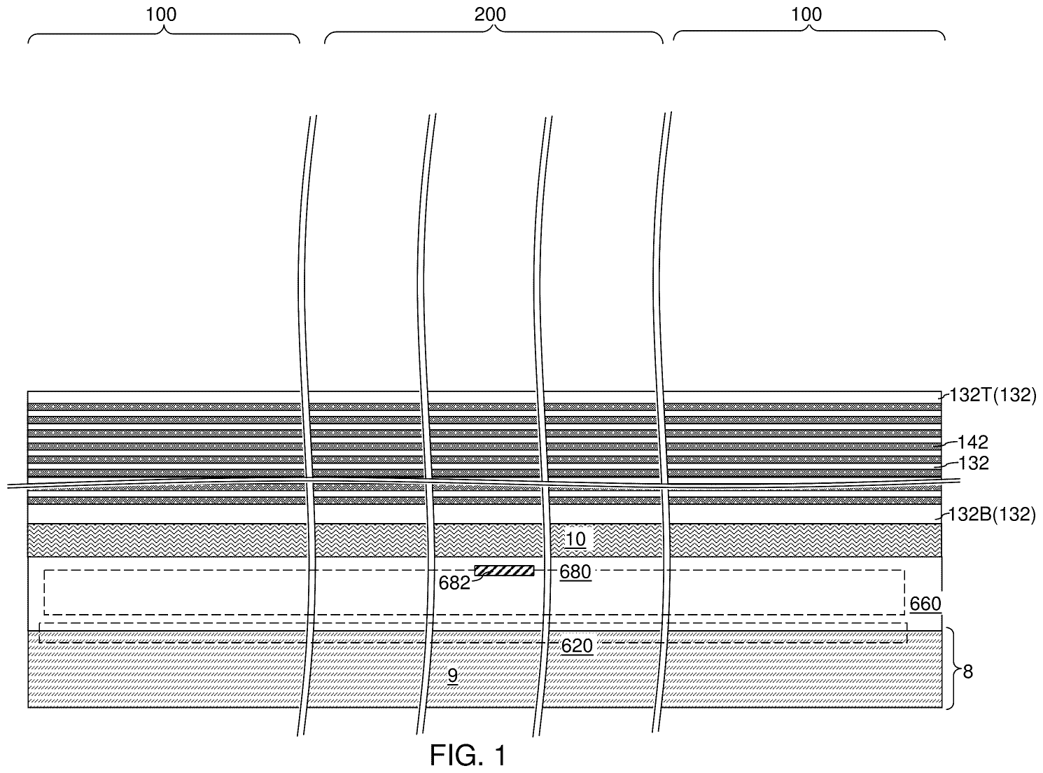

Referring to FIG. 1, a first exemplary structure according to a first embodiment of the present disclosure is illustrated. The first exemplary structure comprises a substrate 8, which may be a semiconductor substrate, an insulating substrate, a conductive substrate, or a combination thereof. In one embodiment, the substrate 8 may comprise a semiconductor substrate consisting essentially of a single crystalline semiconductor material or a polycrystalline semiconductor material. In one embodiment, the substrate 8 may be a portion of a commercially available silicon wafer on which a plurality of semiconductor dies, such as a two-dimensional array of semiconductor dies, can be subsequently formed. In case the substrate 8 comprises a semiconductor substrate, semiconductor devices 620 may be formed on top of the substrate 8. Generally, the semiconductor devices 620 may comprise any type of semiconductor devices known in the art. In one embodiment, the semiconductor devices 620 may comprise complementary metal-oxide-semiconductor (CMOS) field effect transistors. In one embodiment, the semiconductor devices 620 may comprise a peripheral (i.e., driver) circuit for controlling operation of a three-dimensional memory device to be subsequently formed thereabove. Alternatively, the semiconductor devices 620 of the peripheral circuit may be formed on a separate substrate and then bonded to the three-dimensional memory device.

Optionally, metal interconnect structures 680 embedded within dielectric material layers 660 may be formed above the substrate 8. The metal interconnect structures 680 are also referred to as lower-level metal interconnect structures 680, and the dielectric material layers 660 are also referred to lower-level dielectric material layers 660. In case the semiconductor devices 620 are present, the lower-level metal interconnect structures 680 may provide electrical connection to the semiconductor devices 620. In one embodiment, the metal interconnect structures 680 may comprise metal pads 682, which may be employed as a contact pad for optional connection via structures to be subsequently formed.

In case the lower-level dielectric material layers 660 are present, a semiconductor material layer 10 may be formed over the lower-level dielectric material layers 660. The semiconductor material layer 10 may comprise a single semiconductor material layer, or may comprise a vertical stack of multiple semiconductor material sublayers. In one embodiment, in-process source-level material layers may be formed in lieu of the semiconductor material layer 10. In this case, the in-process source-level material layers may comprise a vertical stack including a lower source semiconductor layer, a source-level sacrificial layer that is subsequently replaced with a source contact layer, and an upper source semiconductor layer. In case the lower-level dielectric material layers 660 are not employed, the semiconductor material layer 10 may be omitted. While an embodiment is described in which a semiconductor material layer 10 is employed, alternative embodiments are expressly contemplated herein in which the semiconductor material layer 10 is replaced with in-process source-level material layers, or is omitted.

An alternating stack of first material layers and second material layers is subsequently formed. Each first material layer may include a first material, and each second material layer may include a second material that is different from the first material. In case at least another alternating stack of material layers is subsequently formed over the alternating stack of the first material layers and the second material layers, the alternating stack is herein referred to as a first alternating stack. The level of the first alternating stack is herein referred to as a first-tier level, and the level of the alternating stack to be subsequently formed immediately above the first-tier level is herein referred to as a second-tier level, etc.

The first alternating stack may include first insulting layers 132 as the first material layers, and first spacer material layers as the second material layers. In one embodiment, the first spacer material layers may be sacrificial material layers that are subsequently replaced with electrically conductive layers. In another embodiment, the first spacer material layers may be electrically conductive layers that are not subsequently replaced with other layers. While the present disclosure is described using embodiments in which sacrificial material layers are replaced with electrically conductive layers, embodiments in which the spacer material layers are formed as electrically conductive layers (thereby obviating the need to perform replacement processes) are expressly contemplated herein.

In one embodiment, the first material layers and the second material layers may be first insulating layers 132 and first sacrificial material layers 142, respectively. In this case, the alternating stack comprises a vertically alternating sequence of the first insulating layers 132 and the first sacrificial material layers 142. In one embodiment, each first insulating layer 132 may include a first insulating material, and each first sacrificial material layer 142 may include a first sacrificial material. As used herein, a “sacrificial material” refers to a material that is removed during a subsequent processing step.

As used herein, an alternating stack of first elements and second elements refers to a structure in which instances of the first elements and instances of the second elements alternate. Each instance of the first elements that is not an end element of the alternating plurality is adjoined by two instances of the second elements on both sides, and each instance of the second elements that is not an end element of the alternating plurality is adjoined by two instances of the first elements on both ends. The first elements may have the same thickness throughout, or may have different thicknesses. The second elements may have the same thickness throughout, or may have different thicknesses. The alternating plurality of first material layers and second material layers may begin with an instance of the first material layers or with an instance of the second material layers, and may end with an instance of the first material layers or with an instance of the second material layers. In one embodiment, an instance of the first elements and an instance of the second elements may form a unit that is repeated with periodicity within the alternating plurality.

The first alternating stack (132, 142) may include first insulating layers 132 composed of the first material, and first sacrificial material layers 142 composed of the second material, which is different from the first material. The first material of the first insulating layers 132 may be at least one insulating material. Insulating materials that may be used for the first insulating layers 132 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the first insulating layers 132 may be silicon oxide.

The second material of the first sacrificial material layers 142 is a sacrificial material that may be removed selective to the first material of the first insulating layers 132. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material.

The first sacrificial material layers 142 may comprise an insulating material, a semiconductor material, or a conductive material. The second material of the first sacrificial material layers 142 may be subsequently replaced with electrically conductive electrodes which may function, for example, as control gate electrodes of a vertical NAND device. In one embodiment, the first sacrificial material layers 142 may be material layers that comprise silicon nitride.

In one embodiment, the first insulating layers 132 may include silicon oxide, and sacrificial material layers may include silicon nitride sacrificial material layers. The first material of the first insulating layers 132 may be deposited, for example, by chemical vapor deposition (CVD). For example, if silicon oxide is used for the first insulating layers 132, tetraethylorthosilicate (TEOS) may be used as the precursor material for the CVD process. The second material of the first sacrificial material layers 142 may be formed, for example, CVD or atomic layer deposition (ALD).

The thicknesses of the first insulating layers 132 and the first sacrificial material layers 142 may be in a range from 20 nm to 50 nm, although lesser and greater thicknesses may be used for each first insulating layer 132 and for each first sacrificial material layer 142. The number of repetitions of the pairs of a first insulating layer 132 and a first sacrificial material layer 142 may be in a range from 2 to 1,024, and typically from 8 to 256, although a greater number of repetitions may also be used. In one embodiment, each first sacrificial material layer 142 in the first alternating stack (132, 142) may have a uniform thickness that is substantially invariant within each respective first sacrificial material layer 142.

In one embodiment, the bottommost layer of the first alternating stack (132, 142) may be the bottommost one of the first insulating layers 132, which is herein referred to as a bottommost first insulating layer 132B or a bottommost insulating layer. The topmost layer of the first alternating stack (132, 142) may be a topmost one of the first insulating layers, which is herein referred to as a topmost first insulating layer 132T. The first exemplary structure comprises memory array regions 100 in which three-dimensional memory arrays are subsequently formed, a contact region 200 in which layer contact via structures are subsequently formed.

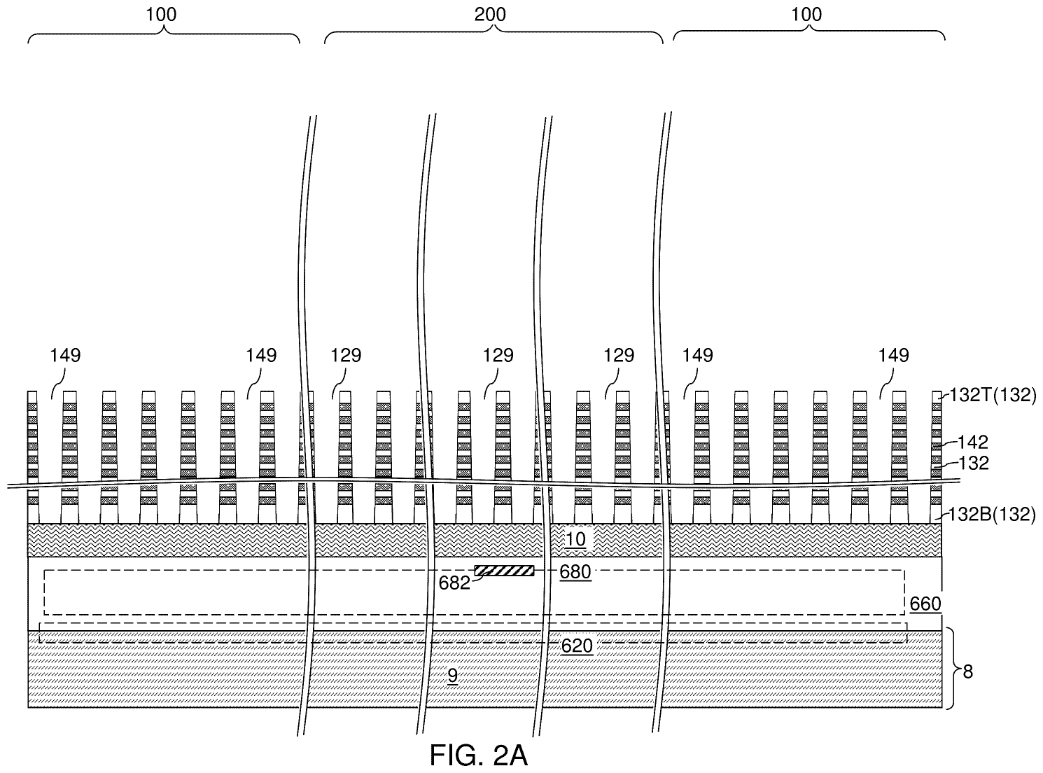

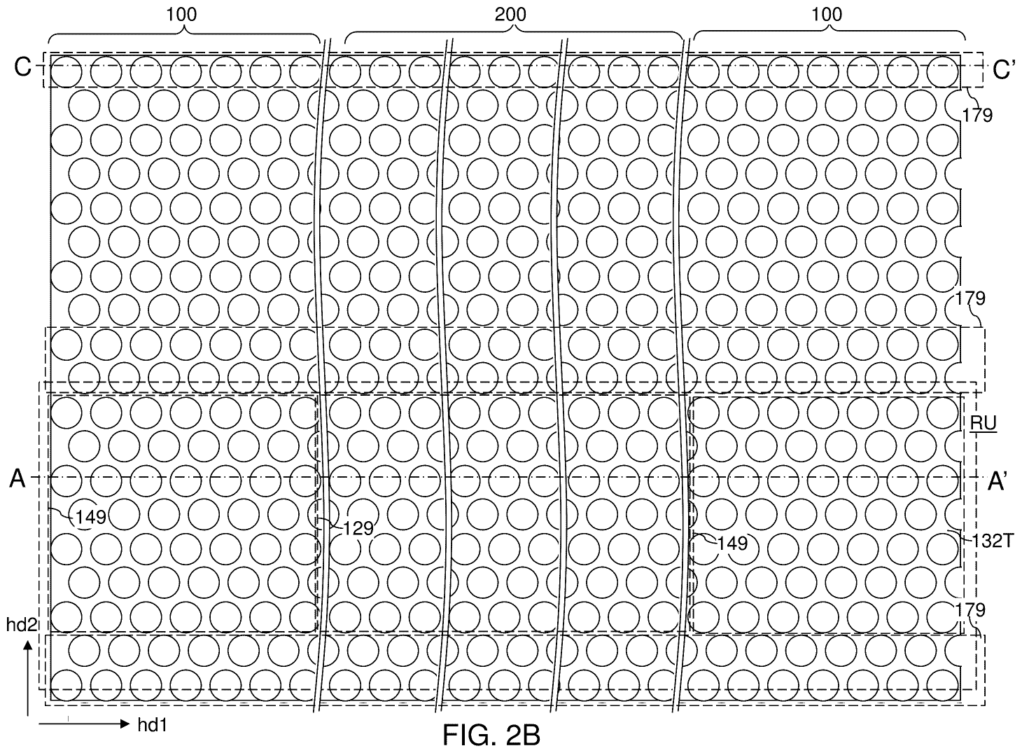

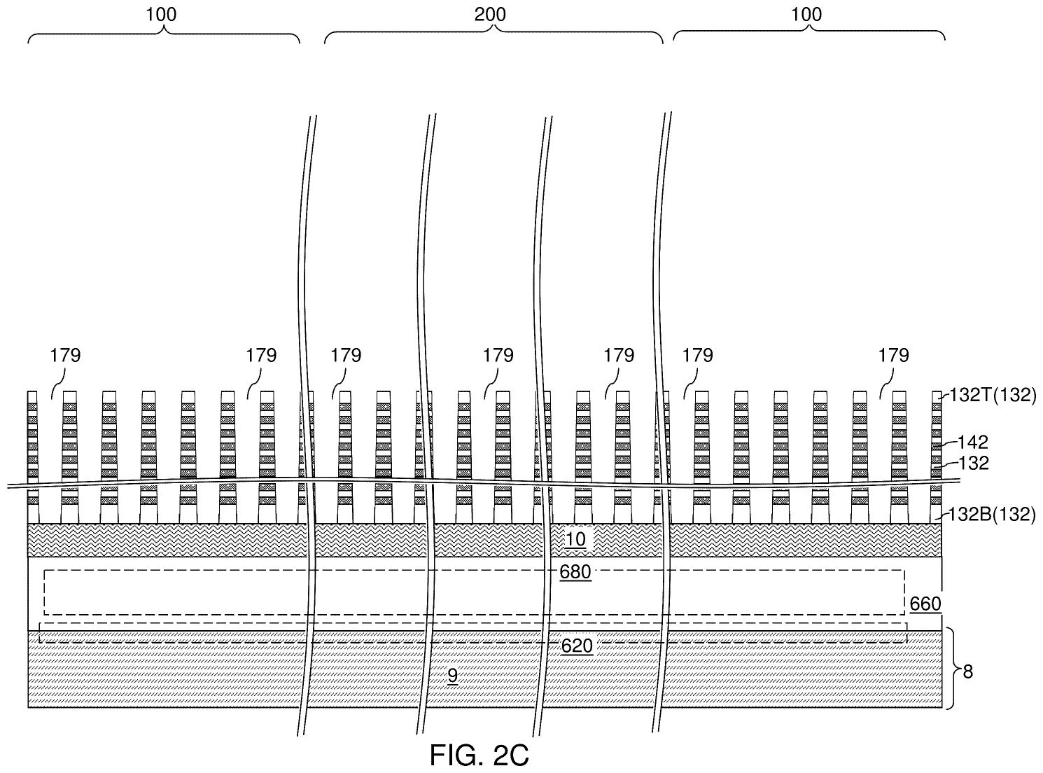

Referring to FIGS. 2A-2C, various first-tier openings (149, 179, 129) may be formed through the first alternating stack (132, 142). A photoresist layer (not shown) may be applied over the first alternating stack (132, 142), and may be lithographically patterned to form various openings therethrough. The pattern of openings in the photoresist layer may be transferred through the first alternating stack (132, 142) by a first anisotropic etch process to form the various first-tier openings (149, 179, 129) concurrently, i.e., during the first anisotropic etch process. The various first-tier openings (149, 179, 129) may include first memory openings 149, first support openings 129, and first isolation openings 179. The first memory openings 149 are formed in the memory array regions 100, the first support openings 129 are formed in the contact region 200, and the first isolation openings 179 are formed in rows that laterally extend along a first horizontal direction hd1 and laterally spaced apart from each other along a second horizontal direction hd2. In one embodiment, the first-tier openings (149, 179, 129) may be formed in a hexagonal close packed array (e.g., in rows in which the openings are laterally offset between adjacent rows) in which the first memory openings 149, the first support openings 129, and the first isolation openings 179 are formed as a respective subset.

The first memory openings 149 are openings that are formed in the memory array regions 100 through each layer within the first alternating stack (132, 142) and are subsequently used to form memory stack structures therein. The first support openings 129 are openings that are formed in the contact region 200. Rows of first isolation openings 179 laterally extend along the first horizontal direction (e.g., word line direction) hd1 through the memory array regions 100 and the contact region 200. The first isolation openings 179 may be arranged in rows that laterally extend along a first horizontal direction hd1, and the first memory openings 149 comprise clusters of first memory openings 149. Each cluster of first memory openings 149 may be located between respective neighboring sets of rows of the first isolation openings 179. In one embodiment, the pattern of the various first-tier openings (149, 179, 129) may be formed with a periodicity along the second horizontal direction (e.g., bit line direction) hd2 such that a pattern in a repetition unit RU is repeated along the second horizontal direction hd2 with a periodicity. Each instance of the repetition unit RU may comprise at least one row of first isolation openings 179, which may comprise a row of first isolation openings 179 or a plurality of rows of first isolation openings 179. In the illustrated example in FIG. 2B, two neighboring rows of first isolation openings 179 may be provided within each repetition unit RU.

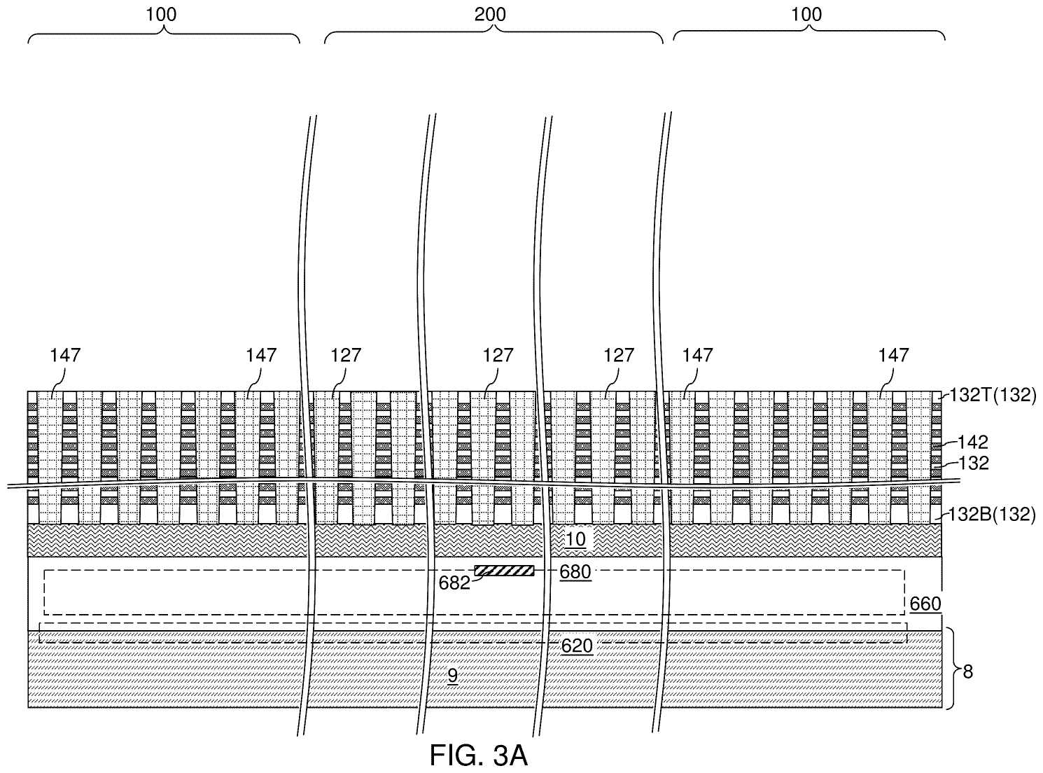

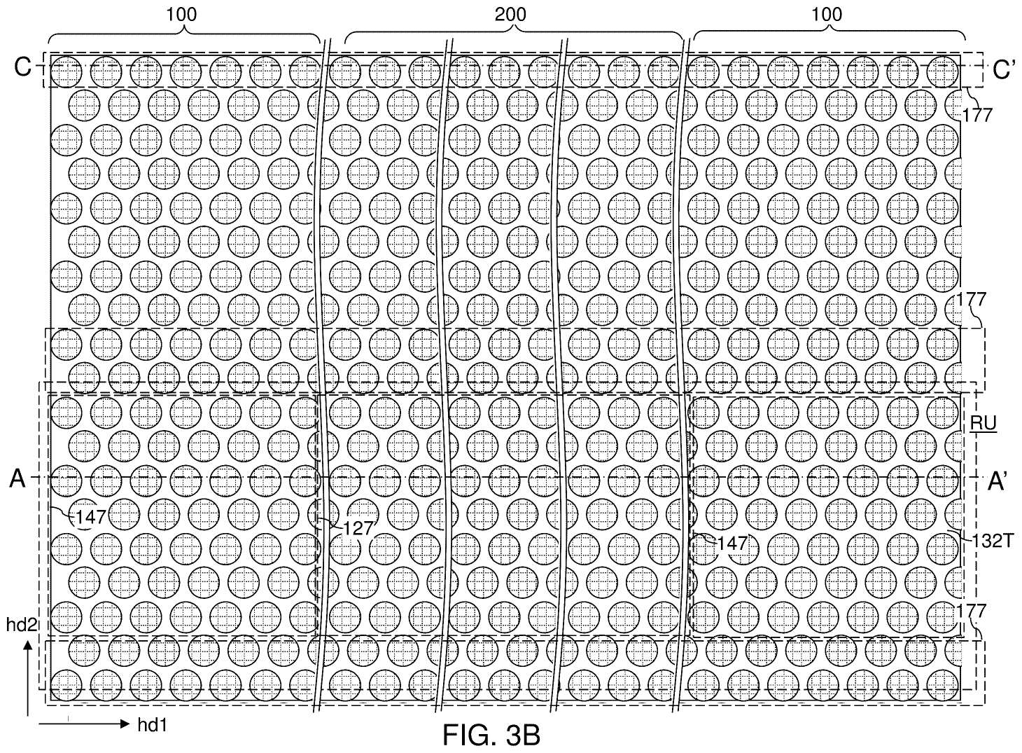

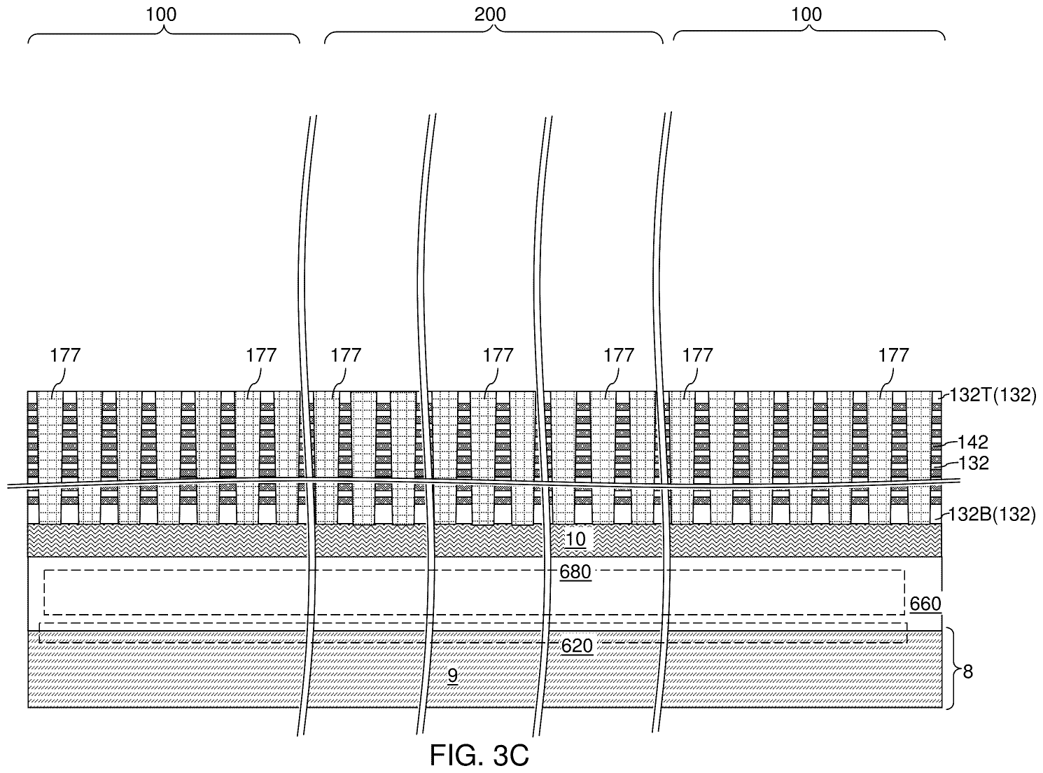

Referring to FIGS. 3A-3C, first sacrificial opening fill structures (147, 127, 177) may be formed in the various first-tier openings (149, 129, 179). For example, an optional first-tier etch stop liner and a first sacrificial fill material can be deposited in each of the first-tier openings (149, 129, 179), and excess portions of the optional first-tier etch stop liner and the first sacrificial fill material can be removed from above the horizontal plane including the top surface of the first-tier alternating stack (132, 142). The first sacrificial fill material includes a material that may be subsequently removed selective to the materials of the first insulating layers 132 and the first sacrificial material layers 142. The first-tier etch stop liner includes a thin etch stop material layer, such as a silicon oxide layer or a silicon nitride layer, having a thickness in a range from 1 nm to 3 nm. The first sacrificial fill material may be formed by a non-conformal deposition or a conformal deposition method.

In one embodiment, the first sacrificial fill material may include a semiconductor material such as silicon (e.g., a-Si or polysilicon), a silicon-germanium alloy, germanium, a III-V compound semiconductor material, or a combination thereof. In another embodiment, the first sacrificial fill material may include a carbon-containing material (such as amorphous carbon or diamond-like carbon) that may be subsequently removed by ashing.

Portions of the deposited sacrificial material may be removed from above the topmost layer of the first alternating stack (132, 142) by a planarization process. The planarization process may include a recess etch, chemical mechanical planarization (CMP), or a combination thereof. Remaining portions of the first sacrificial fill material and the optional first-tier etch stop liner comprise first sacrificial opening fill structures (147, 127, 177). For example, a first sacrificial memory opening fill structure 147 may be formed in each first memory opening 149. A first sacrificial support opening fill structure 127 may be formed in each first sacrificial opening 129. A first sacrificial isolation opening fill structure 177 may be formed in each first isolation opening 179. Each first sacrificial memory opening fill structure 147 may comprise an optional first etch stop liner and a first sacrificial memory opening fill material portion. Each first sacrificial support opening fill structure 127 may comprise an optional first etch stop liner and a first sacrificial fill material portion. Each first sacrificial isolation opening fill structure 177 may comprise an optional first etch stop liner and a first isolation fill material portion.

The first sacrificial isolation opening fill structures 177 may be arranged in rows that laterally extend along a first horizontal direction hd1, and the first sacrificial memory opening fill structures 147 may comprise clusters of first sacrificial memory opening fill structures 147. Each cluster of first sacrificial memory opening fill structures 147 may be located between respective neighboring sets of rows of the first sacrificial isolation opening fill structures 177. The top surfaces of the first sacrificial opening fill structures (147, 127, 177) may be coplanar with the top surface of the topmost first insulating layer 132T. Each of the first sacrificial opening fill structures (147, 127, 177) may, or may not, include cavities therein.

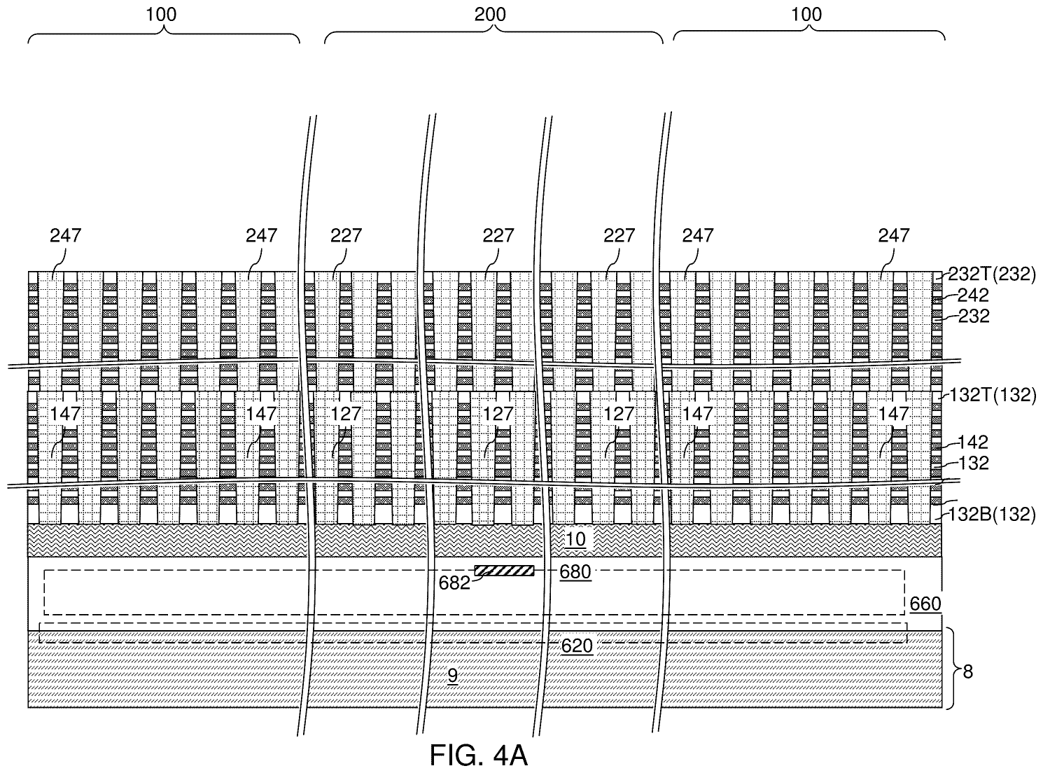

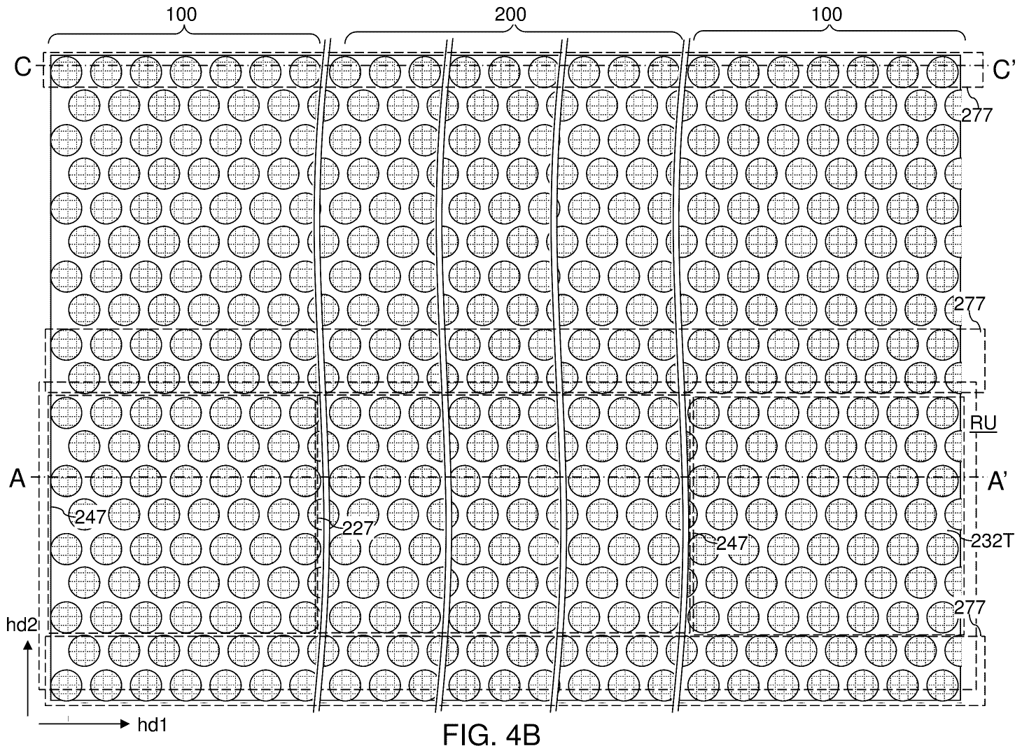

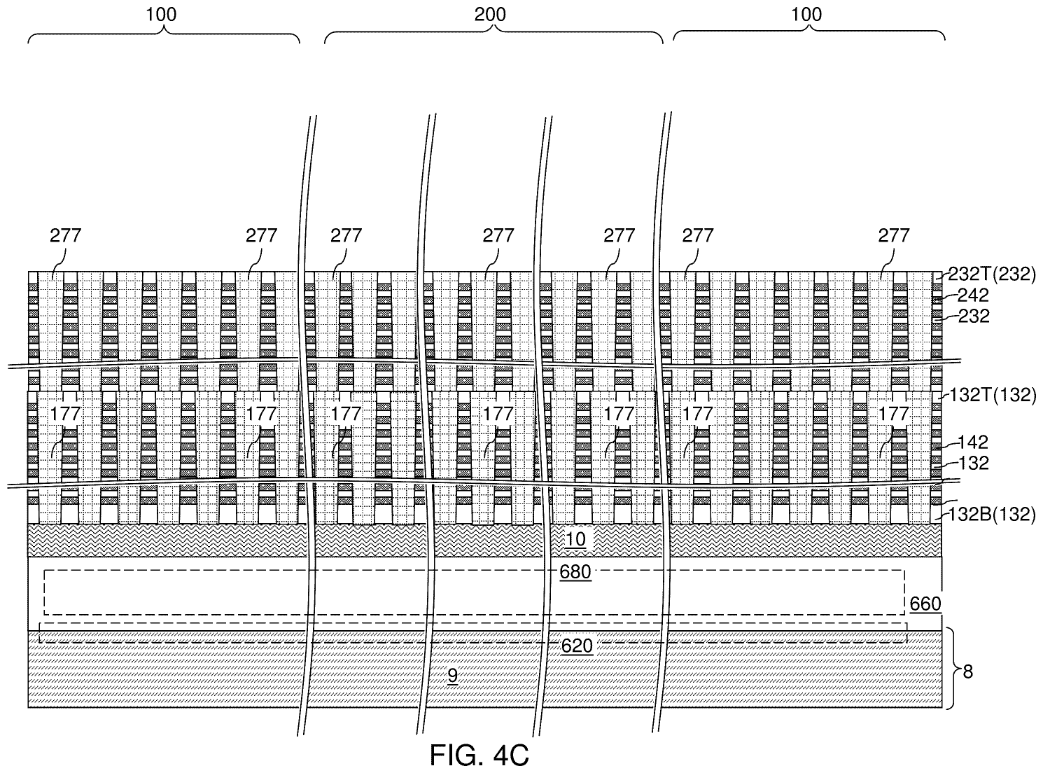

Referring to FIGS. 4A-4C, a second alternating stack (232, 242) of second insulating layers 232 and second sacrificial material layers 242 can be formed above the first alternating stack (132, 142). The second insulating layers 232 may have the same material composition as, and may have the same thicknesses range as, the first insulating layers 132. The second sacrificial material layers 242 may have the same material composition as, and may have the same thickness range as, the first sacrificial material layers 142. Generally, the second alternating stack (232, 242) may be formed by performing the processing steps described with reference to FIG. 1. The topmost one of the second insulating layers 232 is herein referred to as a topmost second insulating layer 232T.

The set of processing steps described with reference to FIGS. 2A-2C and 3A-3C can be performed to form various second-tier openings and various second sacrificial opening fill structures (247, 227, 277). Generally, the second-tier openings can be formed through the second alternating stack (232, 242). The second-tier openings may comprise second memory openings that are formed on top of a respective first sacrificial memory opening fill structure 147, second sacrificial openings that are formed on top of a respective first sacrificial support opening fill structure 127, and supplementary second sacrificial openings that are formed on top of a respective first sacrificial isolation opening fill structure 177.

The second sacrificial opening fill structures (247, 227, 277) may comprise second sacrificial memory opening fill structures 247 that are formed in the second memory openings, second sacrificial support opening fill structures 227 that are formed in the second sacrificial opening, and second sacrificial isolation opening fill structures 277 that are formed in the second isolation openings. Each second sacrificial memory opening fill structure 247 may comprise an optional second etch stop liner and a second sacrificial memory opening fill material portion. Each second sacrificial support opening fill structure 227 may comprise an optional second etch stop liner and a second sacrificial support opening fill material portion. Each second sacrificial isolation opening fill structure 277 may comprise an optional second etch stop liner and a second sacrificial isolation opening fill material portion.

The second sacrificial isolation opening fill structures 277 may be arranged in rows that laterally extend along the first horizontal direction hd1, and the second sacrificial memory opening fill structures 247 may comprise clusters of second sacrificial memory opening fill structures 247. Each cluster of second sacrificial memory opening fill structures 247 may be located between respective neighboring sets of rows of the second sacrificial isolation opening fill structures 277. The top surfaces of the second sacrificial opening fill structures (247, 227, 277) may be coplanar with the top surface of the topmost second insulating layer 232T. Each of the second sacrificial opening fill structures (247, 227, 277) may, or may not, include cavities therein. Two neighboring rows of second sacrificial isolation opening fill structures 277 may be provided within each repetition unit RU.

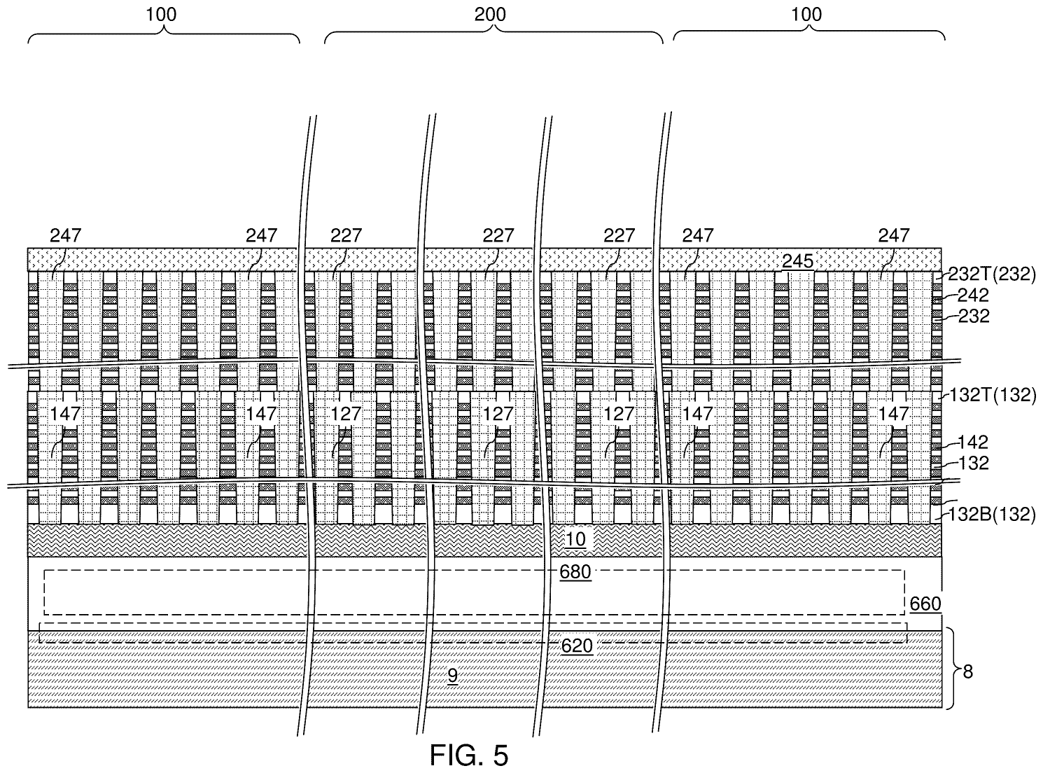

Referring to FIG. 5, an etch mask layer 245 can be formed over the second alternating stack (232, 242). The etch mask layer 245 comprise a material that is different from material of the topmost second insulating layers 232 and the second sacrificial opening fill structures (247, 227, 277). The etch mask layer 245 may comprise a photoresist material, or may comprise a hard mask material that can be subsequently patterned. For example, the etch mask layer 245 may comprise a silicon nitride hard mask material.

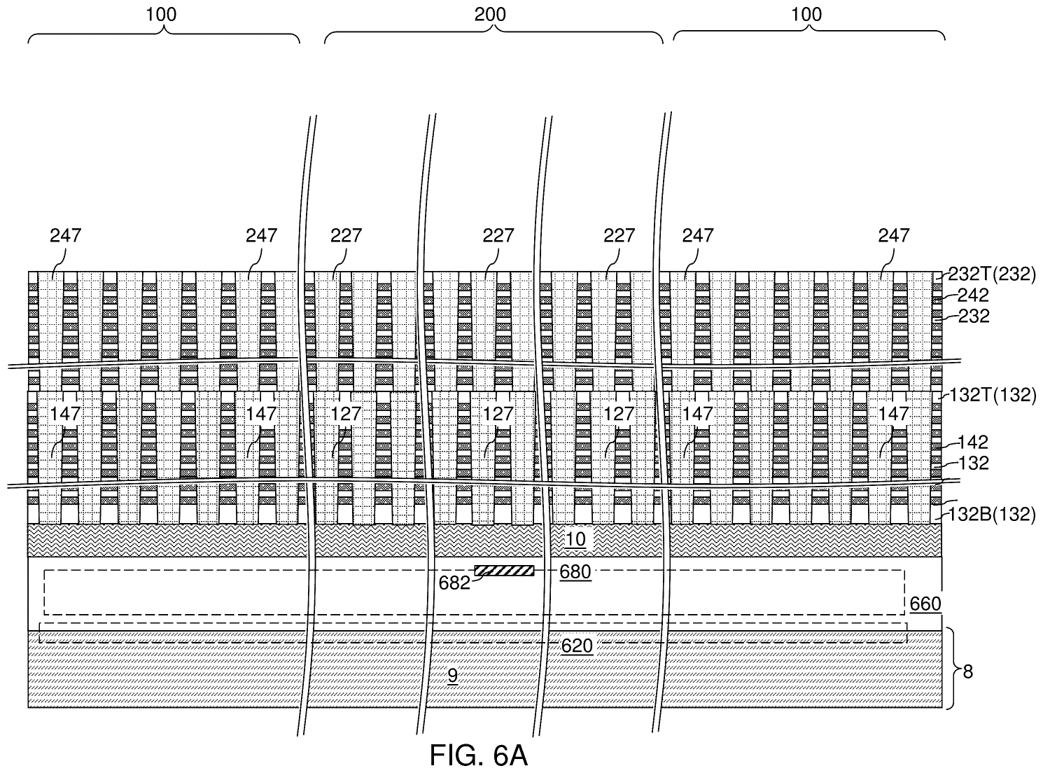

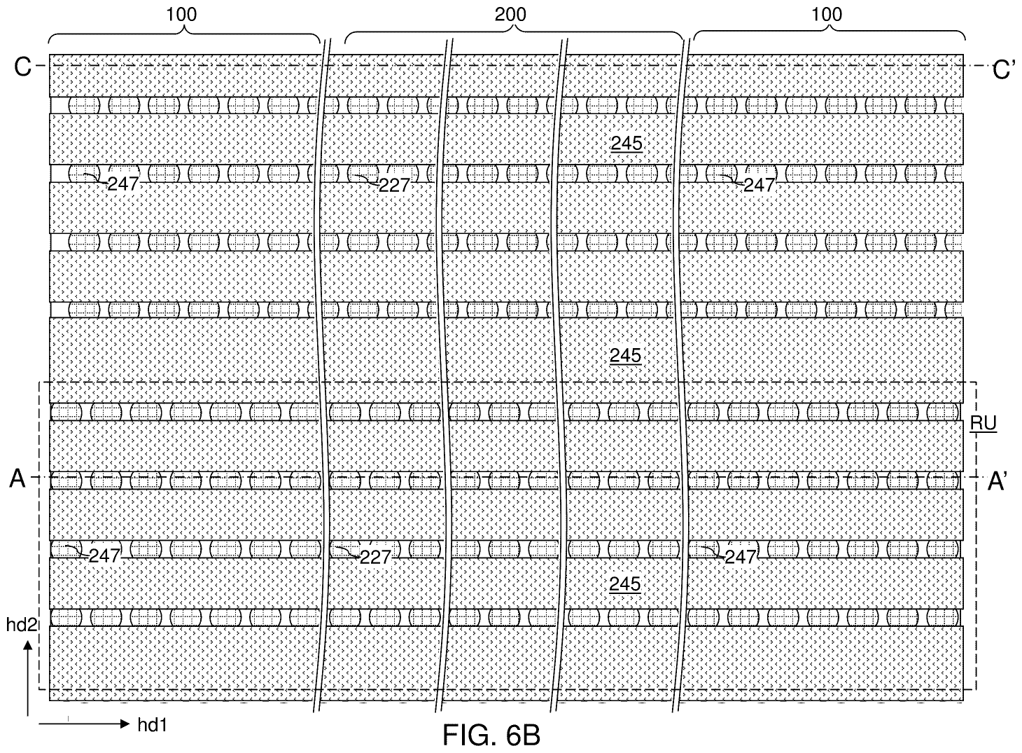

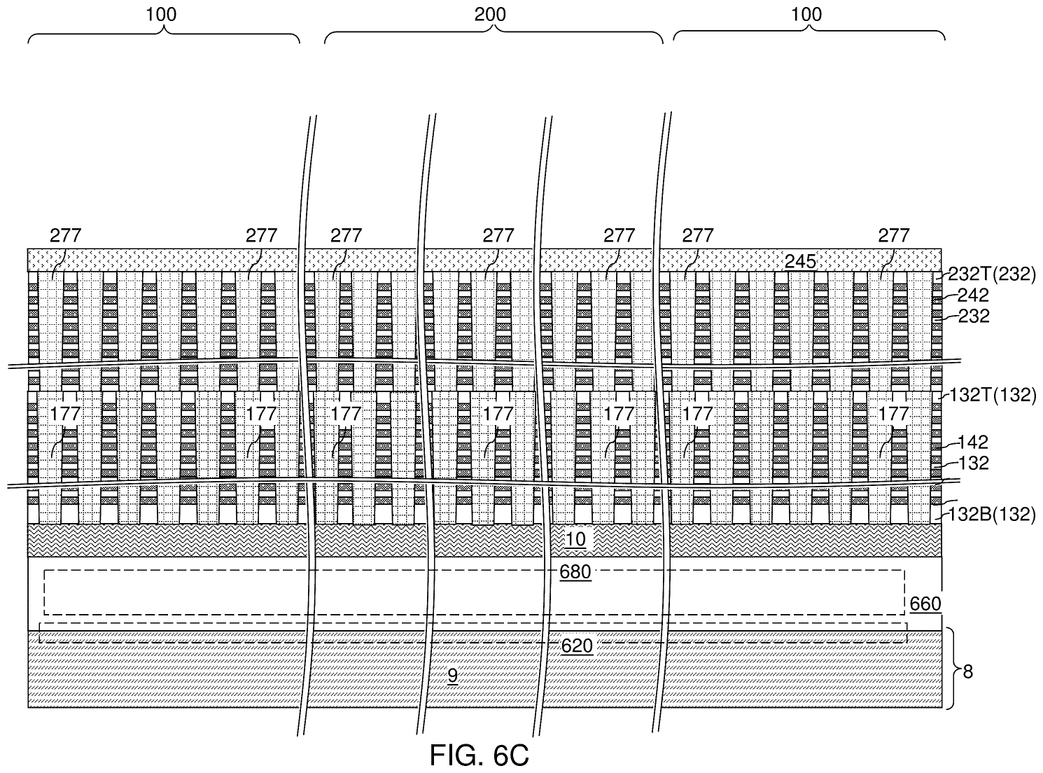

Referring to FIGS. 6A-6C, the etch mask layer 245 may be patterned into strip patterns. If the etch mask layer 245 comprises a photoresist material, the etch mask layer 245 may be patterned by lithographic exposure and development. If the etch mask layer 245 comprises a hard mask material, a photoresist layer can be applied over the etch mask layer 245 and can be lithographically patterned, and the pattern in the photoresist layer can be transferred through the etch mask layer 245 employing an anisotropic etch process to pattern the etch mask layer 245.

Generally, the second sacrificial isolation opening fill structures 277 may be arranged in rows that laterally extend along the first horizontal direction hd1, and each row of second sacrificial isolation opening fill structures 277 can be covered by a respective patterned portion of the etch mask layer 245. In one embodiment, a first subset of rows of second sacrificial memory opening fill structures 247 and second sacrificial support opening fill structures 227 located between respective neighboring sets of rows of second sacrificial isolation opening fill structures 277 can be covered by a respective subset of the patterned portions of the etch mask layer 245, i.e., a respective set of etch mask strips that are patterned portions of the etch mask layer 245. In case two rows of second sacrificial isolation opening fill structures 277 is provided within each repetition unit RU, a patterned strip of the etch mask layer 245 may cover the two rows of second sacrificial isolation opening fill structures 277. In one embodiment, each set of second sacrificial memory opening fill structures 247 and second sacrificial support opening fill structures 227 located between respective neighboring sets of rows of second sacrificial isolation opening fill structures 277 may be arranged in multiple rows that laterally extend along the first horizontal direction hd1 and laterally spaced apart along the second horizontal direction hd2. Each row may comprise multiple second sacrificial memory opening fill structures 247 and multiple second sacrificial support opening fill structures 227.

A first subset of the rows of respective second sacrificial memory opening fill structures 247 and respective second sacrificial support opening fill structures 227 may be covered by a respective strip of the patterned etch mask layer 245, and a second subset of the rows of respective second sacrificial memory opening fill structures 247 and respective second sacrificial support opening fill structures 227 may underlie a gap between a neighboring pair of strips of patterned etch mask layer 245. In one embodiment, a first subset of row and a second subset of rows may be interlaced along the second horizontal direction hd1. Thus, upon numbering of rows of second sacrificial memory opening fill structures 247 and second sacrificial support opening fill structures 227 between a respective neighboring pair of rows of second sacrificial isolation opening fill structures 277 with positive integers beginning with 1, odd-numbered rows may be covered by strips of the patterned etch mask layer 245, and even-numbered rows may underlie a gap between neighboring strips of the patterned etch mask layer 245. Alternatively, even-numbered rows may be covered by strips of the patterned etch mask layer 245, and odd-numbered rows may underlie a gap between neighboring strips of the patterned etch mask layer 245.

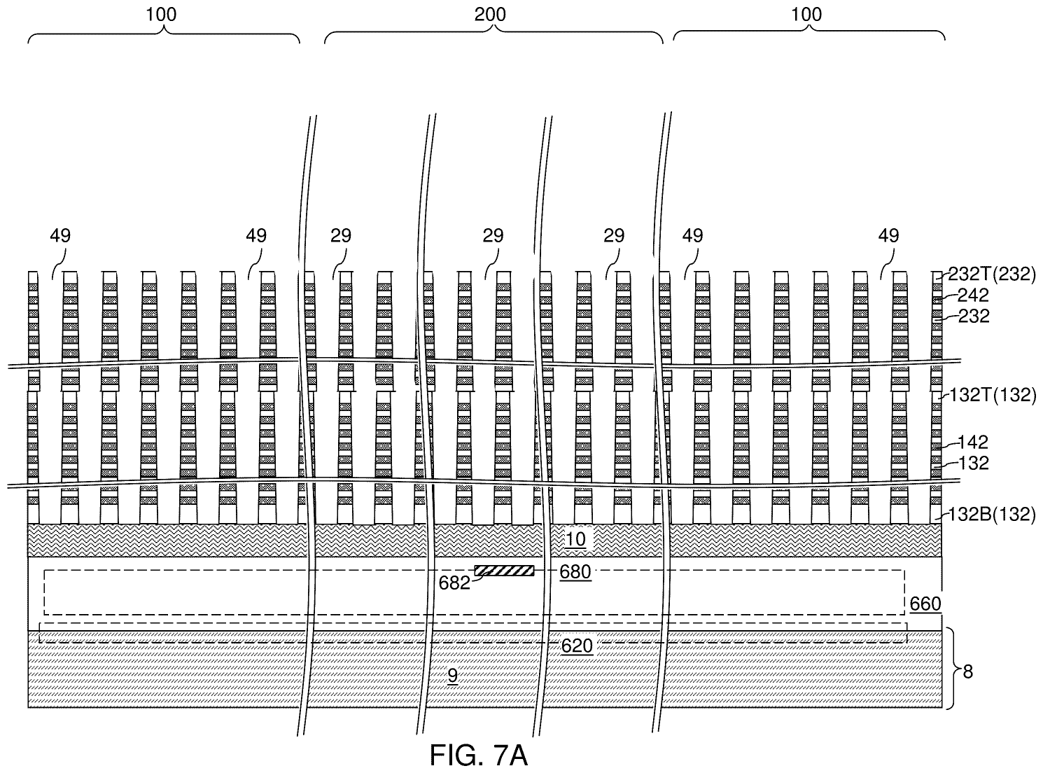

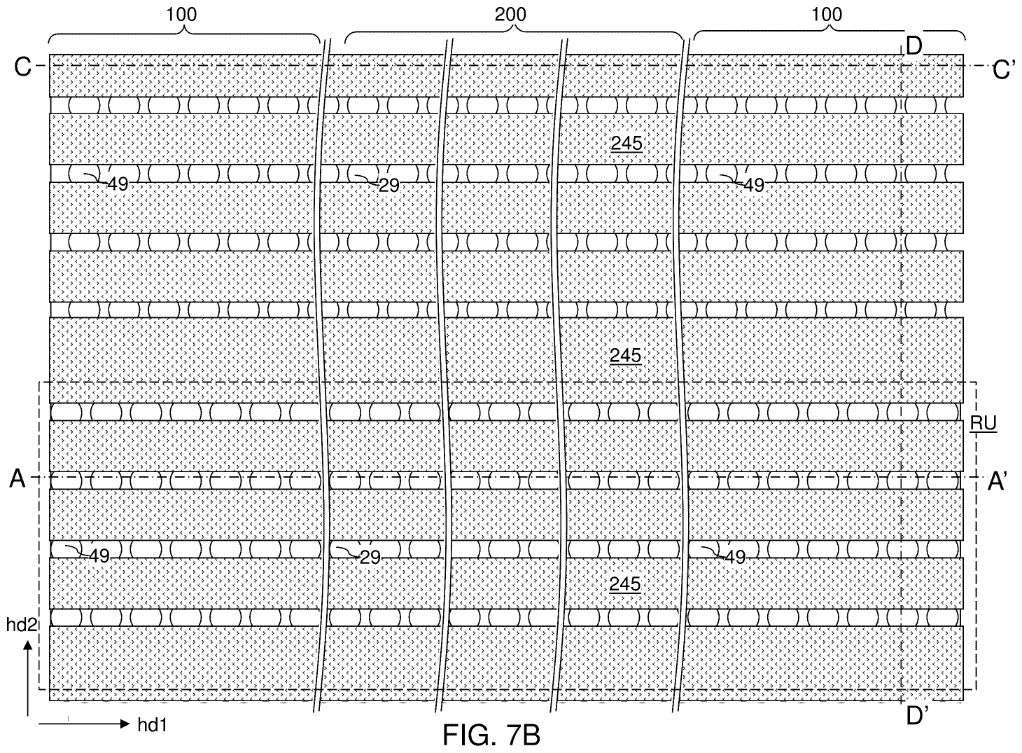

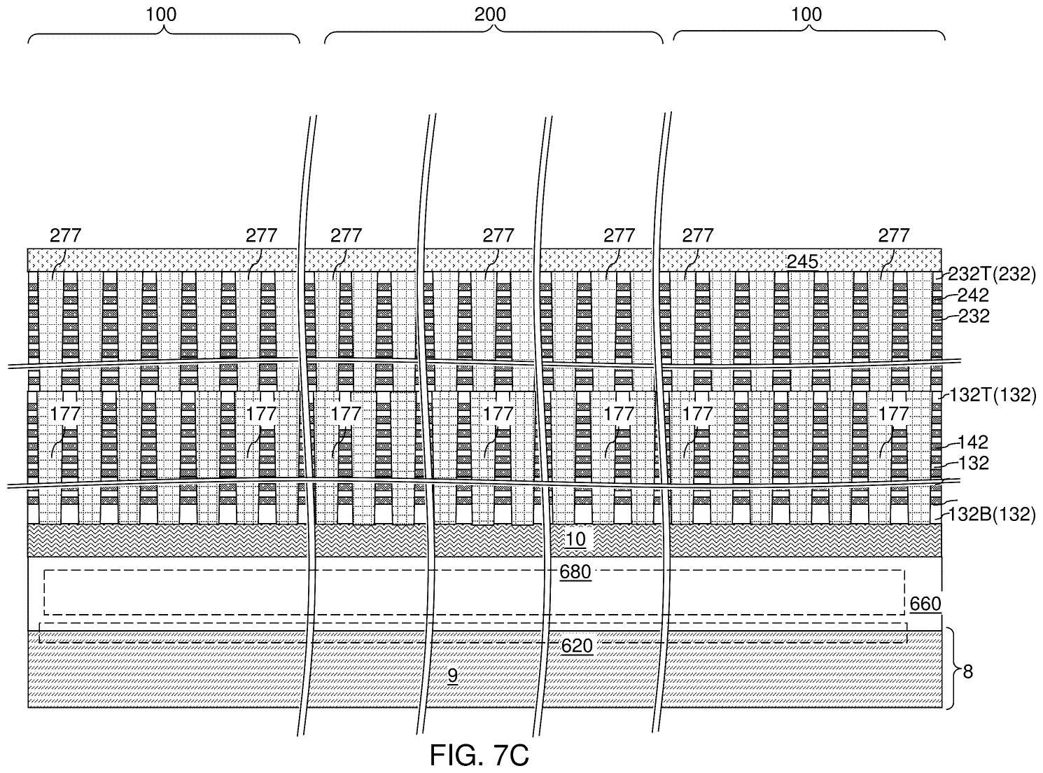

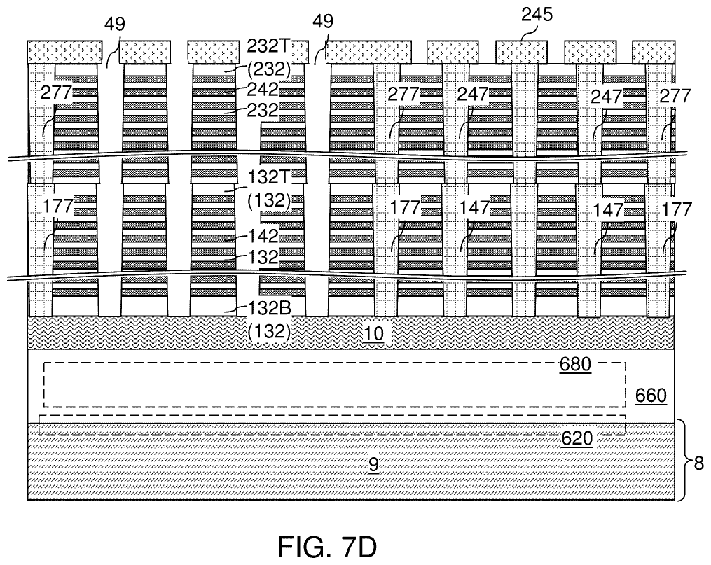

Referring to FIGS. 7A-7D, a selective etch or ashing process can be performed to remove subsets of the second sacrificial memory opening fill structures 247, the second sacrificial support opening fill structures 227, the first sacrificial memory opening fill structures 147, and the first sacrificial support opening fill structures 127 that underlie slit-shaped gaps in the patterned etch mask layer 245. For example, if the sacrificial opening fill structures (147, 127, 177, 247, 227, 277) comprise a semiconductor material, such as amorphous silicon, then a wet etch process employing hot trimethyl-2 hydroxyethyl ammonium hydroxide (“hot TMY”) or tetramethyl ammonium hydroxide (TMAH) may be performed to remove the subsets of the second sacrificial memory opening fill structures 247, the second sacrificial support opening fill structures 227, the first sacrificial memory opening fill structures 147, and the first sacrificial support opening fill structures 127 that underlie the slit-shaped gaps in the patterned etch mask layer 245. In case etch stop liners are employed, additional etch steps may be employed to remove the etch stop liners as necessary. In another example, if the sacrificial opening fill structures (147, 127, 177, 247, 227, 277) comprise a carbon-based material, such as amorphous carbon, then an ashing process may be performed to remove the subsets of the second sacrificial memory opening fill structures 247, the second sacrificial support opening fill structures 227, the first sacrificial memory opening fill structures 147, and the first sacrificial support opening fill structures 127 that underlie the slit-shaped gaps in the patterned etch mask layer 245.

First cavities, which are also referred to as first inter-tier cavities, may be formed in a first subset of memory openings 49. The memory openings 49 refer to all combinations of a respective first memory openings 149 and a respective overlying second memory opening. The first subset of the memory openings 49 are located in volumes from which vertical stacks of a respective second sacrificial memory opening fill structures 247 and a respective first sacrificial memory opening fill structures 147 are removed. A second set of the memory openings 49 is filled with vertical stacks of sacrificial memory opening fill structures (147, 247).

Additional cavities, which are also referred to as additional inter-tier cavities, may be formed in a first subset of support openings 29. The support openings 29 refer to all combinations of a respective first support openings 129 and a respective overlying second support opening. The first subset of the support openings 29 are located in volumes from which vertical stacks of a respective second sacrificial support opening fill structures 227 and a respective first sacrificial support opening fill structures 127 are removed. A second set of the support openings 29 is filled with vertical stacks of sacrificial support opening fill structures (127, 227).

Generally, memory openings 49 can be formed through at least one vertically alternating sequence such as the first alternating stack (132, 142) and the second alternating stack (232, 242). The memory openings 49 are arranged in rows of memory openings 49 that laterally extend along a first horizontal direction hd1, and sacrificial memory opening fill structures (such as the first sacrificial memory opening fill structures 147 and the second sacrificial memory opening fill structures 247) can be formed in the memory openings 49 as described above. First cavities may be formed by removing a first subset of the sacrificial memory opening fill structures (147, 247) from inside a first subset of the memory openings 49 without removing a second subset of the sacrificial memory opening fill structures (147, 247) that are located in a second subset of the memory openings 49. In one embodiment, the first cavities located in the first subset of the memory openings 49 may be arranged in rows that laterally extend along the first horizontal direction hd1, the second subset of the sacrificial memory opening fill structures (147, 247) located in the second subset of the memory openings 49 may be arranged in additional rows that laterally extend along the first horizontal direction hd1. Generally, the first subset of the memory openings 49 (that contains the first cavities) and the second subset of the memory openings 49 (that is filled with the sacrificial memory opening fill structures (147, 247)) may be interlaced along the second horizontal direction hd2.

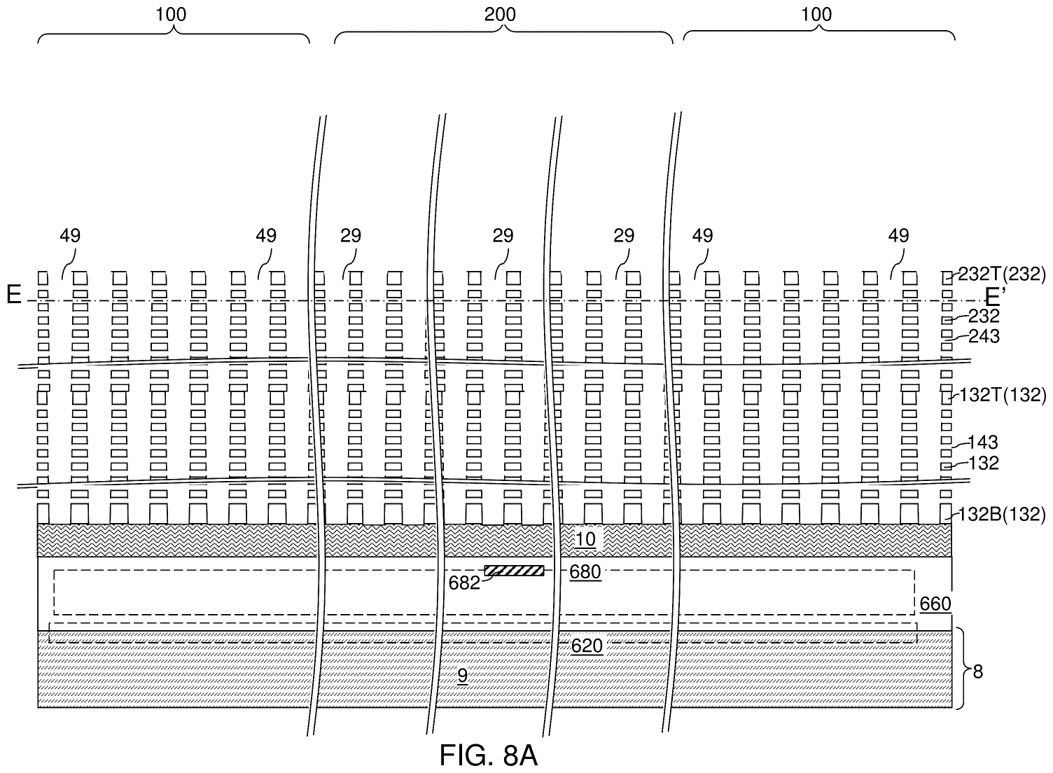

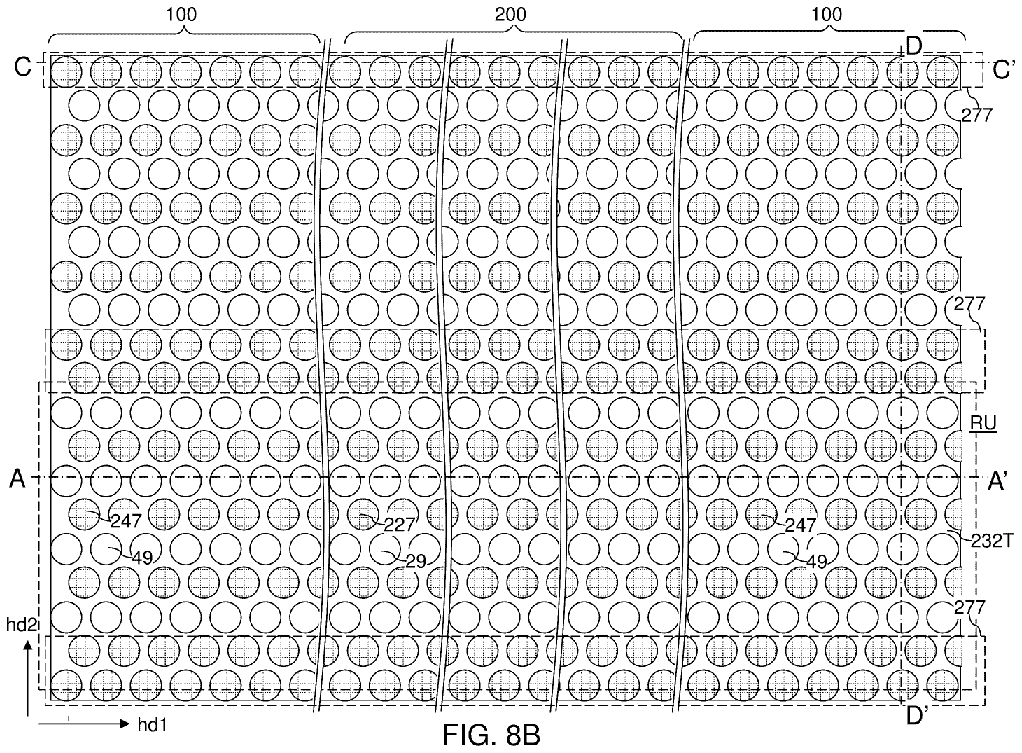

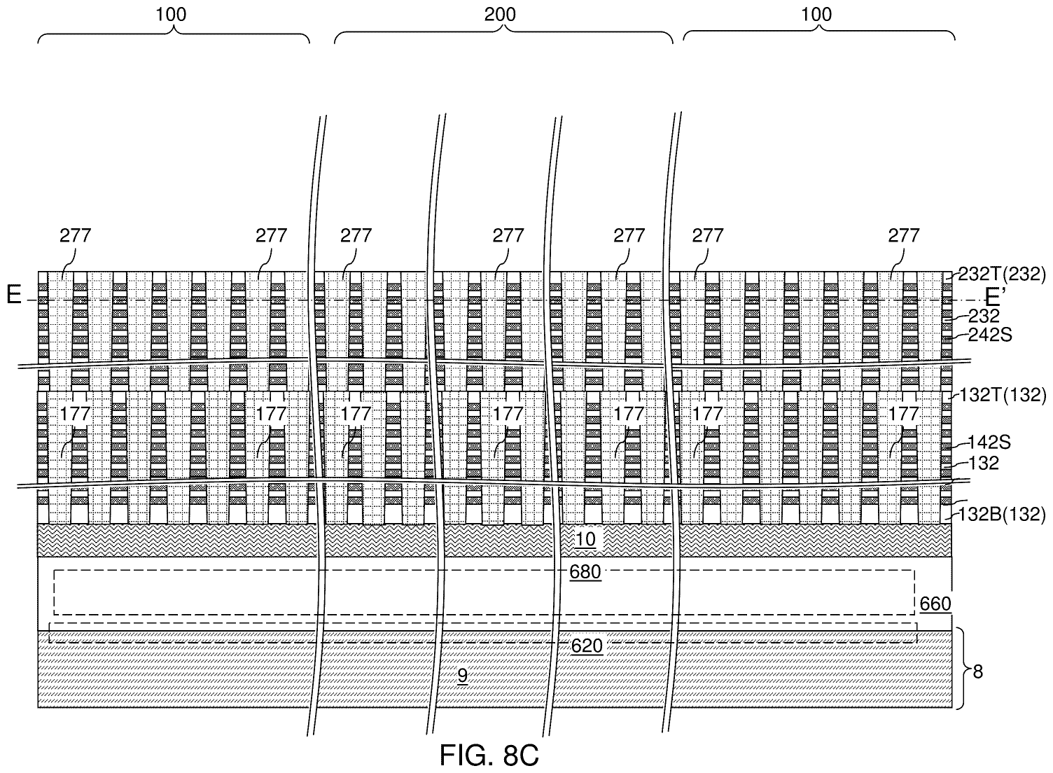

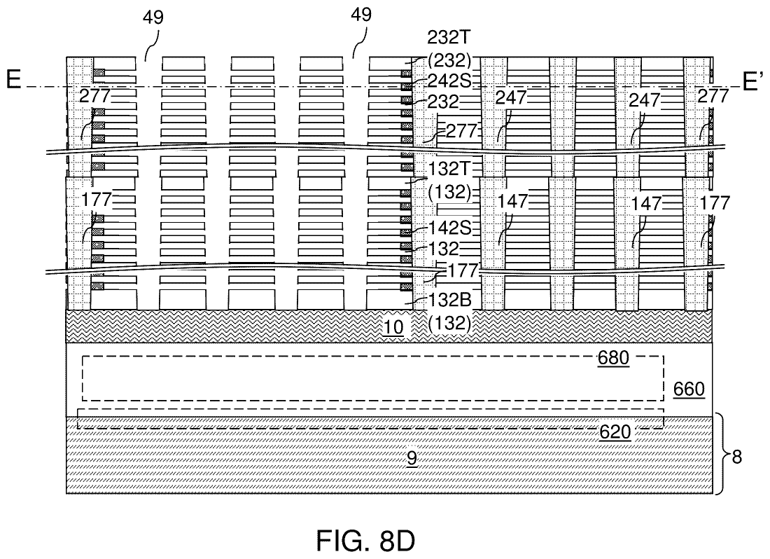

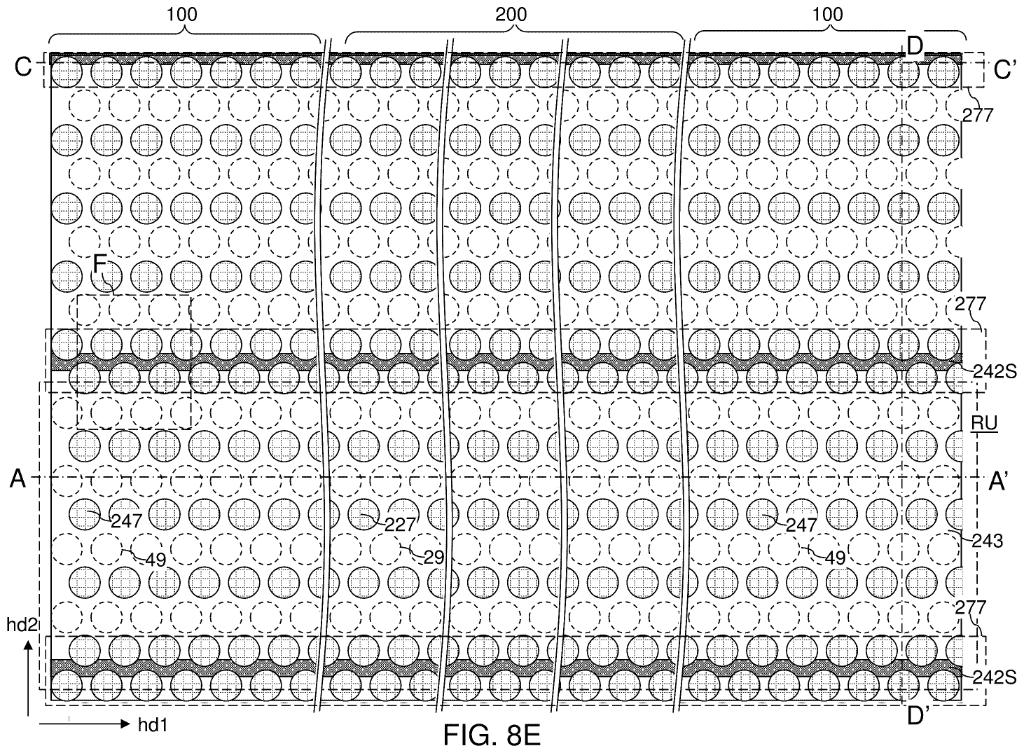

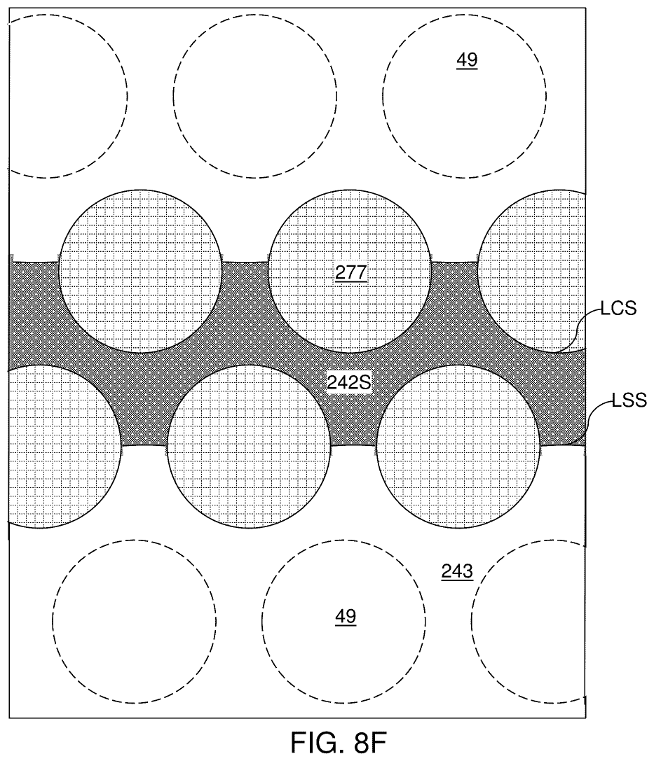

Referring to FIGS. 8A-8F, laterally-extending cavities (143, 243) can be formed by performing an isotropic etch process that laterally recesses the sacrificial material layers (142, 242) from around the first cavities selective to materials of the insulating layers (132, 232) and the second subset of the sacrificial memory opening fill structures (147, 247). For example, an etchant that selectively etches the materials of the sacrificial material layers (142, 242) with respect to the materials of the insulating layers (132, 232) and the sacrificial memory opening fill structures (147, 247) can be introduced into the first cavities in the first subset of the memory openings 49, for example, employing an isotropic etch process. Laterally-extending cavities (143, 243) are formed in volumes from which the sacrificial material layers (142, 242) are removed. The laterally-extending cavities (143, 243) may comprise first laterally-extending cavities 143 that are formed in volumes from which the first sacrificial material layers 142 are removed, and second laterally-extending cavities 243 that are formed in volumes from which the second sacrificial material layers 242 are removed.

The isotropic etch process can be a wet etch process employing a wet etch solution, or can be a gas phase (dry) etch process in which the etchant is introduced in a vapor phase into the laterally-extending cavities (143, 243). For example, if the sacrificial material layers (142, 242) include silicon nitride, then the etch process can be a wet etch process in which the exemplary structure is immersed within a wet etch tank including phosphoric acid, which etches silicon nitride selective to silicon oxide, silicon, and various other materials employed in the art.

Each of the laterally-extending cavities (143, 243) can be a laterally extending cavity having a lateral dimension that is greater than the vertical extent of the cavity. In other words, the lateral dimension of each of the laterally-extending cavities (143, 243) can be greater than the height of the respective laterally-extending cavity (143, 243). Each of the laterally-extending cavities (143, 243) can laterally extend substantially parallel to the top surface of the substrate 8. A laterally-extending cavity (143, 243) can be vertically bounded by a top surface of an underlying insulating layer (132, 232) and a bottom surface of an overlying insulating layer (132, 232). In one embodiment, each of the laterally-extending cavities (143, 243) can have a uniform height throughout.

In one embodiment, the sacrificial material layers (142, 242) may comprise a dielectric material, such as silicon nitride, and a pattern of the first subset of the sacrificial memory opening fill structures (147, 247) (which is the same as the pattern of the first cavities formed in the first subset of the memory openings 49) and the duration of the isotropic etch process are selected such that remaining portions of the sacrificial material layers (142, 242) comprise dielectric material strips (142S, 242S) that laterally extend along the first horizontal direction hd1. The lateral extent of each of the laterally-extending cavities (143, 243) along the second horizontal direction hd2 in each repetition unit RU may be less than the periodicity of the repetition unit RU along the second horizontal direction hd2, and may be about the same as the periodicity of the repetition unit RU along the second horizontal direction hd2 less a lateral dimension of a dielectric material strip (142S, 242S). Each neighboring pair of laterally-extending cavities (143, 242) located between a vertically-neighboring pair of insulating layers (132, 232) among the insulating layers (132, 232) can be laterally spaced from each other by a respective one of the dielectric material strips (142S, 242S).

In one embodiment, each of the laterally-extending cavities (143, 243) laterally surrounds a respective cluster of memory openings 49, and does not laterally encircle any of the isolation openings that are filled with a respective vertical stack of sacrificial isolation opening fill structures (177, 277). The respective cluster of memory openings 49 comprise first memory openings containing first cavities and second memory openings filled within vertical stacks of sacrificial memory opening fill structures (147, 247).

In one embodiment shown in FIGS. 8E and 8F, each of the dielectric material strips (142S, 242S) comprises vertically-straight and laterally-concave sidewalls LCS that contact a rows of vertical stacks of sacrificial isolation opening fill structures (177, 277), and a two-dimensional array of vertically-straight and laterally-straight sidewalls LSS that are exposed to a respective one of the laterally-extending cavities (143, 243). As used herein, a “vertically-straight and laterally-concave” surface or surface segment refers to a surface or surface segment that is straight in a vertical cross-sectional profile and is concave in a horizontal cross-sectional profile. As used herein, a “vertically-straight and laterally-straight” surface or surface segment refers to a surface or surface segment that is straight in a vertical cross-sectional profile and is straight in a horizontal cross-sectional profile.

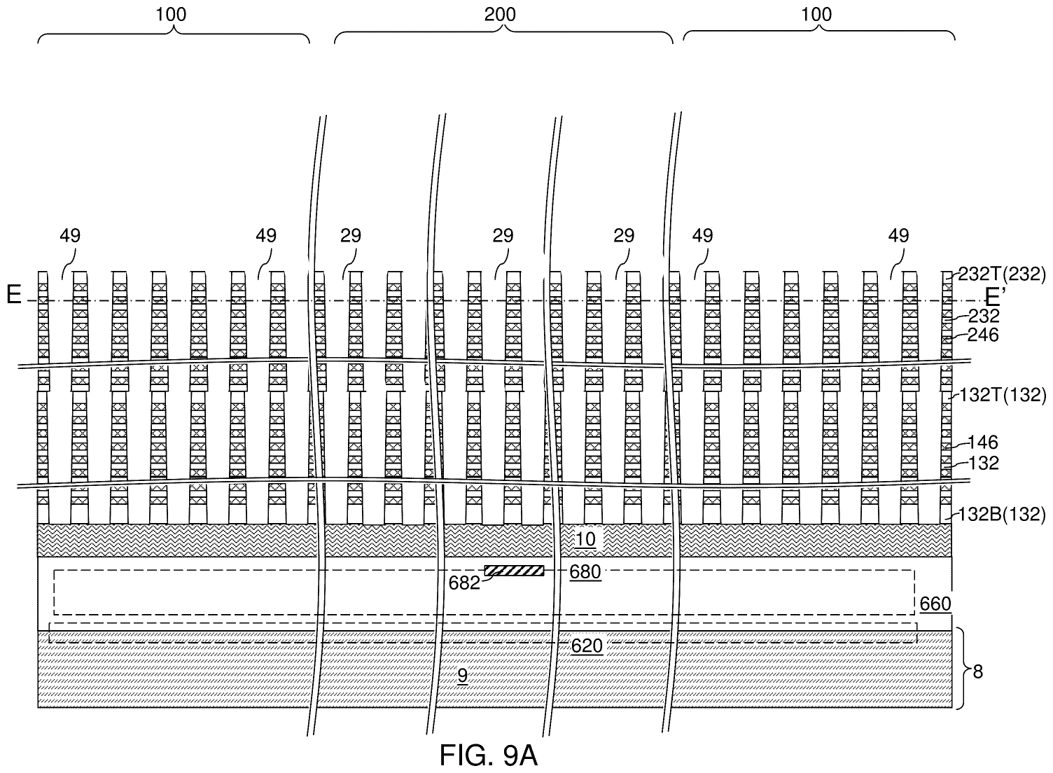

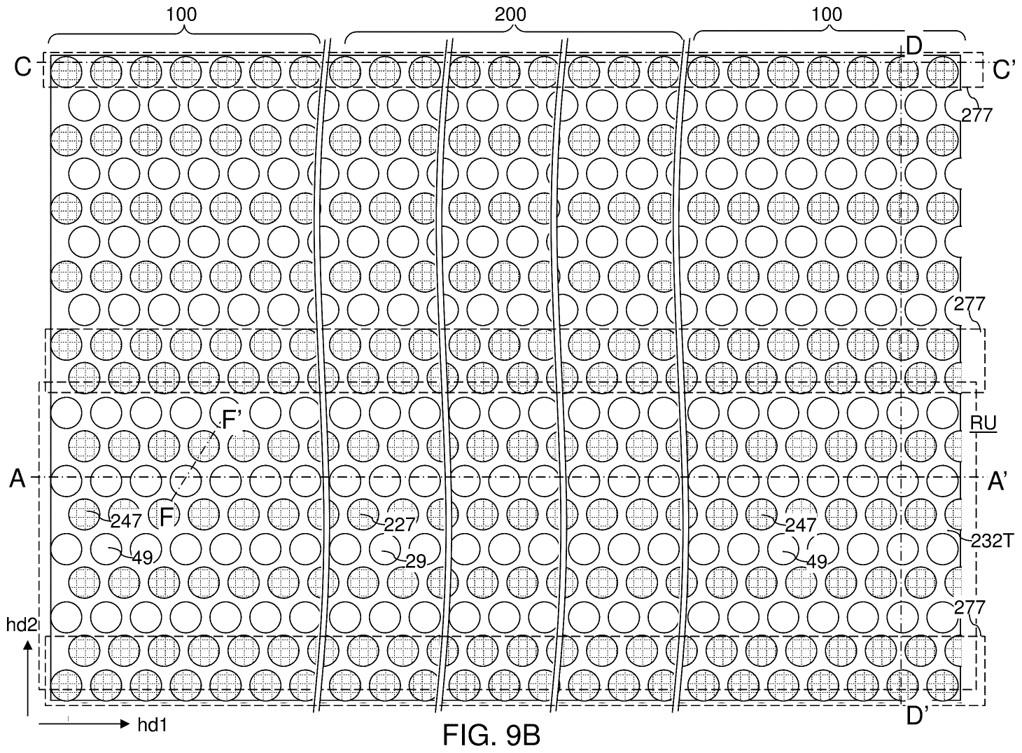

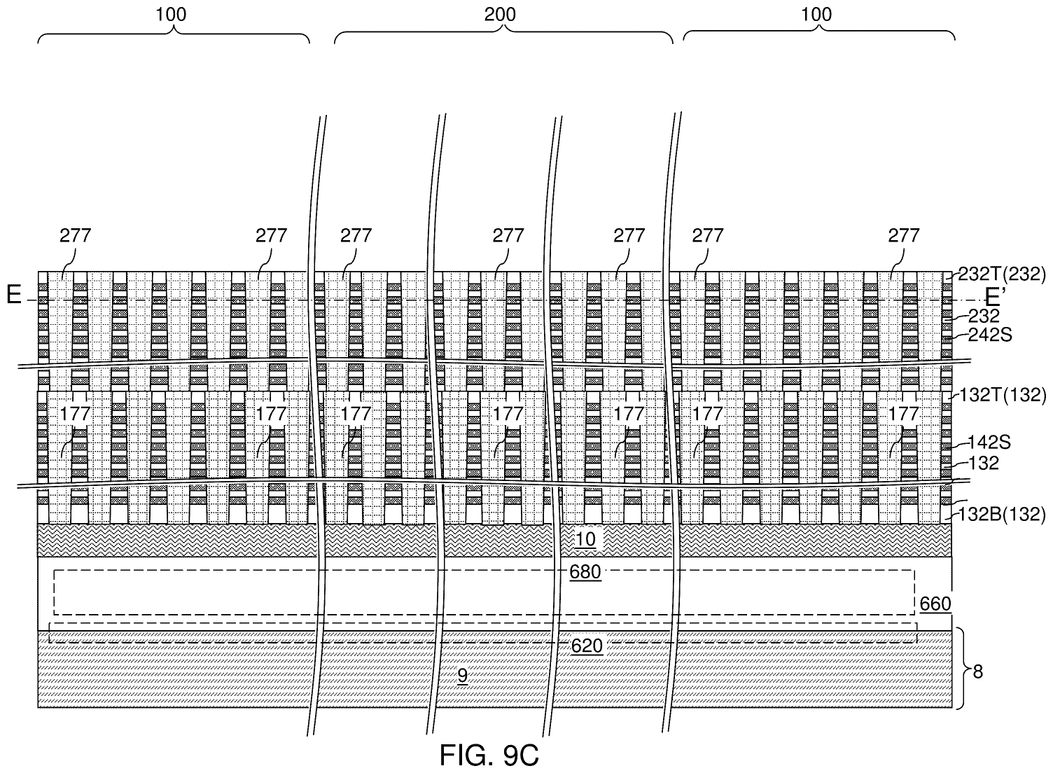

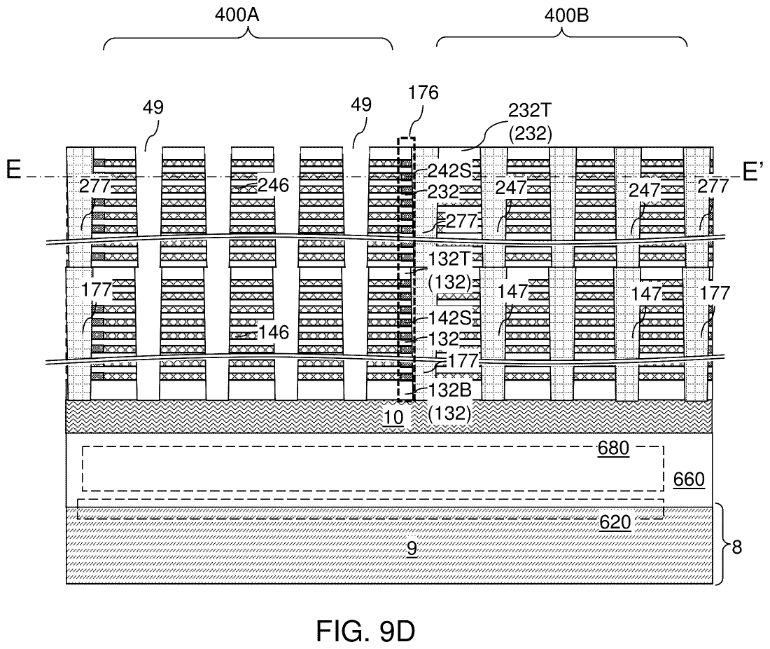

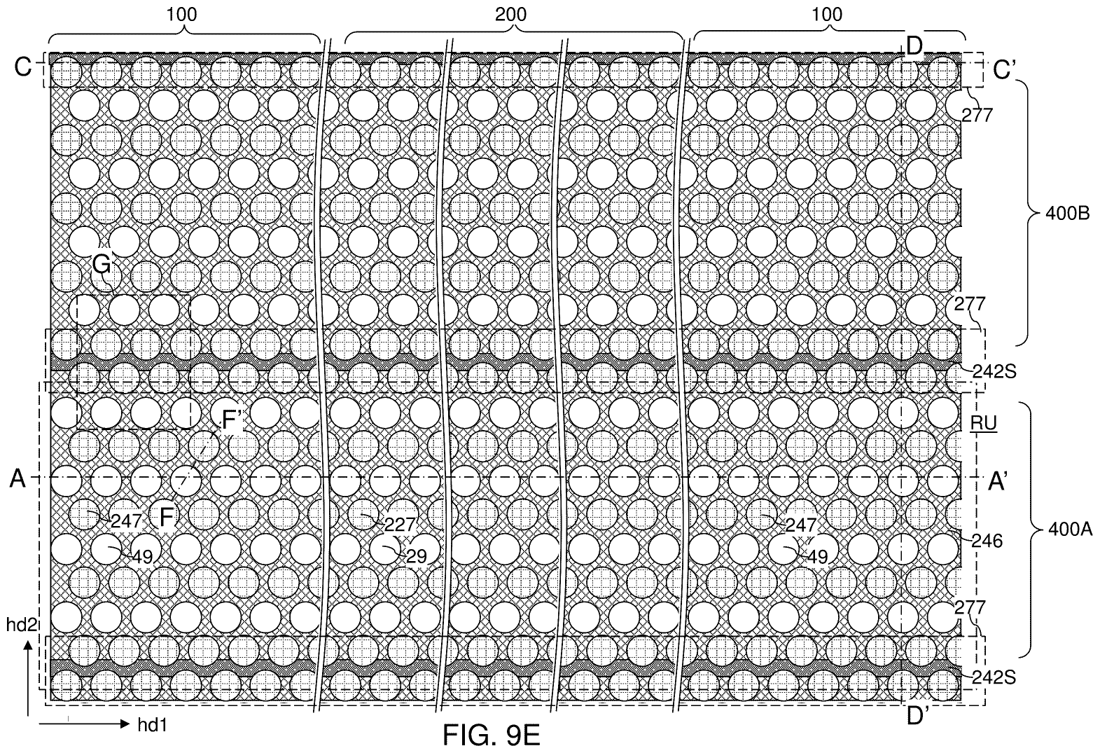

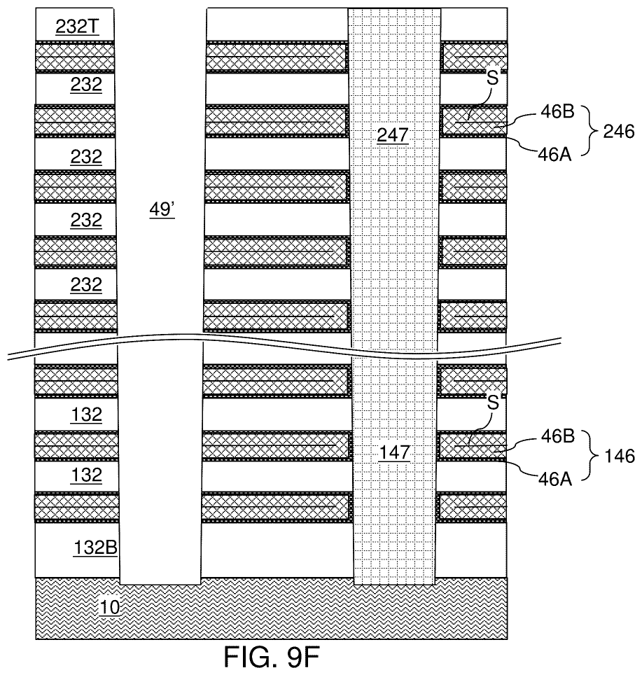

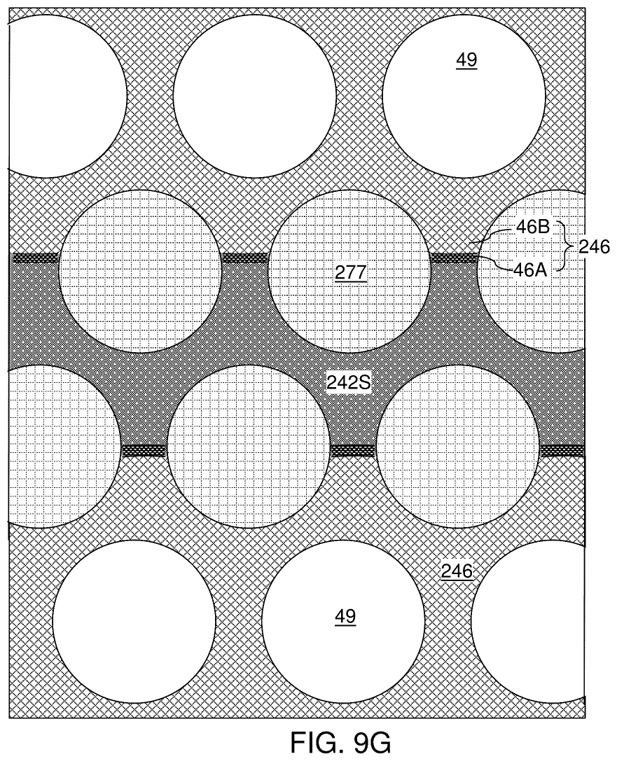

Referring to FIGS. 9A - 9G, at least one conductive material such as at least one metallic material may be conformally deposited in the laterally-extending cavities (143, 243) through the unfilled first set of memory openings 49. The at least one conductive material may comprise, for example, a metallic barrier liner material (such as TiN, TaN, WN, MoN, TiC, TaC, WC, etc.) and a metallic fill material (such as W, Ti, Ta, Co, Ru, Mo, Cu, etc.). Portions of the at least one conductive material that are deposited in the first cavities in the first subset of the memory openings 49 or above the topmost second insulating layer 232T can be removed by a recess etch process, which may comprise an isotropic etch process and/or an anisotropic etch process.

If an isotropic etch process is used and the at least one conductive material is recessed away from the first cavities to expose a portion of the respective laterally-extending cavity (143, 243), then the at least one conductive material may be regrown in the exposed portion of the respective laterally-extending cavity (143, 243). For example, the electrically conductive material may comprise a metal, such as Ru or W, which is selectively grown through the first cavities in the exposed portion of the respective laterally-extending cavity (143, 243) from the edges of the previously recessed electrically conductive material. After the selective regrowth, the laterally-extending cavities (143, 243) may be completely filled with the at least one conductive material.

Each remaining portion of the at least one conductive material that fills a respective laterally-extending cavity (143, 243) constitutes an electrically conductive layer (146, 246). The electrically conductive layers (146, 246) comprise first electrically conductive layers 146 that replace the first sacrificial material layers 142, and second electrically conductive layers 246 that replace the second sacrificial material layers 242. Each of the electrically conductive layers (146, 246) may comprise a combination of a respective metallic barrier liner 46A and a respective metallic fill material portion 46B containing a respective seam S therein. Each seam S may comprise a grain boundary in the metallic fill material portion which is formed due to metal growth from only three sides. Each metallic barrier liner 46A is a patterned portion of the metallic barrier liner material, and each metallic fill material portion 46B is a patterned portion of the metallic fill material.

Each combination of electrically conductive layers (146 or 246) and dielectric material strips (142S or 242S) located between a vertically neighboring pair of insulating layers (132, 232) constitutes a composite layer {(142S, 146) or (242S, 246)}. Each composite layer {(142S, 146) or (242S, 246)} comprises a respective laterally alternating sequence of electrically conductive layers (146, 246) and dielectric material strips (142S, 242S) that alternate along the second horizontal direction hd2. The dielectric material strips (142S, 242S) laterally extend along a first horizontal direction hd1.

Referring to FIGS. 9D and 9E, a vertical stack of alternating dielectric material strips (142S, 242S) and insulating layers (132, 232) located between two neighboring rows of sacrificial isolation opening fill structures (177, 277) forms a dielectric wall 176 extending in the first horizontal direction hd1. The dielectric wall 176 is located between two adjacent memory blocks 400A and 400B which are separated along the second horizontal direction. Thus, the dielectric wall electrically isolates the adjacent memory blocks 400A and 400B from each other.

In one embodiment shown in FIG. 9G, each of the dielectric material strips (142S, 242S) comprises: vertically-straight and laterally-concave sidewalls that contact a rows of vertical stacks of sacrificial isolation opening fill structures (177, 277); and a two-dimensional array of vertically-straight and laterally-straight surface segments that contacts electrically conductive layers (146, 246) within an alternating stack {(132, (146, 142S)), (232, (246, 242S))}.

In one embodiment, each of the electrically conductive layers (146, 246) comprises a respective laterally-extending seam S; the first cavities in a first subset of the memory openings 49 are in direct contact with a respective subset of the seams S of the electrically conductive layers (146, 246); and each vertical stack of sacrificial memory opening fill structures (147, 247) is not in direct contact with any seams S of the electrically conductive layers (146, 246).

The first cavities in the first subset of the memory openings 49 can be located within first rows of the memory openings 49 that laterally extend along the first horizontal direction hd1; the vertical stacks of sacrificial memory opening fill structures (147, 247) in the second subset of the memory openings 49 can be located within second rows of the memory openings 49 that laterally extend along the first horizontal direction hd1; and the first rows and the second rows are interlaced along a second horizontal direction hd2 that is perpendicular to the first horizontal direction hd1. In one embodiment, each vertical stack of sacrificial isolation opening fill structures (177, 277) is not in direct contact with any of the laterally-extending seams S.

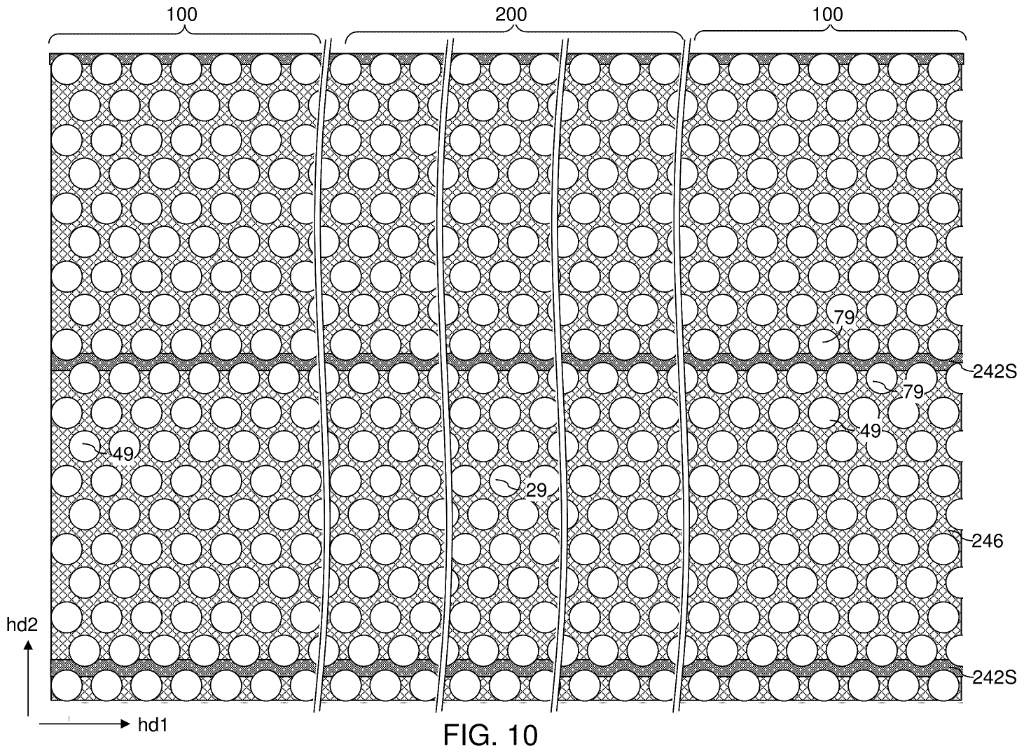

Referring to FIG. 10, the sacrificial fill material (e.g., the remaining first and second sacrificial opening fill structures (147, 127, 177, 247, 227, 277)) remaining in the second subset of the memory openings 49, in the second subset of the support openings 29 and the isolation openings 79 is removed by selective etching or ashing. In the first embodiment, the isolation openings 79 comprise a subset of the memory openings 49 located adjacent to the dielectric material strips (142S, 242S).

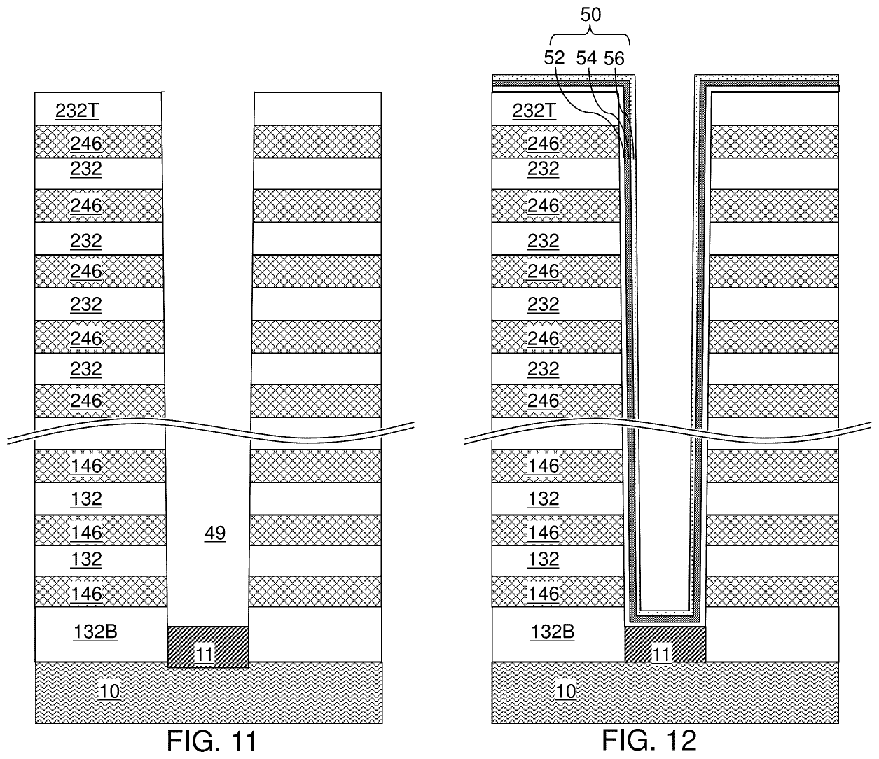

FIGS. 11-14 are sequential vertical cross-sectional views of a region around a memory opening 49 during formation of a memory opening fill structure 58 according to the first embodiment of the present disclosure.

Referring to FIG. 11, an optional channel pedestal 11 May be formed at a bottom portion of each memory opening 49. The channel pedestal 11 May comprise a semiconductor material that is grown on physically exposed surfaces of the semiconductor material layer 10 by a selective deposition process. In this case, the channel pedestal 11 May be employed as a portion of a semiconductor channel.

Alternatively, in case the semiconductor devices 620, the lower-level dielectric material layers 660, and the semiconductor material layer 10 are omitted, sacrificial via structures may be formed directly on a top surface of the substrate 8 in lieu of the channel pedestals 11, and the substrate 8 and the sacrificial via structure may be subsequently removed. In such an embodiment, a source layer (e.g., top source contact) can be subsequently formed on the bottommost first insulating layer 132B such that the source layer contacts bottom ends of vertical semiconductor channels.

Referring to FIG. 12 a stack of layers including a blocking dielectric layer 52, a memory material layer 54, and an optional dielectric liner 56 can be sequentially deposited in the memory openings 49 over each channel pedestal 11. The blocking dielectric layer 52 can include a single dielectric material layer or a stack of a plurality of dielectric material layers. In one embodiment, the blocking dielectric layer can include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 can include a dielectric metal oxide having a dielectric constant greater than 7.9, i.e., having a dielectric constant greater than the dielectric constant of silicon nitride. The thickness of the dielectric metal oxide layer can be in a range from 1 nm to 20 nm, although lesser and greater thicknesses can also be employed. The dielectric metal oxide layer can subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 can include a dielectric semiconductor compound such as silicon oxide, silicon oxynitride, silicon nitride, or a combination thereof.

Subsequently, the memory material layer 54 can be formed. Generally, the memory material layer may comprise any memory material such as a charge storage material, a ferroelectric material, a phase change material, or any material that can store data bits in the form of presence or absence of electrical charges, a direction of ferroelectric polarization, electrical resistivity, or another measurable physical parameter. In one embodiment, the memory material layer 54 can be a continuous layer or patterned discrete portions of a charge trapping material including a dielectric charge trapping material, which can be, for example, silicon nitride. In one embodiment, the memory material layer 54 includes a silicon nitride layer. In one embodiment, the electrically conductive layers (146, 246) and the insulating layers (132, 232) can have vertically coincident sidewalls, and the memory material layer 54 can be formed as a single continuous layer. The memory material layer 54 can be formed, for example, by chemical vapor deposition (CVD), atomic layer deposition (ALD), physical vapor deposition (PVD), or any suitable deposition technique for storing electrical charges therein. The thickness of the memory material layer 54 can be in a range from 2 nm to 20 nm, although lesser and greater thicknesses can also be employed.

Generally, any vertical stack of memory elements known in the art may replace the memory material layer 54. The vertical stack of memory elements can be formed at levels of the electrically conductive layers (146, 246) within each memory opening 49, and may be formed as portions of a continuous memory material layer, or may be formed as discrete memory material portions.

The optional dielectric liner 56, if present, includes a dielectric material. In one embodiment, the optional dielectric liner 56 comprises a tunneling dielectric layer through which charge tunneling can be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The optional dielectric liner 56 can include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the optional dielectric liner 56 can include a stack of a first silicon oxide layer, a silicon oxynitride layer, and a second silicon oxide layer, which is commonly known as an ONO stack. In one embodiment, the optional dielectric liner 56 can include a silicon oxide layer that is substantially free of carbon or a silicon oxynitride layer that is substantially free of carbon. The thickness of the optional dielectric liner 56 can be in a range from 2 nm to 20 nm, although lesser and greater thicknesses can also be employed. The stack of the blocking dielectric layer 52, the memory material layer 54, and the optional dielectric liner 56 constitutes a memory film 50 that stores memory bits. A cavity is present

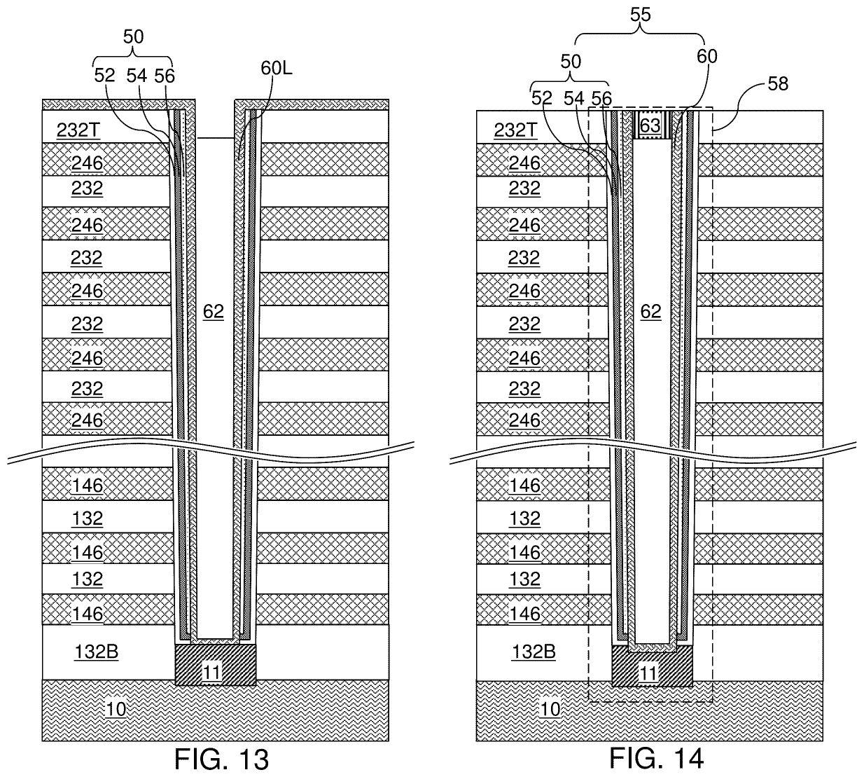

Referring to FIG. 13, an anisotropic etch process can be performed to remove horizontally-extending portions of the memory film 50. A top surface of a channel pedestal 11 can be physically exposed at the bottom of each memory opening 49.

A semiconductor channel material layer 60L can be deposited by a conformal deposition process. The semiconductor channel material layer 60L includes a semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L includes amorphous silicon or polysilicon. The semiconductor channel material layer 60L can be formed by a conformal deposition method such as low pressure chemical vapor deposition (LPCVD). The thickness of the semiconductor channel material layer 60L can be in a range from 2 nm to 10 nm, although lesser and greater thicknesses can also be employed. A cavity can be present in the volume of each memory opening 49 that is not filled with the deposited material layers (52, 54, 56, 60L).

In case the cavity in each memory opening is not completely filled by the semiconductor channel material layer 60L, a dielectric core layer can be deposited in the cavity to fill any remaining portion of the cavity within each memory opening. The dielectric core layer includes a dielectric material such as silicon oxide or organosilicate glass. The dielectric core layer can be deposited by a conformal deposition method such as low pressure chemical vapor deposition (LPCVD), or by a self-planarizing deposition process such as spin coating. The horizontal portion of the dielectric core layer overlying the topmost first insulating layer 132T can be removed, for example, by a recess etch. The recess etch continues until top surfaces of the remaining portions of the dielectric core layer are recessed to a height between the top surface of the topmost first insulating layer 132T and the bottom surface of the topmost first insulating layer 132T. Each remaining portion of the dielectric core layer constitutes a dielectric core 62.

Referring to FIG. 14, a doped semiconductor material can be deposited in cavities overlying the dielectric cores 62. The doped semiconductor material has a doping of the opposite conductivity type of the doping of the semiconductor channel material layer 60L. Thus, the doped semiconductor material has a doping of the second conductivity type. Portions of the deposited doped semiconductor material, the semiconductor channel material layer 60L, the optional dielectric liner 56, the memory material layer 54, and the blocking dielectric layer 52 that overlie the horizontal plane including the top surface of the topmost first insulating layer 132T can be removed by a planarization process such as a chemical mechanical planarization (CMP) process.

Each remaining portion of the doped semiconductor material having a doping of the second conductivity type constitutes a drain region 63. The drain regions 63 can have a doping of a second conductivity type that is the opposite of the first conductivity type. For example, if the first conductivity type is p-type, the second conductivity type is n-type, and vice versa. The dopant concentration in the drain regions 63 can be in a range from 5.0×10¹⁸/cm³ to 2.0×10²¹/cm³, although lesser and greater dopant concentrations can also be employed. The doped semiconductor material can be, for example, doped polysilicon.

Each remaining portion of the semiconductor channel material layer 60L constitutes a vertical semiconductor channel 60 through which electrical current can flow when a vertical NAND device including the vertical semiconductor channel 60 is turned on. Each adjoining set of a blocking dielectric layer 52, a memory material layer 54, and an optional dielectric liner 56 collectively constitute a memory film 50, which can store electrical charges with a macroscopic retention time. As used herein, a macroscopic retention time refers to a retention time suitable for operation of a memory device as a permanent memory device such as a retention time in excess of 24 hours.

Each combination of a memory film 50 and a vertical semiconductor channel 60 within a memory opening 49 constitutes a memory stack structure 55. The memory stack structure 55 is a combination of a vertical semiconductor channel 60, an optional dielectric liner 56, a plurality of memory elements comprising portions of the memory material layer 54, and an optional blocking dielectric layer 52. Each combination of a memory stack structure 55, a dielectric core 62, and a drain region 63 within a memory opening 49 constitutes a memory opening fill structure 58.

Thus, the memory opening fill structures 58 can be formed in each of the cavities formed by removal of vertical stacks of sacrificial memory opening fill structures (147, 247) or. Each of the memory opening fill structures 58 comprises a respective vertical stack of memory elements and a respective vertical semiconductor channel 60. Generally, the memory openings 49 can be laterally spaced from the dielectric material strips (142S, 242S), and can be filled with a respective memory opening fill structure 58 that includes a respective vertical stack of memory elements and a respective vertical semiconductor channel 60.

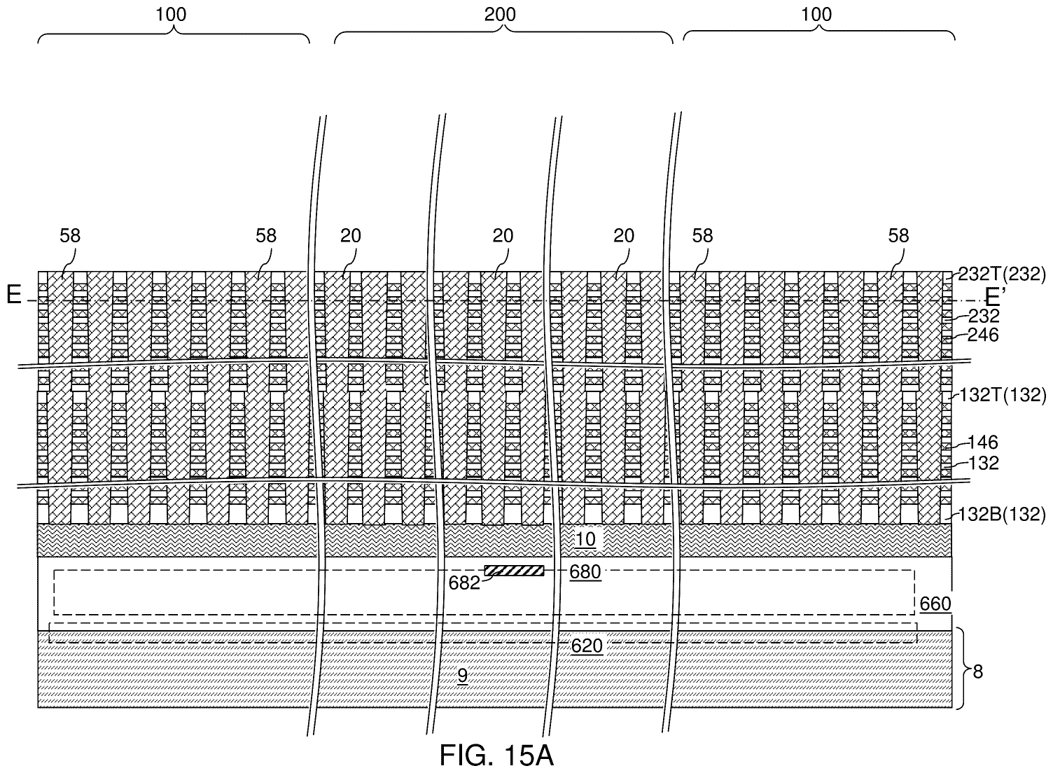

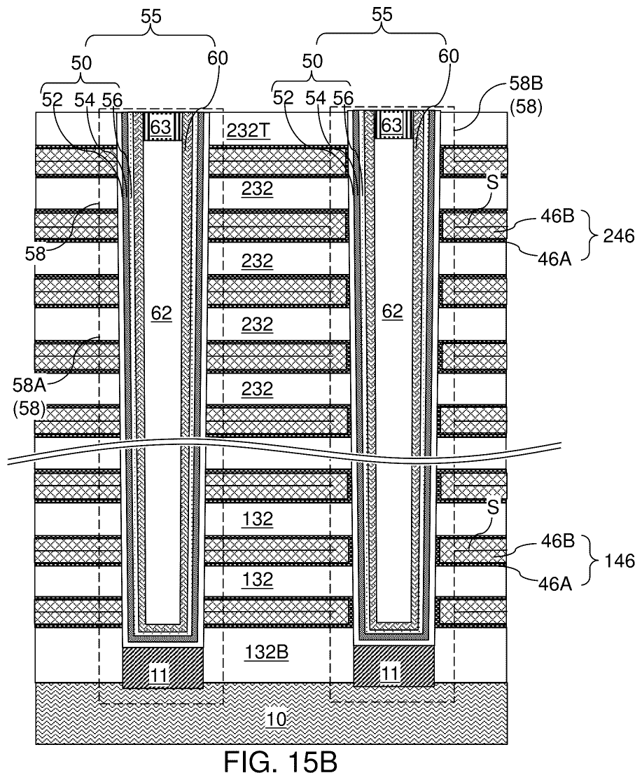

Referring to FIG. 15A, the first exemplary structure is illustrated after formation of the memory opening fill structures 58. The memory opening fill structures formed in the support openings 29 in the contact region 200 comprise support pillar structures 20. The support pillar structures 20 May comprise dummy (i.e., electrically inactive) memory opening fill structures having the same structure as the memory opening fill structures 58. Alternatively, the support openings may be filled entirely with a dielectric material and the support pillar structures 20 comprise dielectric pillars.

FIG. 15B is a close up of a region of FIG. 15A showing the locations of the seams S. In one embodiment, each of the electrically conductive layers (146, 246) comprises a respective laterally-extending seam S (e.g., lateral grain boundary). A first subset 58A of the memory opening fill structures 58 is in direct contact with a respective subset of the seams S of the electrically conductive layers (146, 246). The first subset 58A of the memory opening fill structures 58 is formed in the first subset (e.g., first rows) of memory openings 49 that are used to form the electrically conductive layers (146, 246) in the step shown in FIGS. 9A-9G.

A second subset 58B of the memory opening fill structures 58 is not in direct contact with any seam S of the seams S of the electrically conductive layers (146, 246). The second subset 58B of the memory opening fill structures 58 is formed in the second subset (e.g., second rows) of memory openings 49 that are filled with the sacrificial memory opening fill structures (147, 247) during formation of the electrically conductive layers (146, 246) in the step shown in FIGS. 9A-9G. In one embodiment, the first subset 58A of the memory opening fill structures 58 is located within first rows of the memory openings 49 that laterally extend along the first horizontal direction hd1; the second subset 58B of the memory opening fill structures 58 is located within second rows of the memory openings 49 that laterally extend along the first horizontal direction hd1; and the first rows and the second rows are interlaced along a second horizontal direction hd2 that is perpendicular to the first horizontal direction hd1.

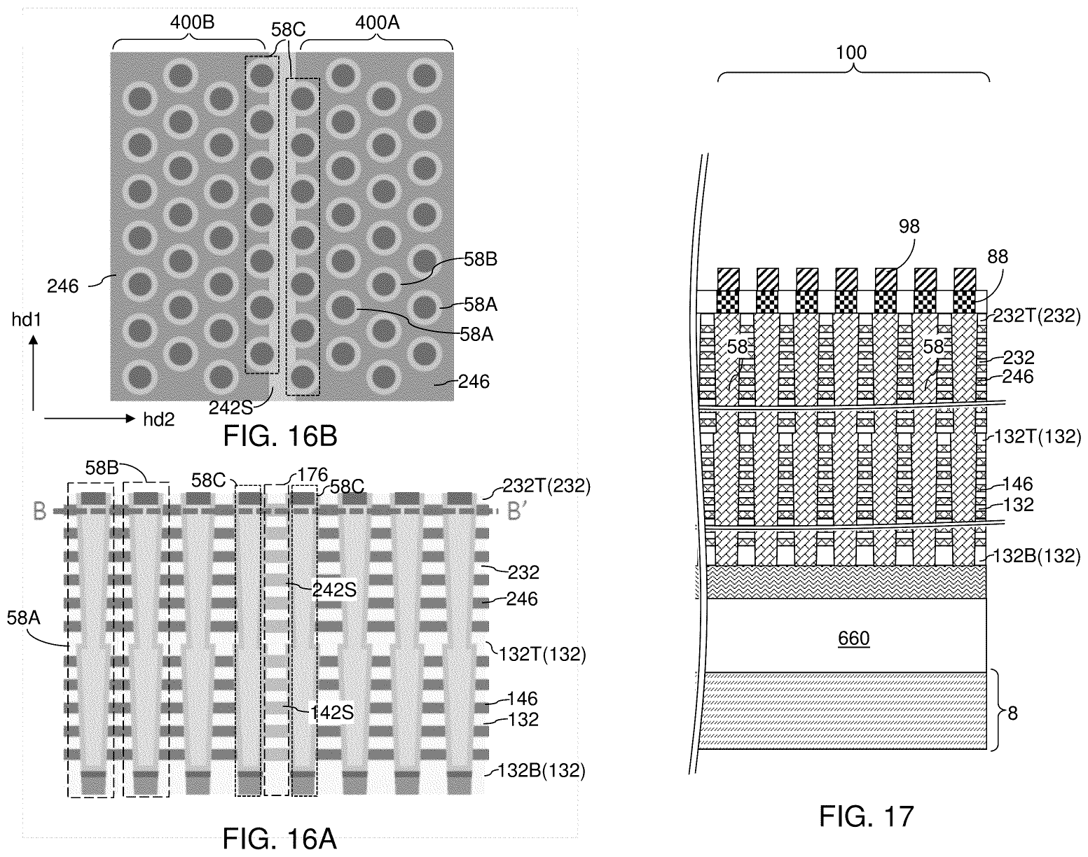

FIG. 16A is a vertical cross-sectional view of a portion of the first exemplary structure of FIG. 15A including the dielectric wall structure 176 which separates adjacent memory blocks along the second horizontal direction hd2. FIG. 16B is a top-down view of the exemplary structure of FIG. 16A along horizontal plane B-B′ FIG. 16A.

In the first embodiment, a third subset 58C of the memory opening fill structures 58 are located in the isolation openings 79 adjacent to the dielectric material strips (142S, 242S). In one embodiment, the third subset 58C of the memory opening fill structures 58 comprises active memory opening fill structures which are configured to store data. In another embodiment, the third subset 58C of the memory opening fill structures 58 comprise dummy (i.e., electrically inactive) memory opening fill structures which are not configured to store data during operation of the memory device.

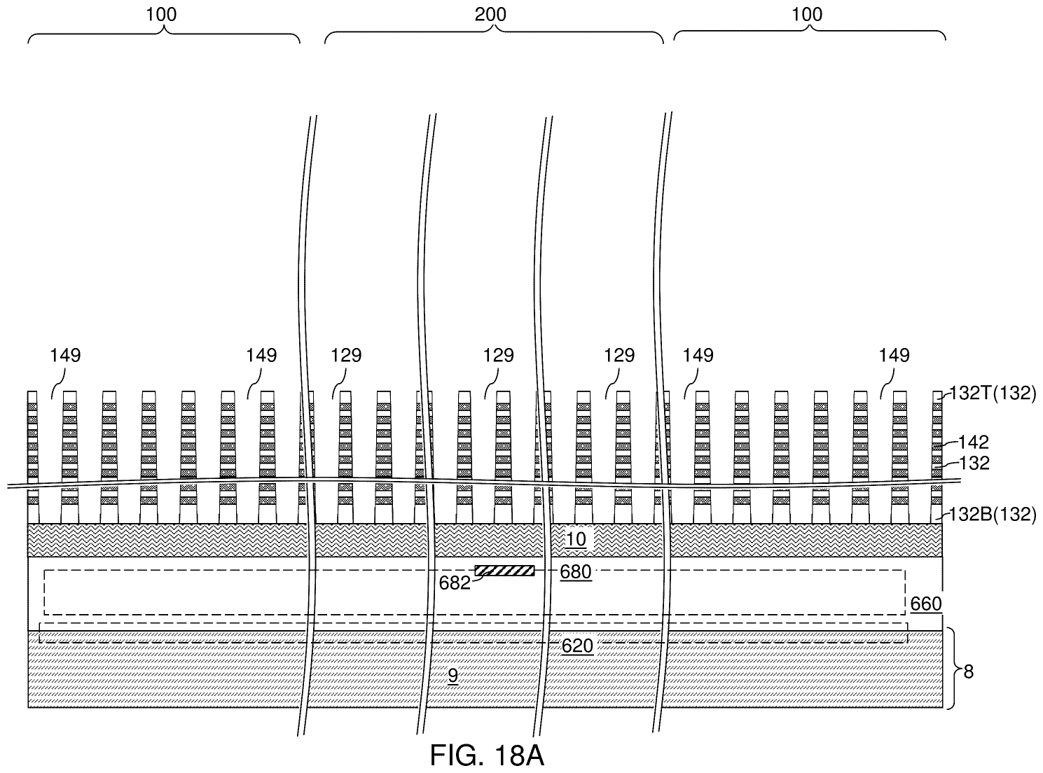

Referring to FIG. 17, additional contact via structures such as drain contact via structures 88 can be formed. The drain contact via structures 88 can contact a top surface of a respective drain region 63 of the memory opening fill structures 58. Bit lines 98 are formed in electrical contact with the drain contact via structures 88 in the memory array regions 100. Furthermore, select gate and word line contact via structures (not shown) may be formed in contact with the electrically conductive layers (146, 246) in the contact region 200. The electrically conductive layers (146, 246) may form a staircase having stepped surfaces in the contact region 200, and the contact via structures contact the respective horizontal surface of each step in the contact region. Alternatively, the contact via structures may comprise laterally insulating contact via structures which extend through a subset of electrically conductor layers and contact a respective one of the electrically conductive layers. In this case, the staircase may be omitted.

Subsequently, additional metal interconnect structures (not shown) embedded in additional dielectric material layers (not shown) can be formed. The additional metal interconnect structures may be referred to as upper-level metal interconnect structures or memory-side metal interconnect structures. Bonding pads (which may be referred to as memory-side bonding pads) may be formed at the topmost level of the dielectric material layers. Optionally, a logic die including a peripheral circuit configurated to control operation of the three-dimensional memory array in the first exemplary structure and logic-side bonding pads may be provided. In this case, the logic-side bonding pads may be bonded to the memory-side bonding pads, for example, by metal-to-metal bonding. In case the lower-level dielectric material layers 660 and the semiconductor material layer 10 are omitted, the substrate 8 may be removed to expose a bottom surface of the bottommost first insulating layer 132B, and a source layer (i.e., top source contact) can be formed on the bottom side of the alternating stack {(132, (146, 142S), (232, (246, 242S))}.

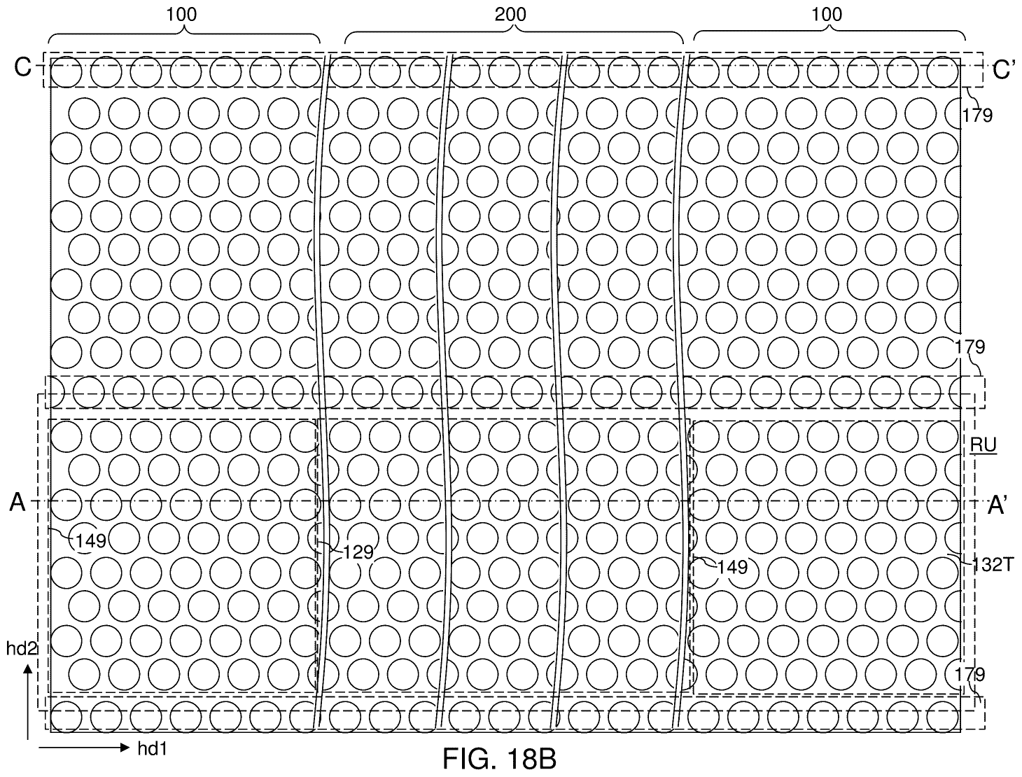

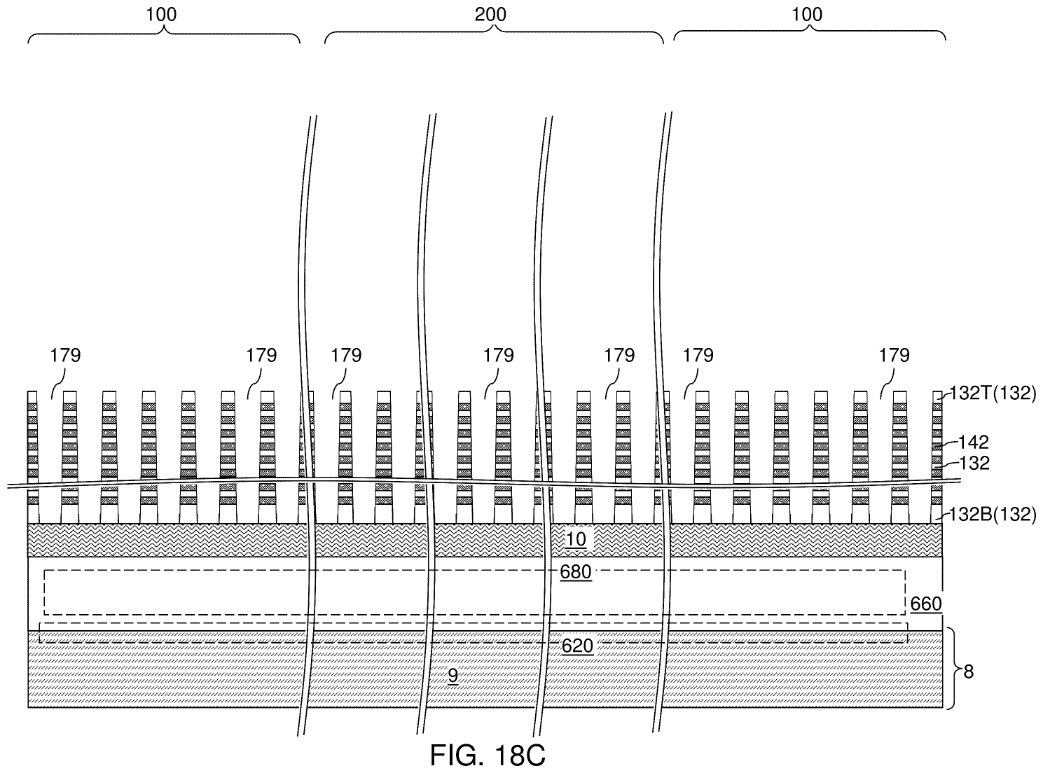

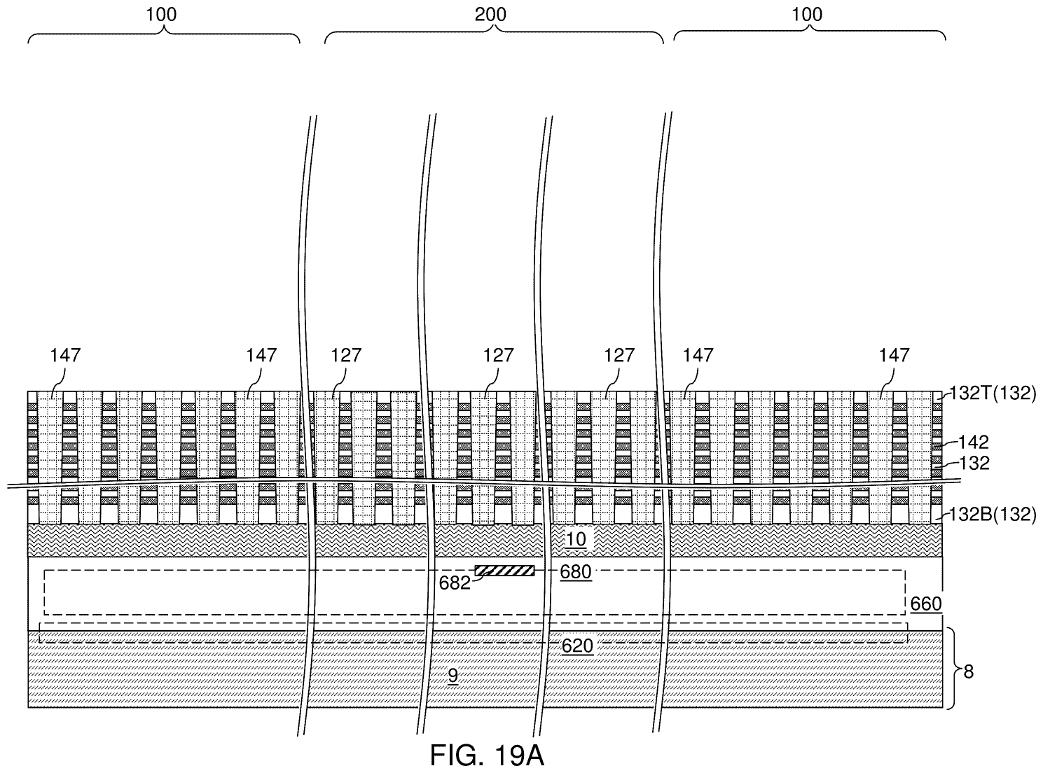

Referring to FIGS. 18A-18C, a second exemplary structure according to the second embodiment of the present disclosure can be derived from the first exemplary structure illustrated in FIGS. 2A-2C by altering the layout of the first-tier openings (149, 129, 179). Specifically, each repetition unit RU may comprise one row of first isolation openings 179. Optionally, each row of first isolation openings 179 may be laterally spaced from neighboring rows of first memory openings 149 and first support openings 129 by a greater distance than lateral spacing between neighboring rows of first memory openings 149 and first support openings 129.

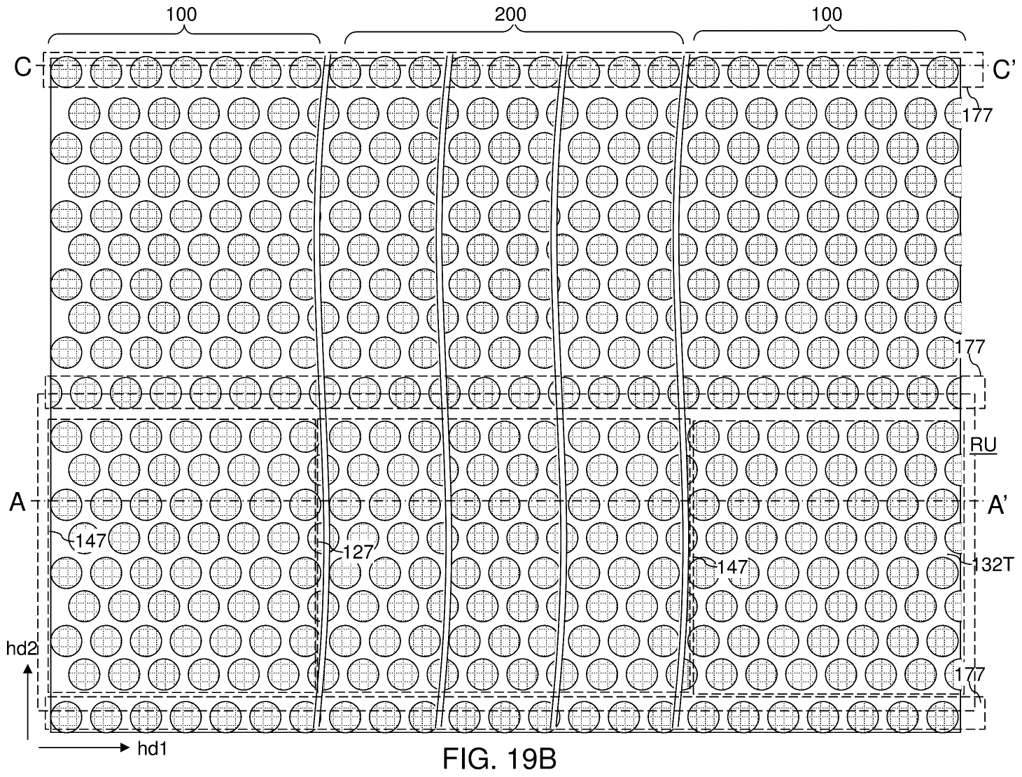

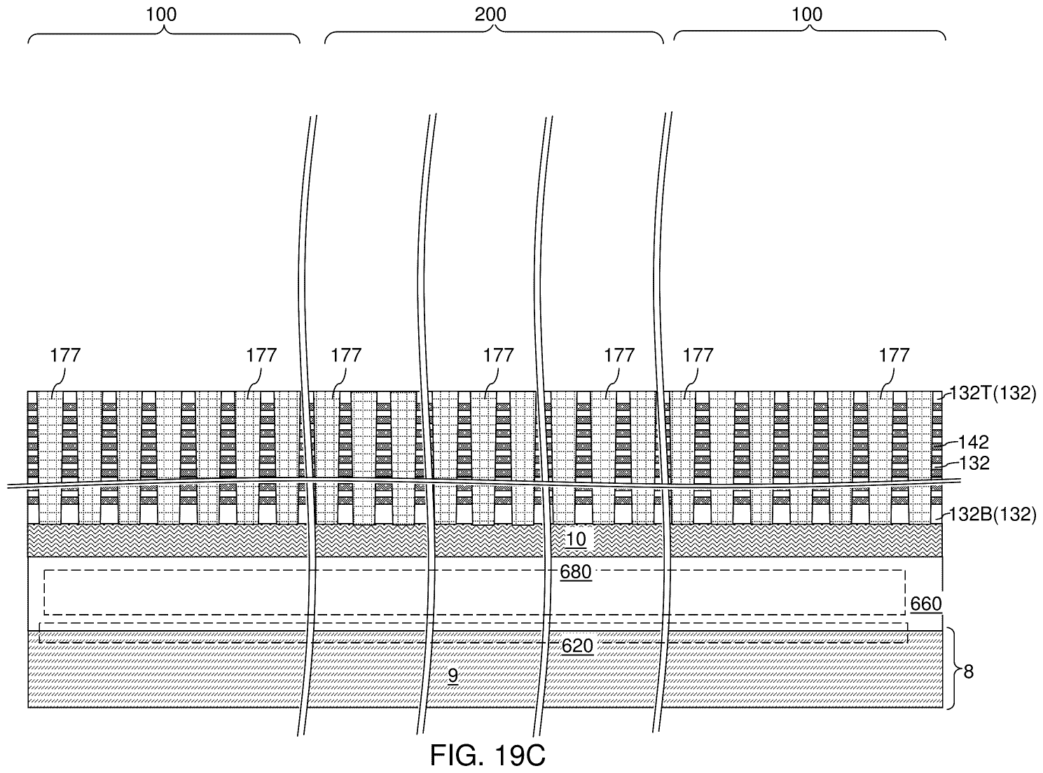

Referring to FIGS. 19A-19C, the processing steps described with reference to FIGS. 3A-3C can be performed to form various first-tier sacrificial opening fill structures (147, 127, 177).

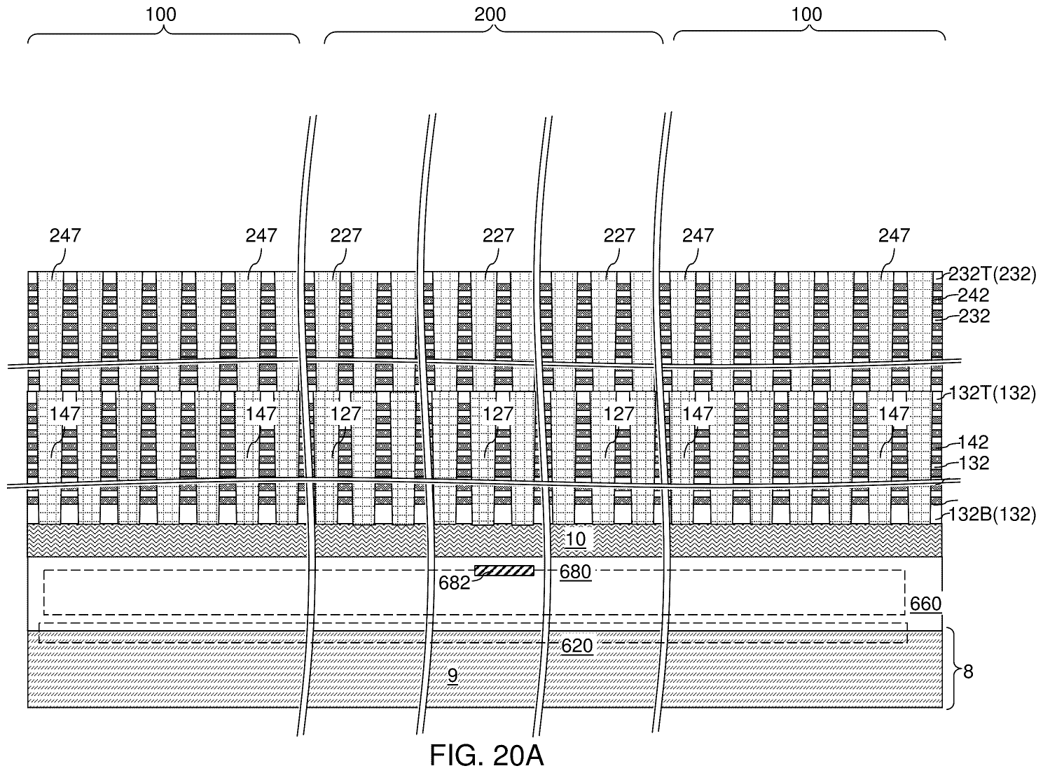

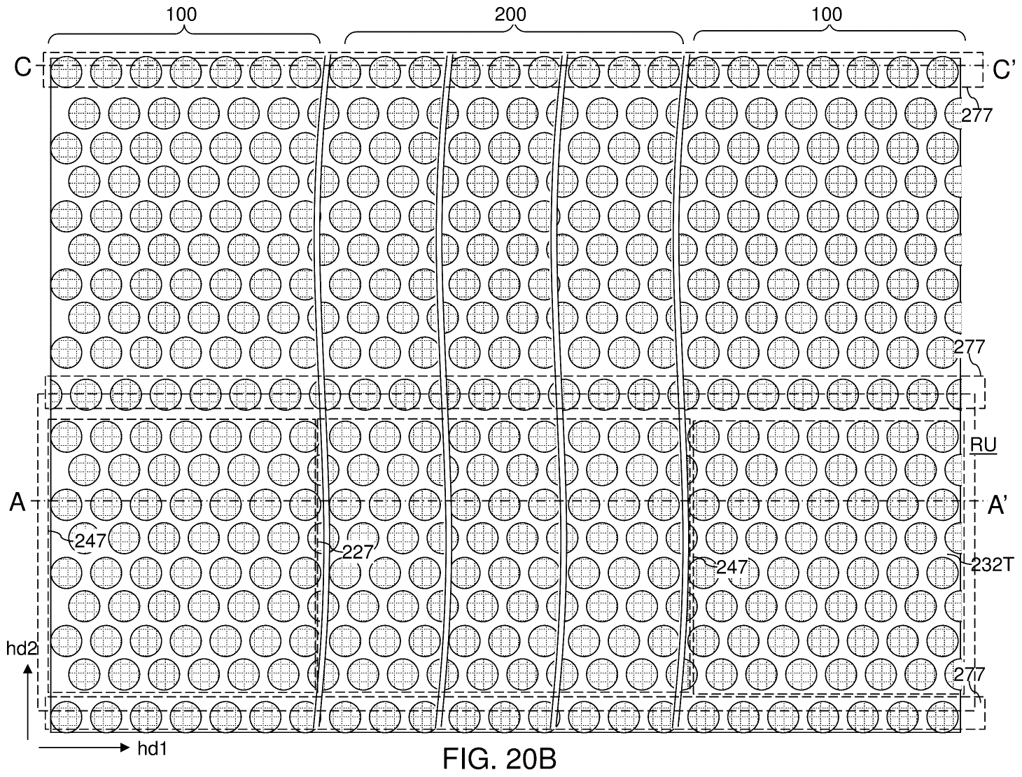

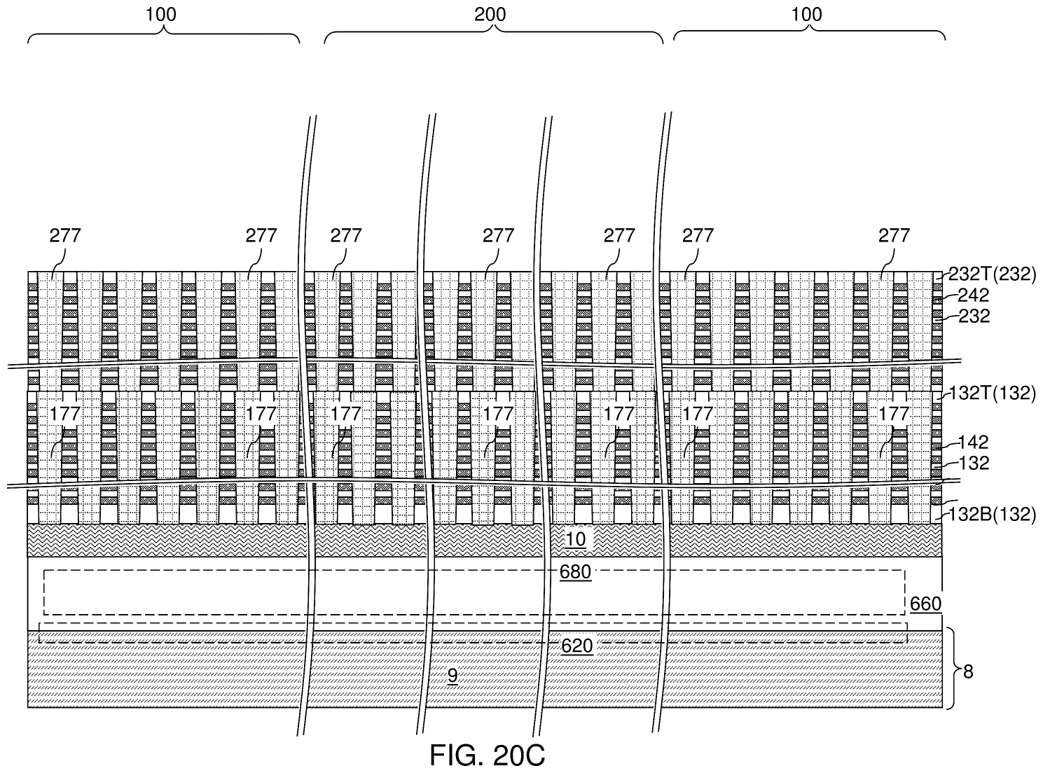

Referring to FIGS. 20A-20C, the processing steps described with reference to FIGS. 4A-4C can be performed to form a second alternating stack of second insulating layers 232 and second sacrificial material layers 242, second-tier openings, and second-tier sacrificial opening fill structures (247, 227, 277).

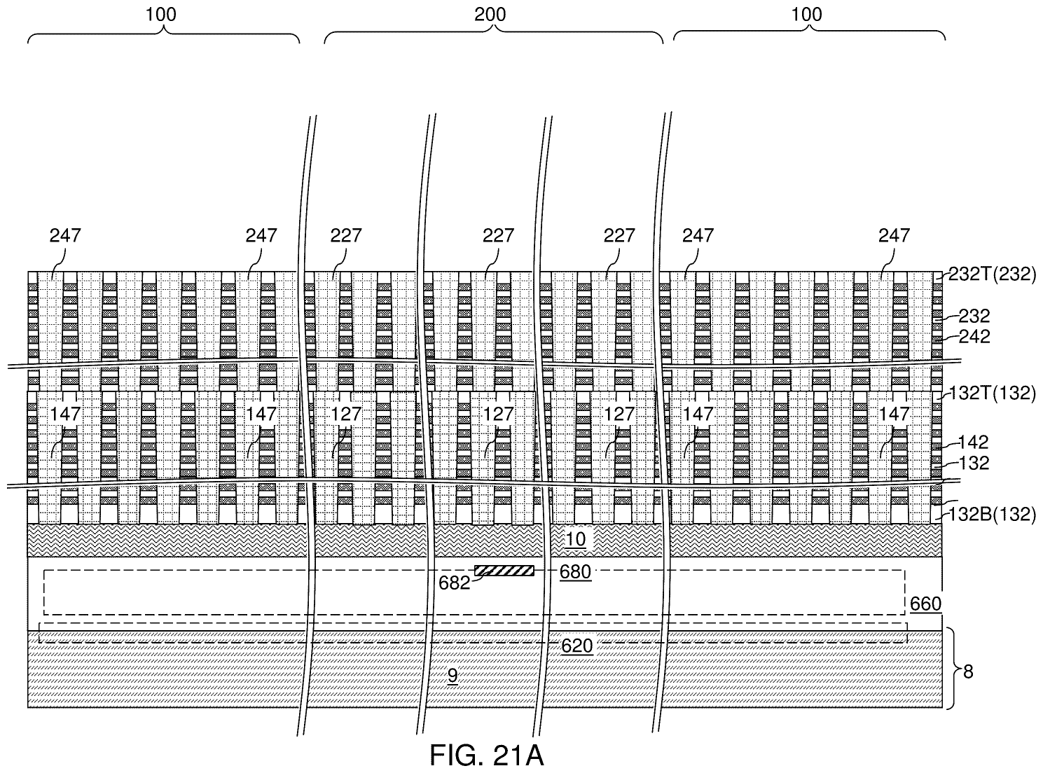

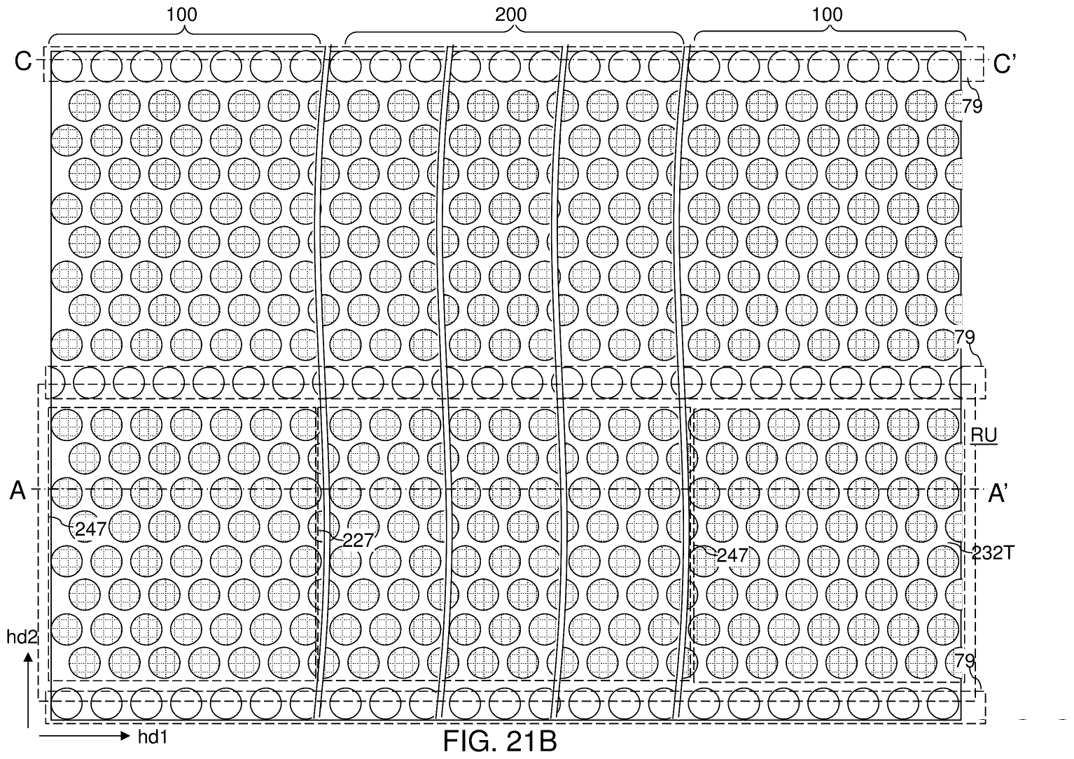

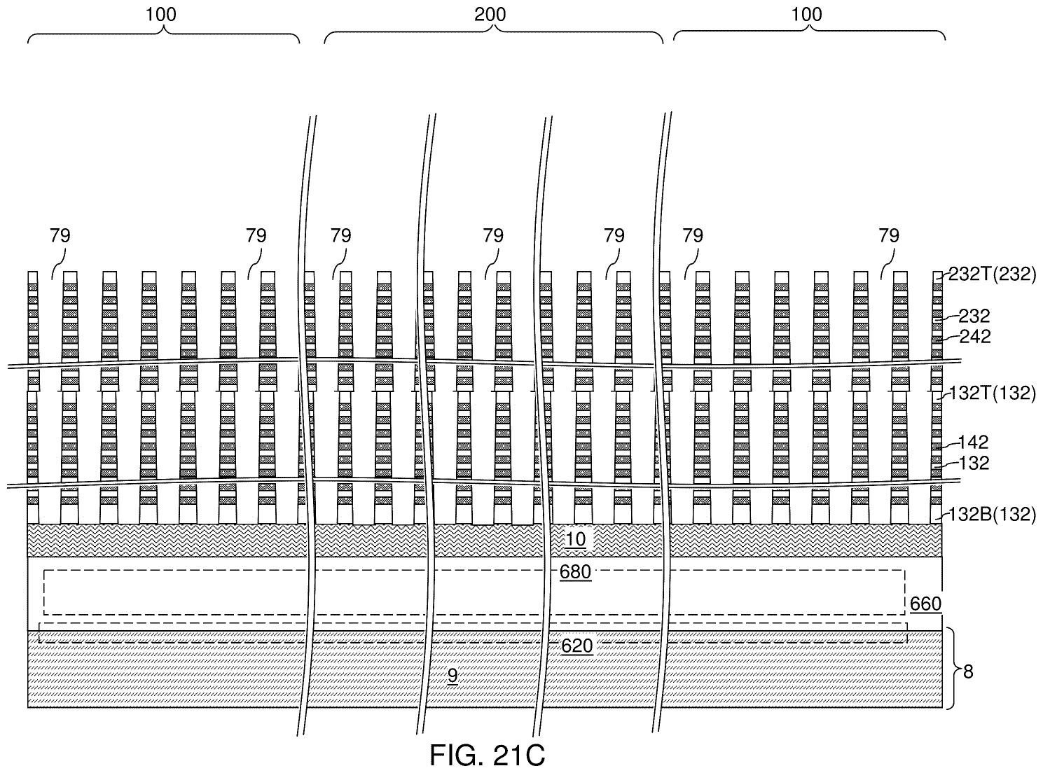

Referring to FIGS. 21A-21C, a photoresist layer (not shown) and optional hard mask layer can be applied over the second alternating stack (232, 242), and can be lithographically patterned to form openings over the second sacrificial isolation opening fill structures 277. A selective etch process can be performed to remove the sacrificial fill materials of the sacrificial isolation opening fill structures (177, 277) selective to the materials of the alternating stacks {(132, 142), (232, 242)}. Inter-tier isolation openings 79, which are also referred to isolation openings 79, are formed in volumes from which the sacrificial isolation opening fill structures (177, 277) are removed. The photoresist layer can be subsequently removed, for example, by ashing. The hard mask layer, if present, can be removed by selective etching.

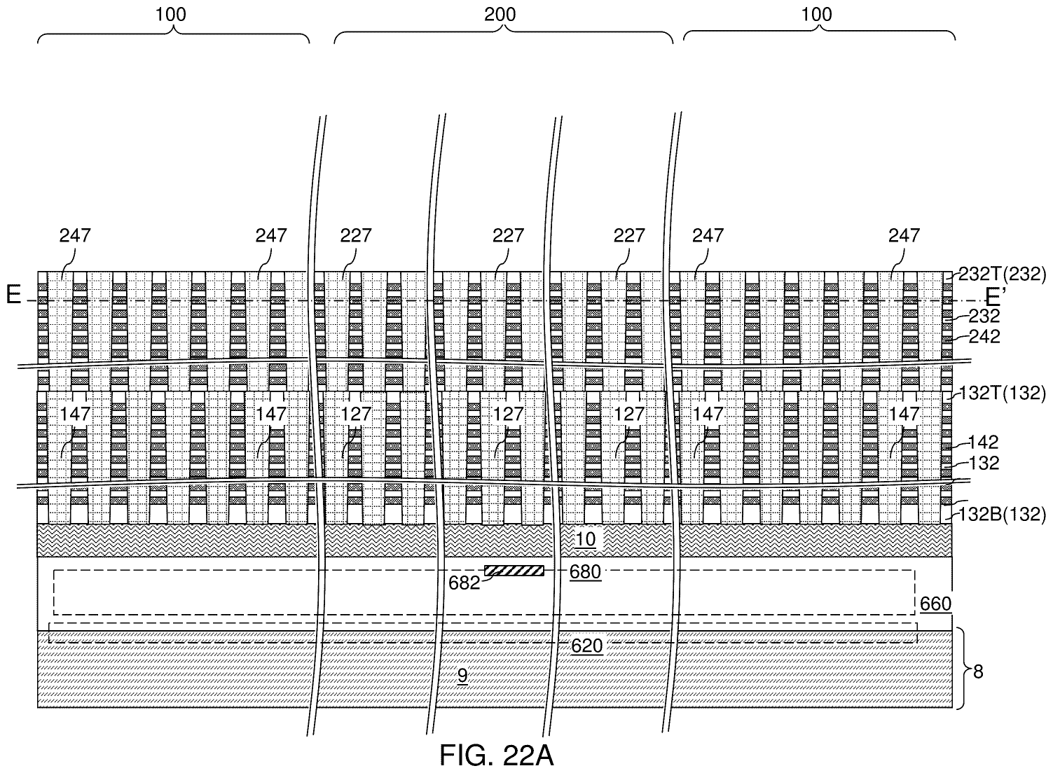

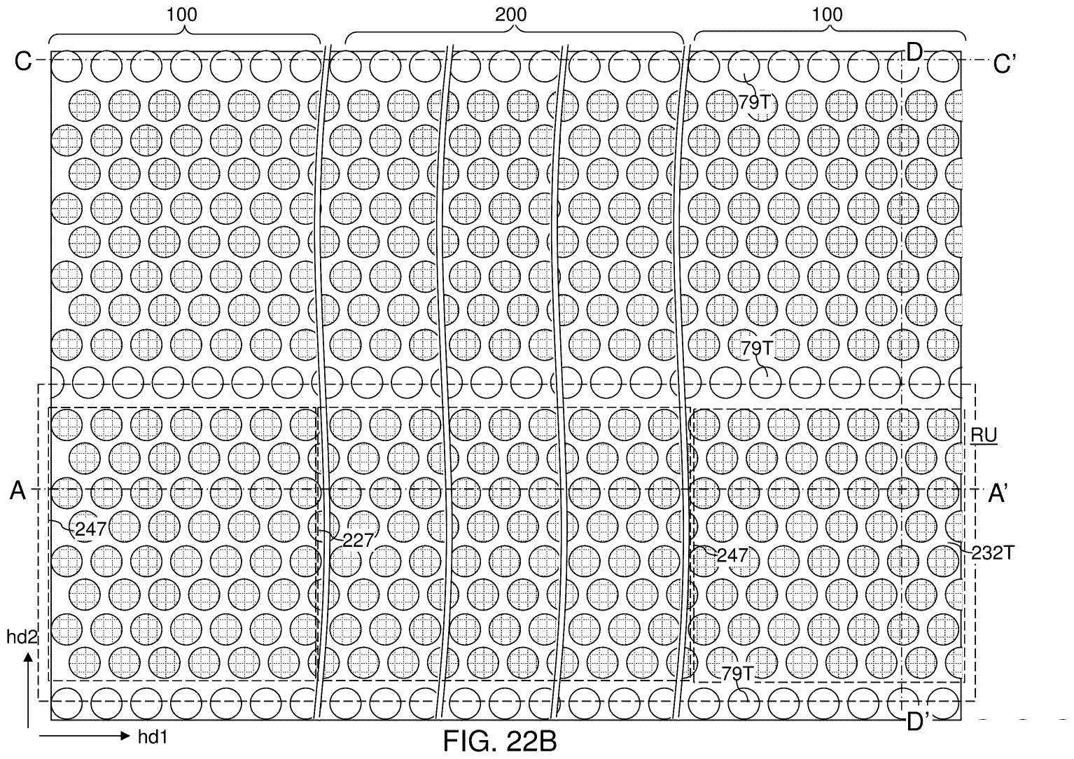

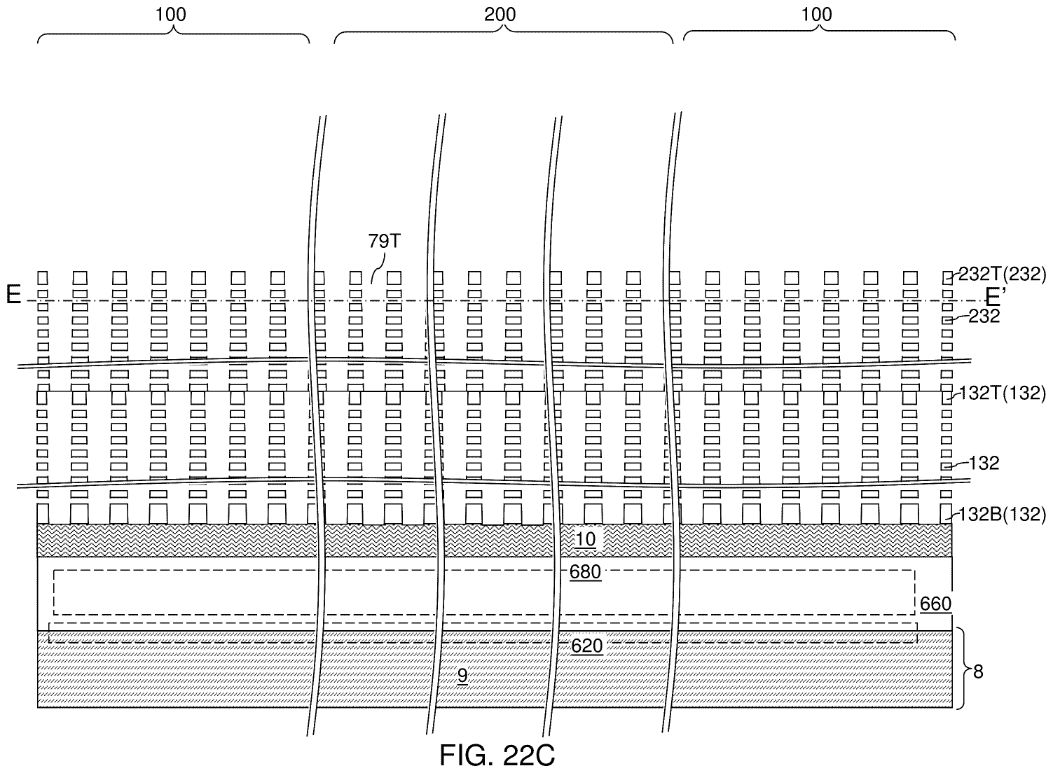

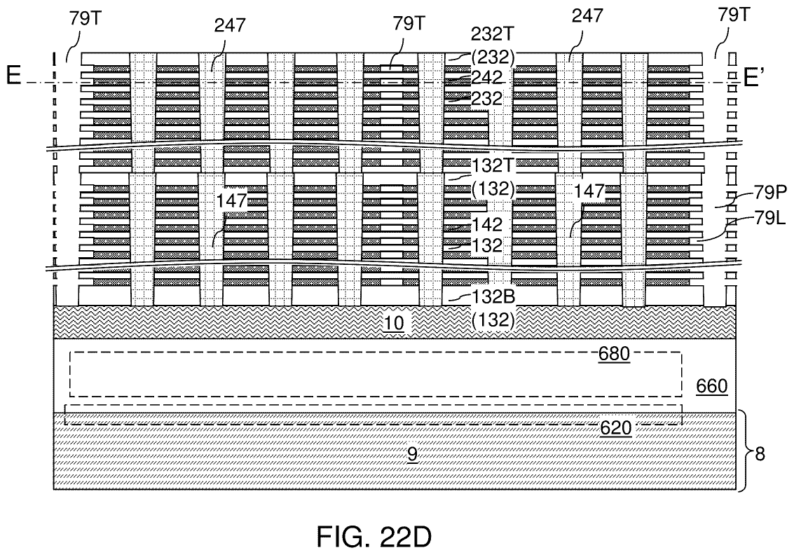

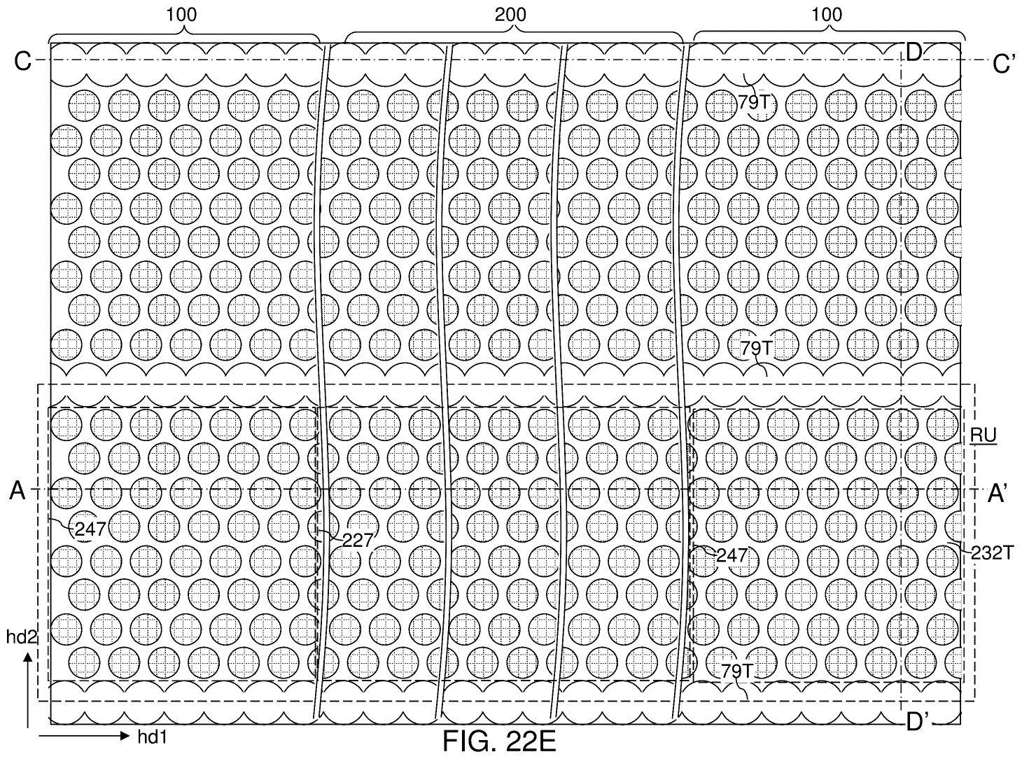

Referring to FIGS. 22A-22E, the isolation openings 79 can be isotropically laterally expanded at each level of the sacrificial material layers (142, 242) by performing an isotropic etch process that etches the materials of the sacrificial material layers (142, 242) selective to the materials of the insulating layers (132, 232), as shown in FIG. 22E. For example, if the sacrificial material layers (142, 242) comprise silicon nitride and if the insulating layers (132, 232) comprise silicon oxide, a wet etch process employing hot phosphoric acid can be performed to isotropically recess the sacrificial material layers (142, 242) around the isolation openings 79. The duration of the isotropic etch process can be selected such that laterally-expanded portions of the isolation openings 79 merge within each row of isolation openings 79 to form a respective interconnected isolation cavity 79T. In one embodiment, the duration of the isotropic etch process can be selected such that the sacrificial memory opening fill structures (147, 247) and the sacrificial support opening fill structures (127, 227) are not exposed to the interconnected isolation cavities 79T.

As shown in FIG. 22D, each interconnected isolation cavity 79T may comprise a respective vertically alternating sequence of laterally-extending cavities 79L and rows of pillar cavities 79P that are interlaced along a vertical direction. Each laterally-extending cavity 79L is located at a level of a respective one of the sacrificial material layers (142, 242). Each laterally-extending cavity may be laterally bounded by vertically-straight and laterally-concave surface segments of a respective pair of the sacrificial material layers (142, 242). Each laterally-extending cavity 79L may laterally extend along the first horizontal direction hd1, and may have a lateral undulation in a width along the second horizontal direction hd2. Each row of pillar cavities 79P may be located at a level of a respective one of the insulating layers (132, 232). Each row of pillar cavities 79P may be arranged along the first horizontal direction hd1.

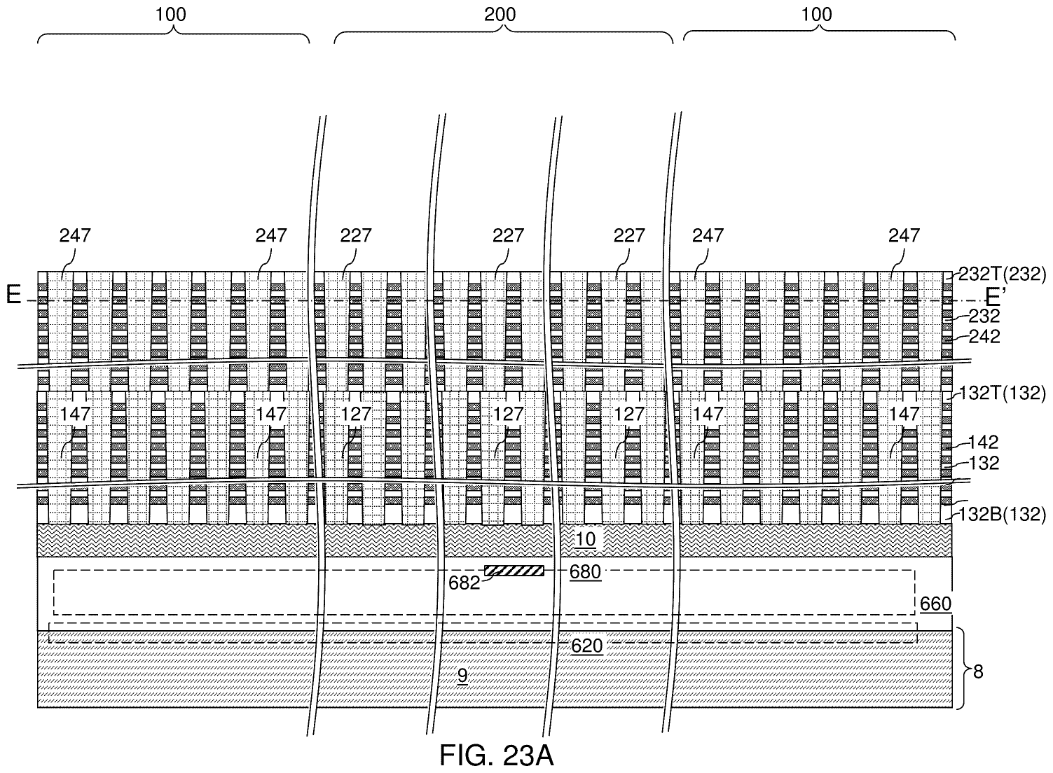

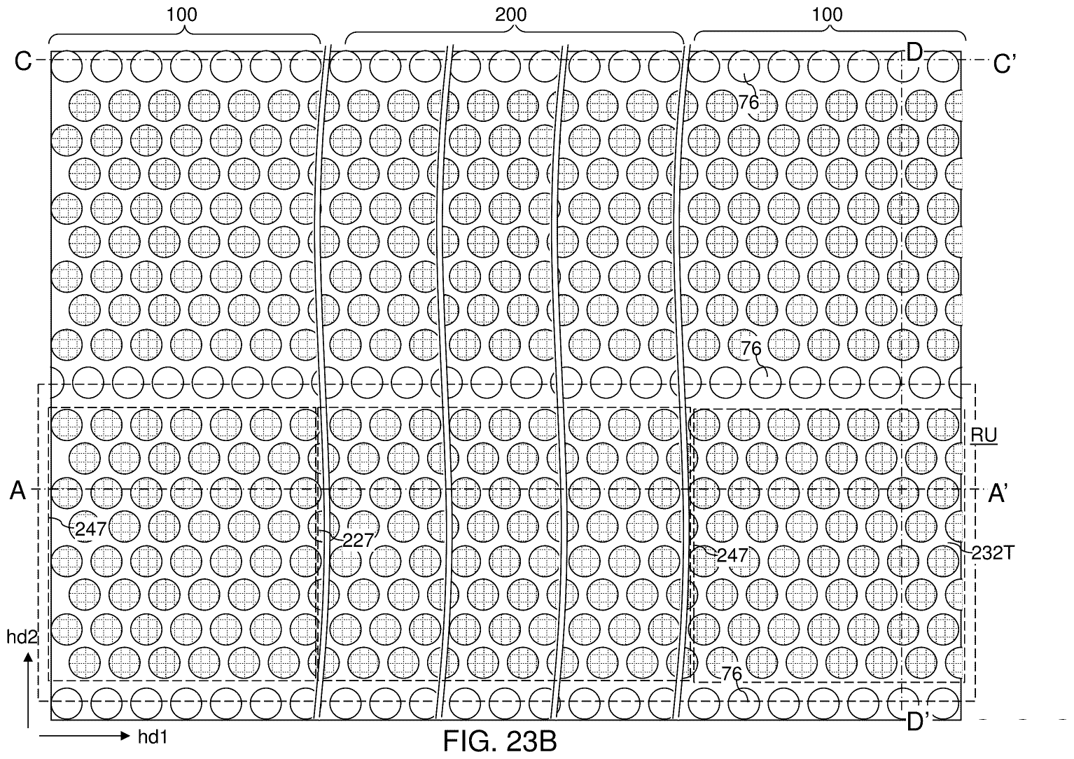

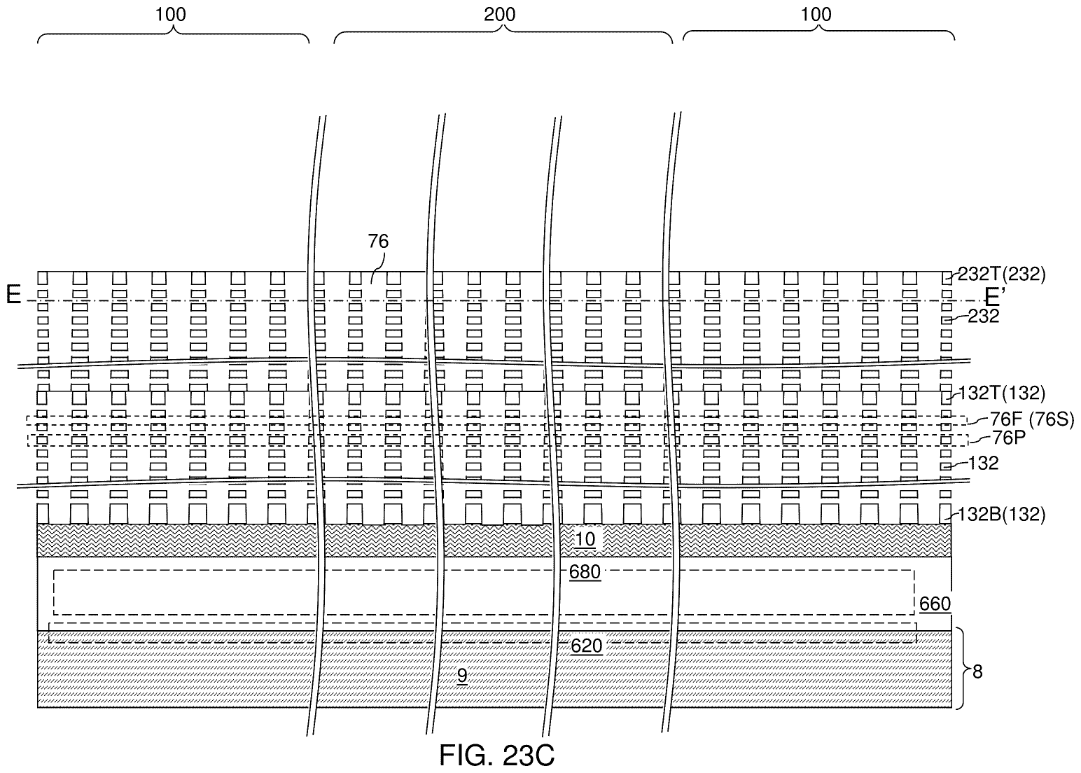

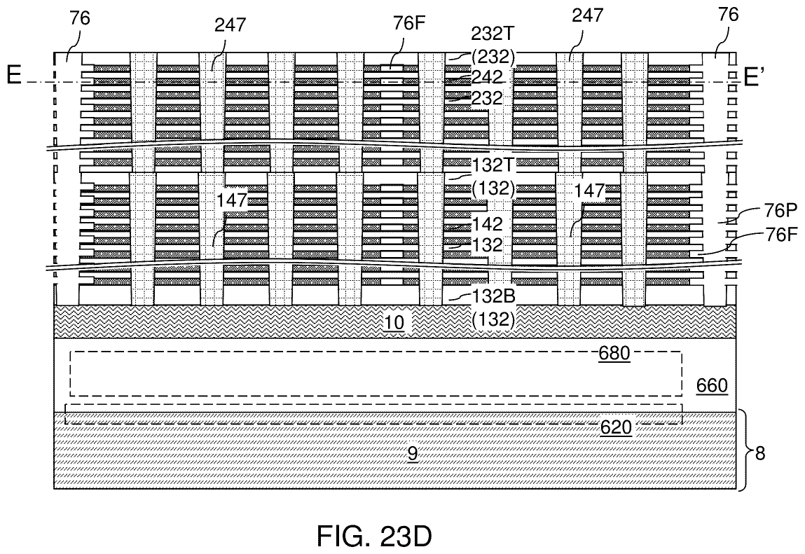

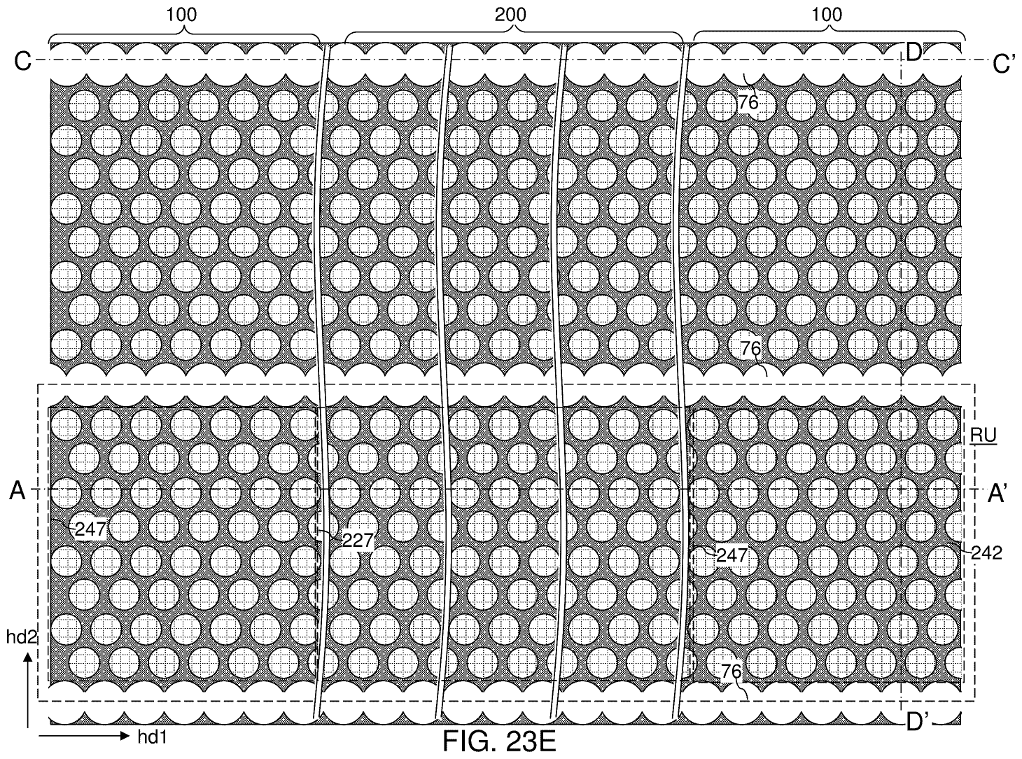

Referring to FIGS. 23A-23E, at least one dielectric fill material, such as silicon oxide, may be conformally deposited in the interconnected isolation cavities 79T. Excess portions of the at least one dielectric fill material can be removed from above the horizontal plane including the top surface of the topmost second insulating layer 232T by a planarization process such as a recess etch process and/or a chemical mechanical polishing process. Each remaining portion of the at least one dielectric fill material that fills a respective interconnected isolation cavity 79T constitutes a dielectric wall structure including a pillar containing laterally protruding fins. Thus, each remaining portion of the at least one dielectric fill material that fills a respective interconnected isolation cavity 79T is herein referred to as a finned dielectric wall structure 76.

Each of the finned dielectric wall structures 76 comprises a row of insulating pillars 76P contains laterally protruding fins 76F that are separated from each other along a vertical direction. The insulating fins 76F are adjoined to each other to form a continuous horizontal dielectric material strip 76S that extends along the first horizontal direction hd1, as shown in FIG. 23C. The fins 76F that make up the dielectric material strip 76S protrude away from the insulating pillars 76P along the second horizontal direction hd2, as shown in FIGS. 23D and 23E, and contact a set of vertically-straight and laterally-concave surface segments of a respective one of the sacrificial material layers (142, 242). Each laterally neighboring pair of the sacrificial material layers (142, 242) located at a same level can be laterally spaced apart from each other along the second horizontal direction hd2 by a respective one of the finned dielectric wall structures 76. In one embodiment, each of the finned dielectric wall structures 76 continuously extends from a bottommost surface of the alternating stack {(132, 142), (232, 242)} to a topmost surface of the alternating stack {(132, 142), (232, 242)}.

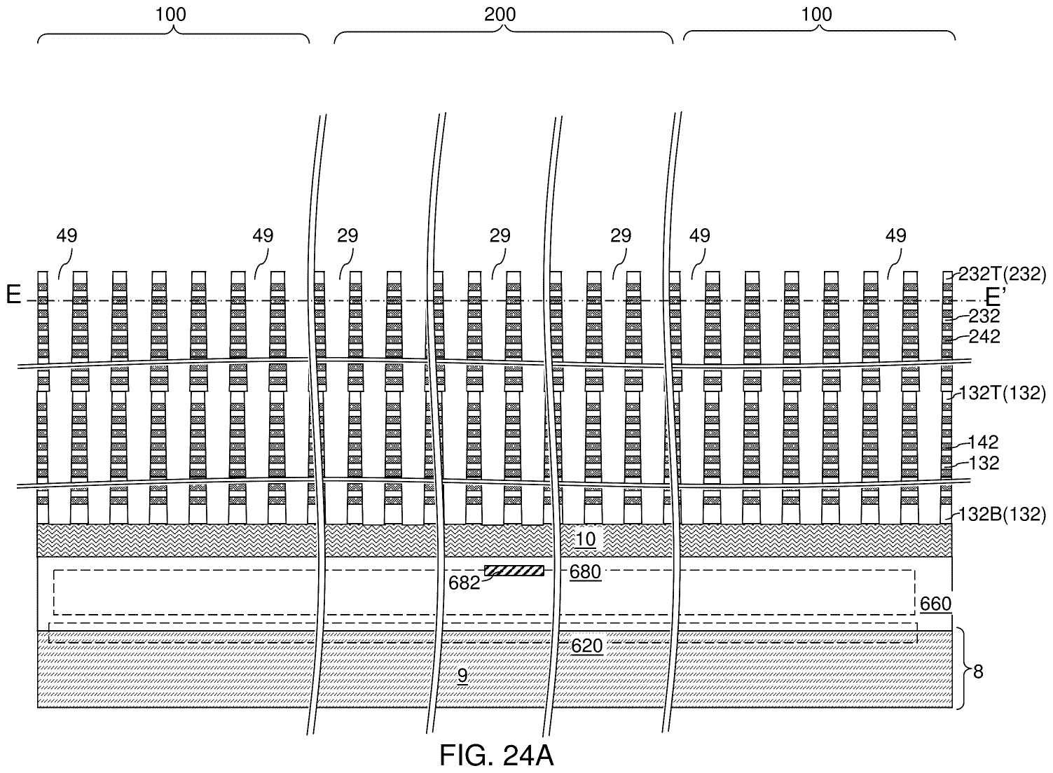

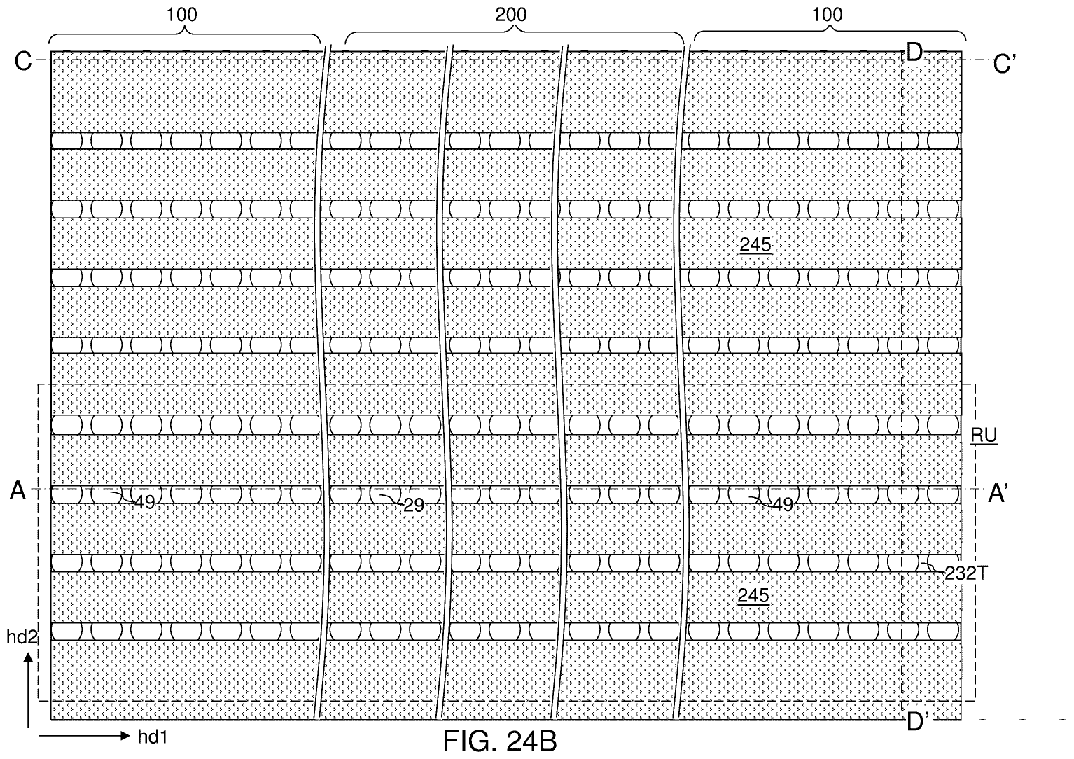

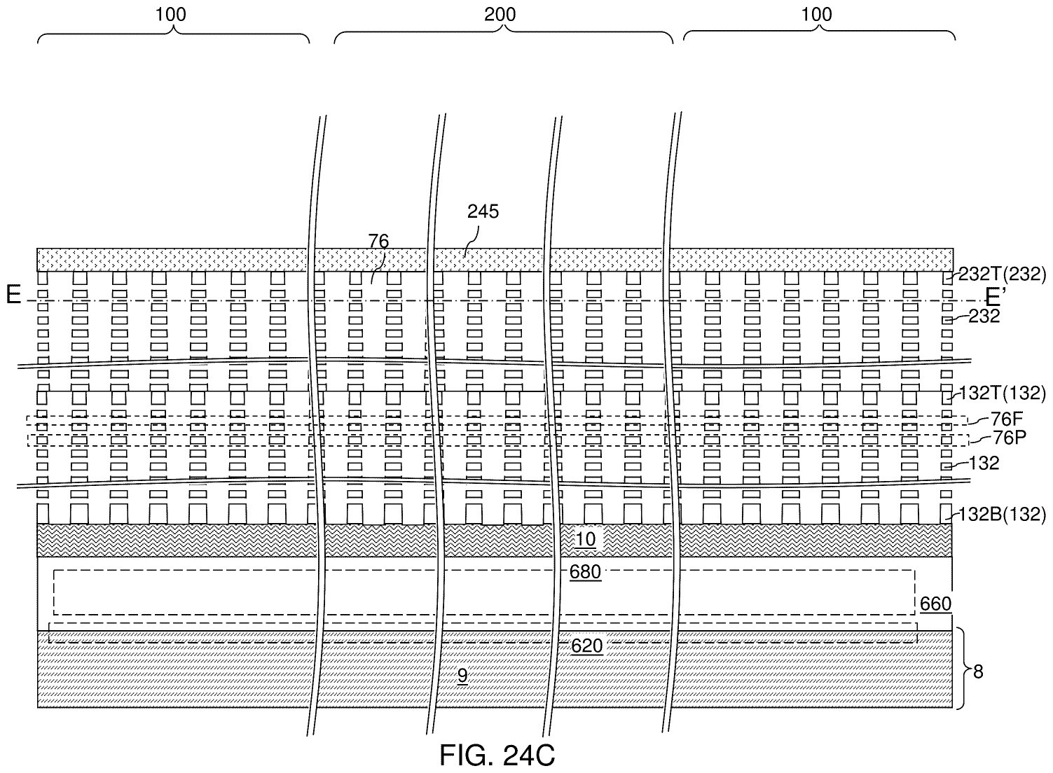

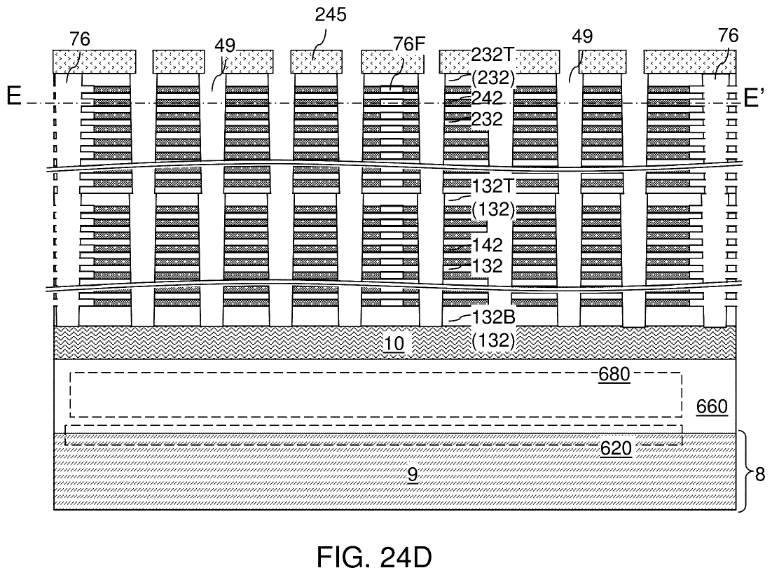

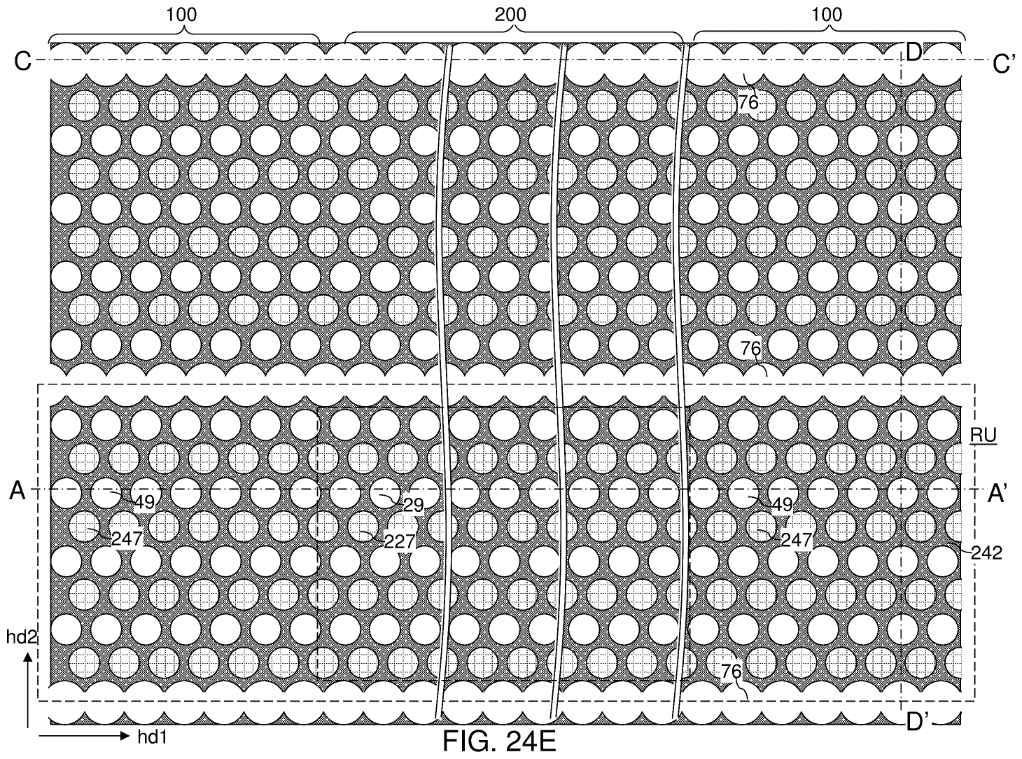

Referring to FIGS. 24A-24E, an etch mask layer 245 can be formed over the second alternating stack (232, 242), and can be patterned into discrete strips. The processing steps described with reference to FIGS. 5 and 6A-6C may be performed with a modification in the pattern of the patterned etch mask layer 245. The finned dielectric wall structures 76 can be covered by a respective patterned portion of the etch mask layer 245. In one embodiment, a first subset of rows of second sacrificial memory opening fill structures 247 and second sacrificial support opening fill structures 227 located between respective neighboring sets of finned dielectric wall structures 76 can be covered by a respective subset of the patterned portions of the etch mask layer 245, i.e., a respective set of etch mask strips that are patterned portions of the etch mask layer 245, while a second subset may be exposed through the etch mask layer 245. In one embodiment, each set of second sacrificial memory opening fill structures 247 and second sacrificial support opening fill structures 227 located between respective neighboring pair of finned dielectric wall structures 76 may be arranged in multiple rows that laterally extend along the first horizontal direction hd1 and laterally spaced apart along the second horizontal direction hd2. Each row may comprise multiple second sacrificial memory opening fill structures 247 and multiple second sacrificial support opening fill structures 227.

A first subset of the rows of respective second sacrificial memory opening fill structures 247 and respective second sacrificial support opening fill structures 227 may be covered by a respective strip of the patterned etch mask layer 245, and a second subset of the rows of respective second sacrificial memory opening fill structures 247 and respective second sacrificial support opening fill structures 227 may underlie a gap between a neighboring pair of strips of patterned etch mask layer 245 and by exposed in the patterned etch mask layer 245. In one embodiment, rows in the first subset and rows in the second subset may be interlaced along the second horizontal direction hd1. Thus, upon numbering of rows of second sacrificial memory opening fill structures 247 and second sacrificial support opening fill structures 227 between a respective neighboring pair of rows of second sacrificial isolation opening fill structures 277 with positive integers beginning with 1, odd-numbered rows may be covered by strips of the patterned etch mask layer 245, and even-numbered rows may underlie a gap between neighboring strips of the patterned etch mask layer 245. Alternatively, even-numbered rows may be covered by strips of the patterned etch mask layer 245, and odd-numbered rows may underlie a gap between neighboring strips of the patterned etch mask layer 245.

The processing steps described with reference to FIGS. 7A-7D may be performed to selectively remove subsets of the second sacrificial memory opening fill structures 247, the second sacrificial support opening fill structures 227, the first sacrificial memory opening fill structures 147, and the first sacrificial support opening fill structures 127 that underlie slit-shaped gaps in the patterned etch mask layer 245.

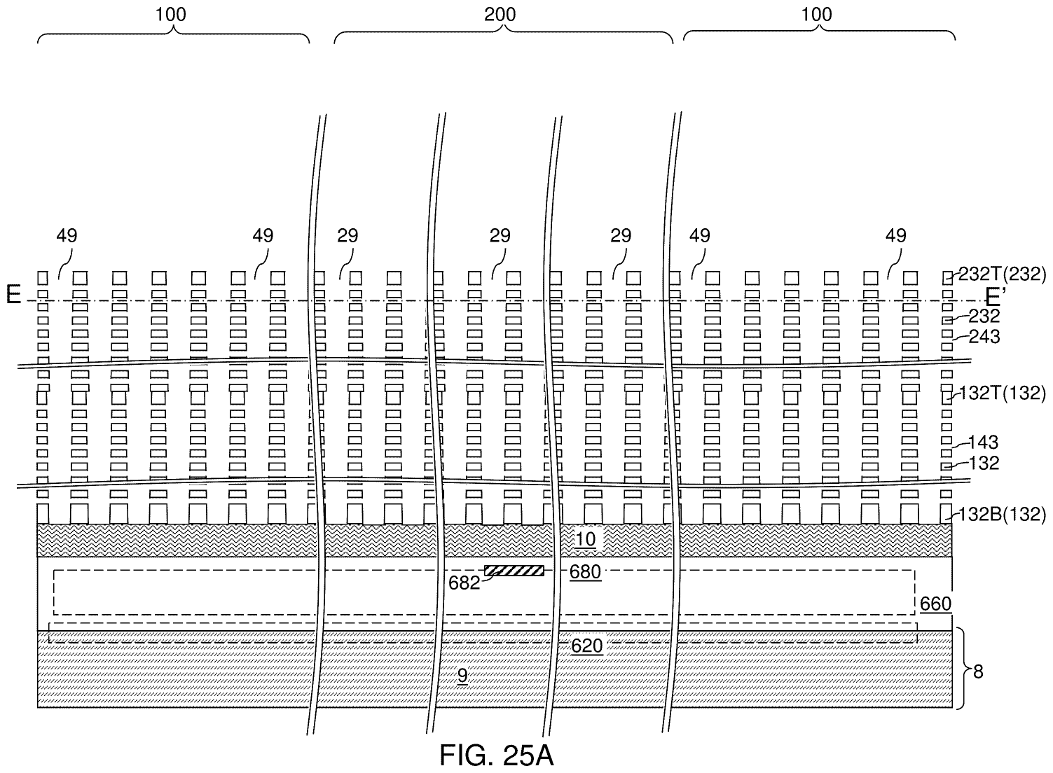

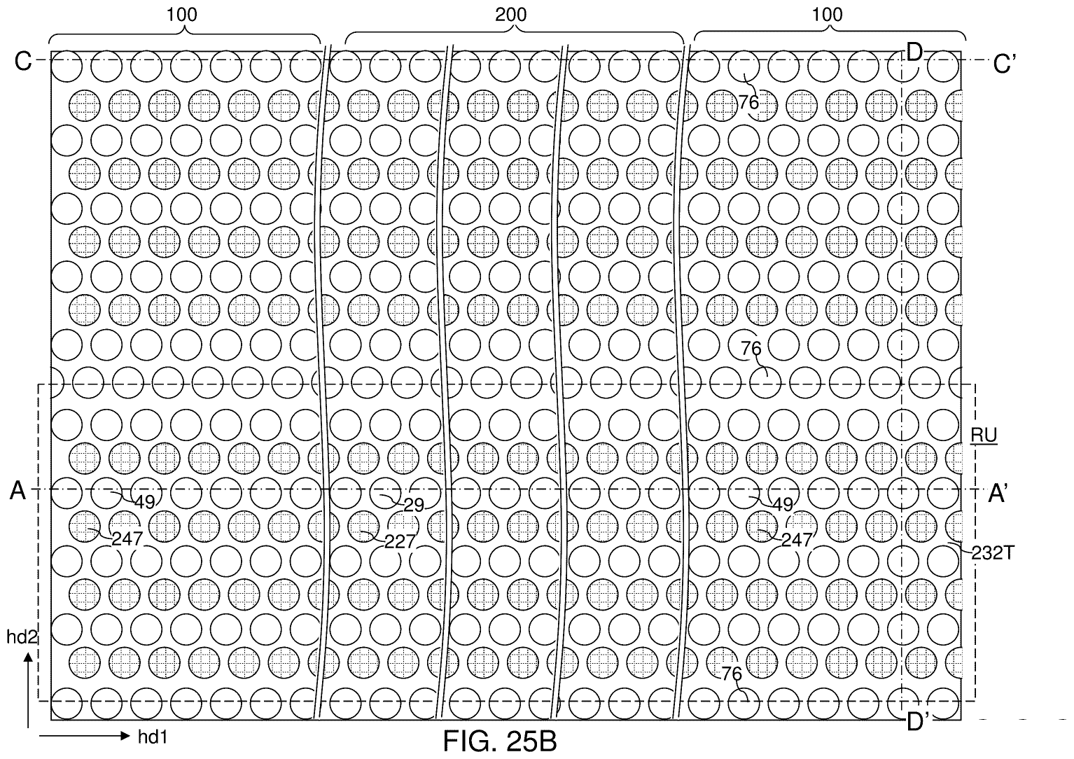

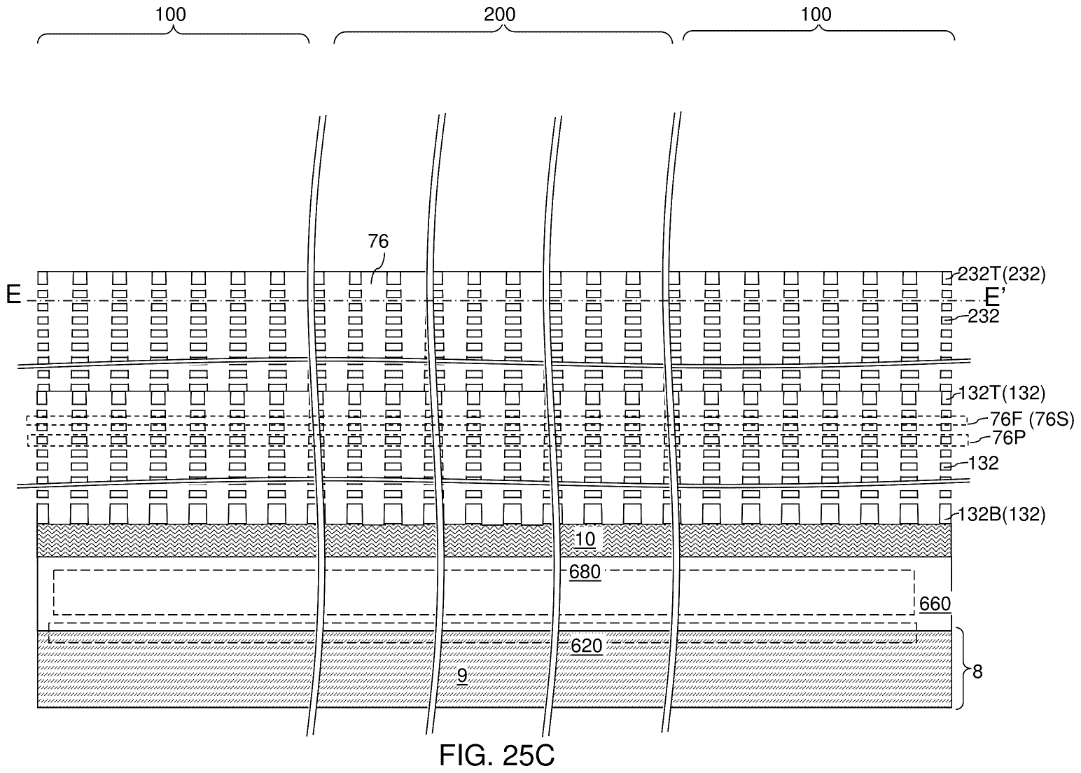

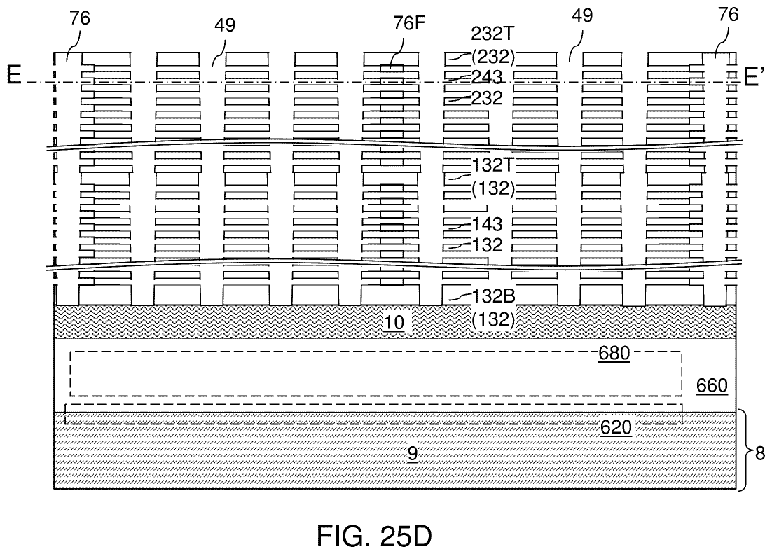

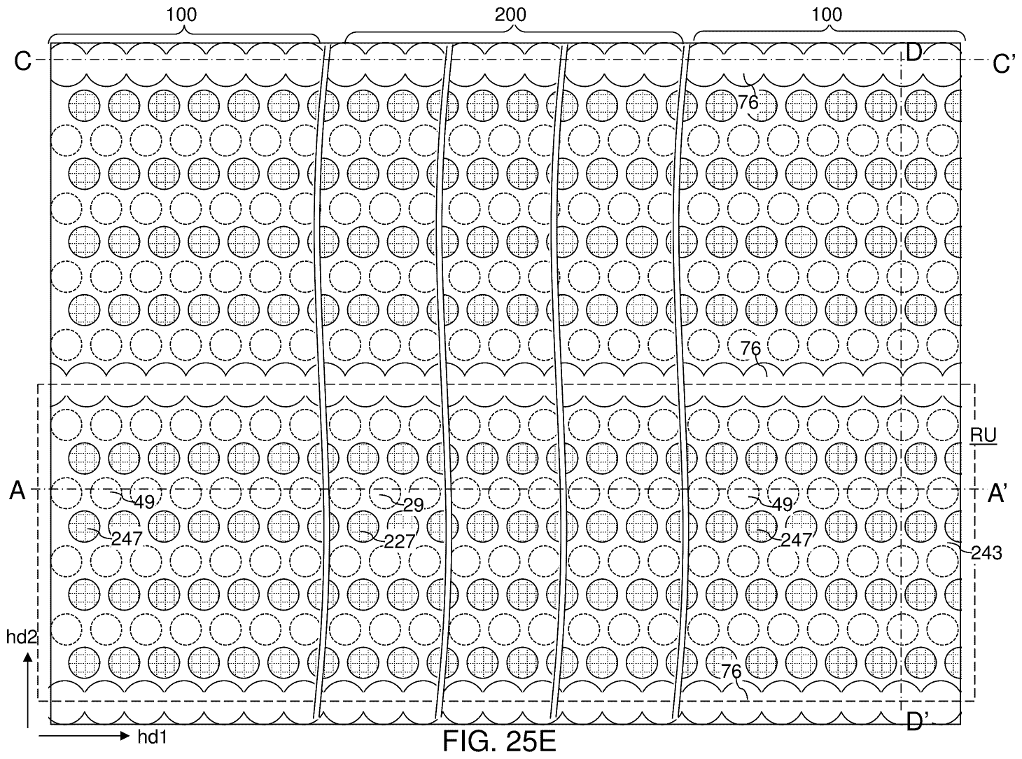

Referring to FIGS. 25A-25E, laterally-extending cavities (143, 243) can be formed by performing an isotropic etch process, as described above with respect to FIGS. 8A-8F. The isotropic etch process laterally recesses the sacrificial material layers (142, 242) from around the first cavities selective to materials of the insulating layers (132, 232) and the second subset of the sacrificial memory opening fill structures (147, 247). For example, an etchant that selectively etches the materials of the sacrificial material layers (142, 242) with respect to the materials of the insulating layers (132, 232), the finned dielectric wall structures 76, and the sacrificial memory opening fill structures (147, 247) can be introduced into the first cavities in the first subset of the memory openings 49, for example, employing the isotropic etch process. Laterally-extending cavities (143, 243) are formed in volumes from which the sacrificial material layers (142, 242) are removed. The laterally-extending cavities (143, 243) may comprise first laterally-extending cavities 143 that are formed in volumes from which the first sacrificial material layers 142 are removed, and second laterally-extending cavities 243 that are formed in volumes from which the second sacrificial material layers 242 are removed.

In one embodiment, the duration of the isotropic etch process are selected such that the entirety of the sacrificial material layers (142, 242) is removed by the isotropic etch process. The lateral extent of each of the laterally-extending cavities (143, 243) along the second horizontal direction hd2 in each repetition unit RU may be less than the periodicity of the repetition unit RU along the second horizontal direction hd2, and may be about the same as the periodicity of the repetition unit RU along the second horizontal direction hd2 less a minimum lateral dimension of a finned dielectric wall structure 76 along the second horizontal direction hd2. Each neighboring pair of laterally-extending cavities (143, 242) located between a vertically-neighboring pair of insulating layers (132, 232) among the insulating layers (132, 232) can be laterally spaced from each other by a respective one of the finned dielectric wall structures 76.

In one embodiment, each of the laterally-extending cavities (143, 243) laterally surrounds a respective cluster of memory openings 49, and does not laterally encircle any of the finned dielectric wall structures 76. The respective cluster of memory openings 49 comprise first memory openings that contain first cavities and second memory openings filled within vertical stacks of sacrificial memory opening fill structures (147, 247). In one embodiment, each of the finned dielectric wall structures 76 comprises vertically-straight and laterally-convex sidewall segments that are exposed to a respective laterally-extending cavity (143, 242).

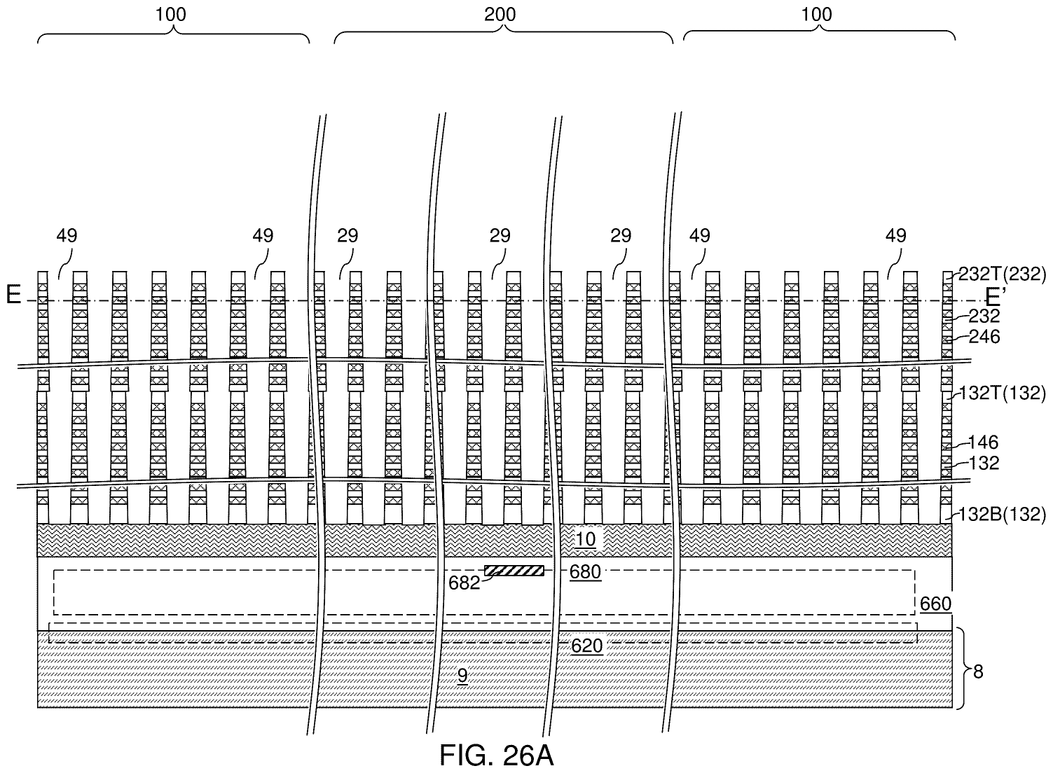

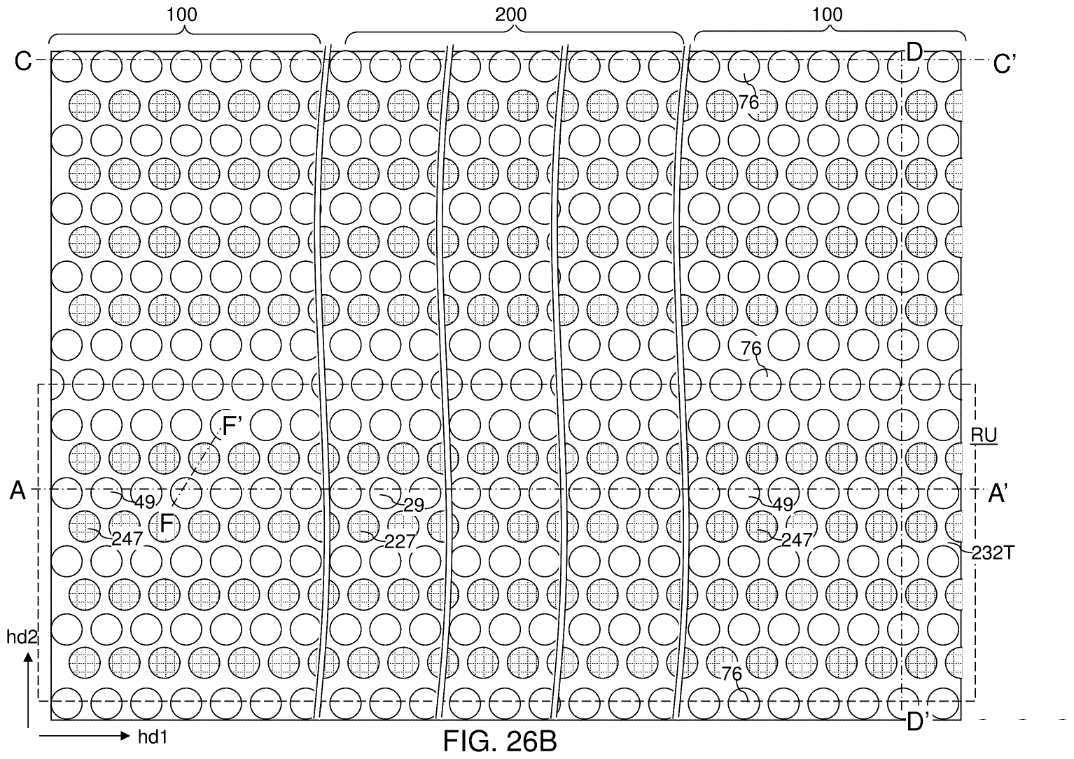

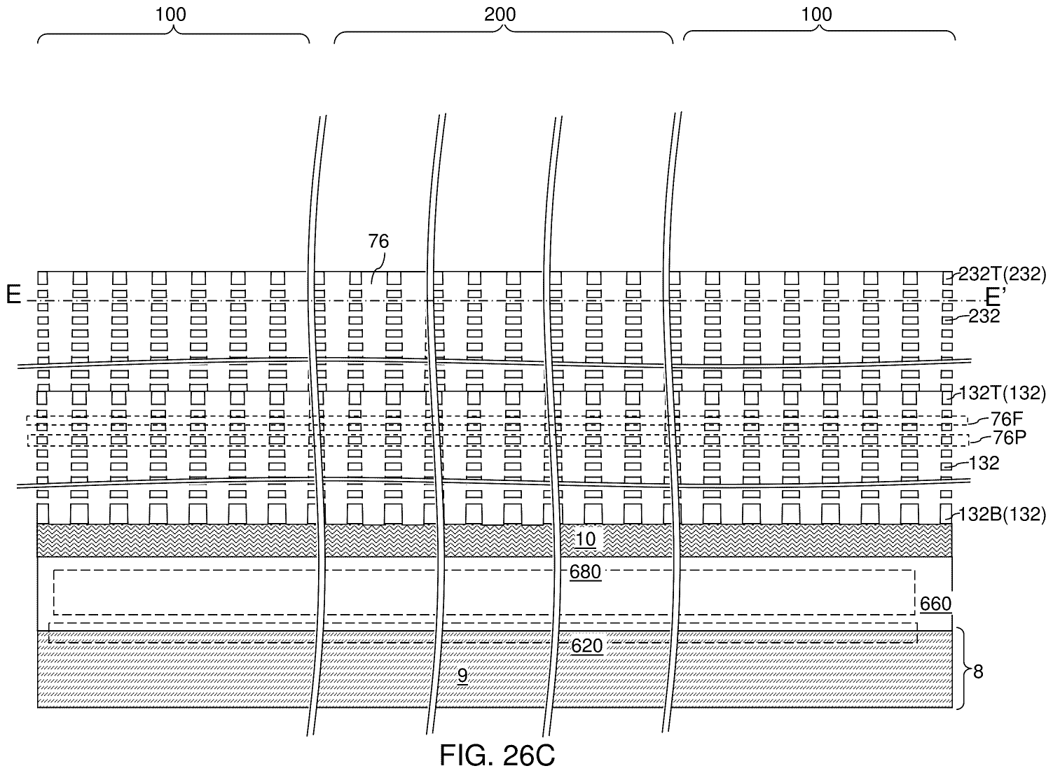

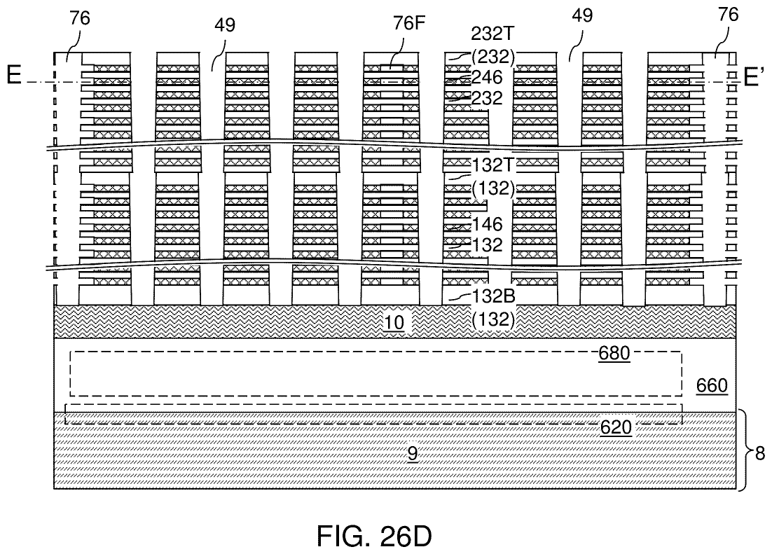

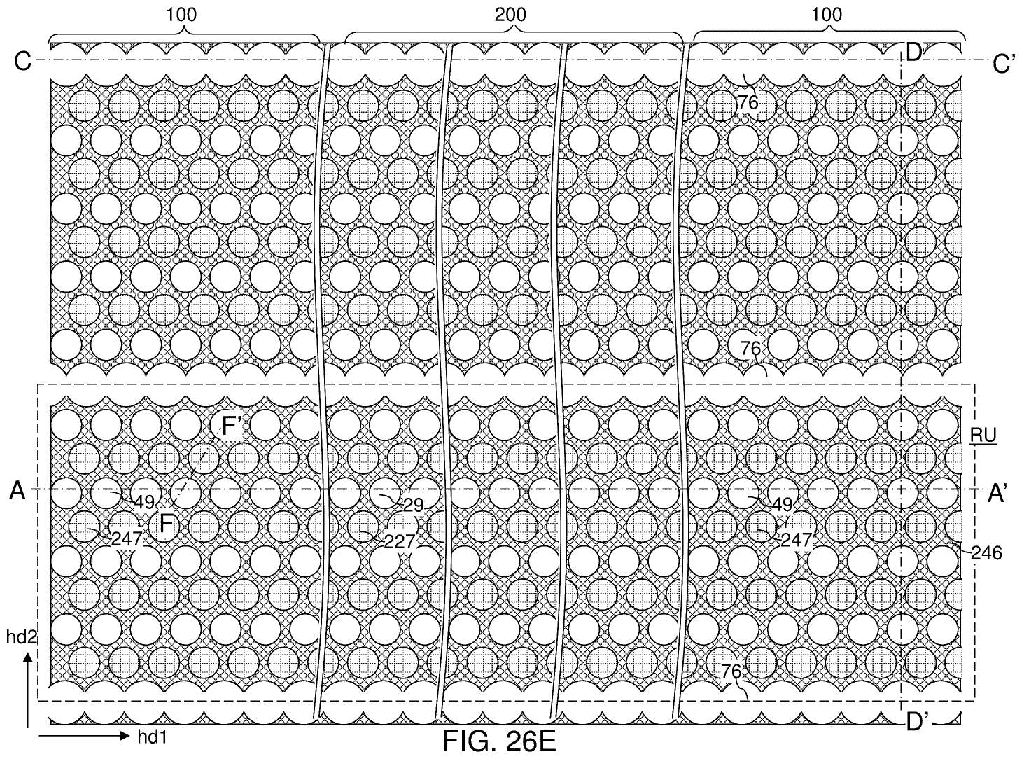

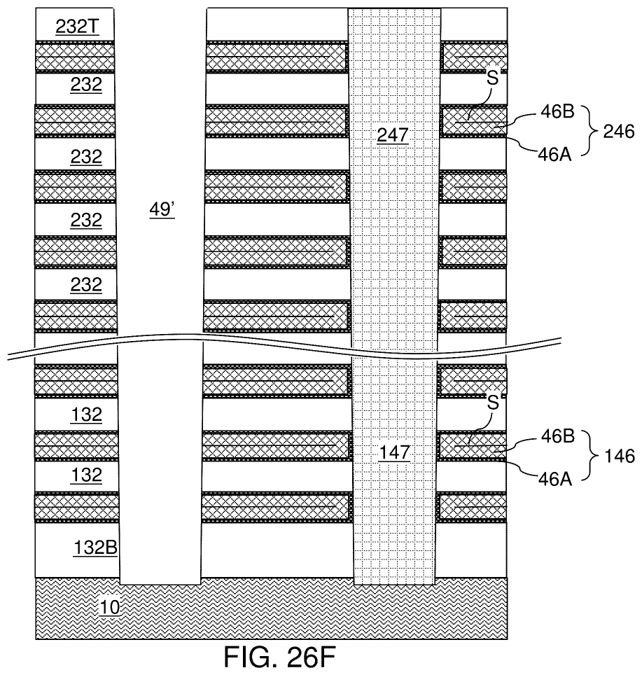

Referring to FIGS. 26A-26B, at least one conductive material such as at least one metallic material may be conformally deposited in the laterally-extending cavities (143, 243). The at least one conductive material may comprise, for example, a metallic barrier liner material (such as TiN, TaN, WN, MoN, TiC, TaC, WC, etc.) and a metallic fill material (such as W, Ti, Ta, Co, Ru, Mo, Cu, etc.). Portions of the at least one conductive material that are deposited in the first cavities in the first subset of the memory openings 49 or above the topmost second insulating layer 232T can be removed by a recess etch process, which may comprise an isotropic etch process and/or an anisotropic etch process. Each remaining portion of the at least one conductive material that fills a respective laterally-extending cavity (143, 243) constitutes an electrically conductive layer (146, 246). The electrically conductive layers (146, 246) comprise first electrically conductive layers 146 that replace the first sacrificial material layers 142, and second electrically conductive layers 246 that replace the second sacrificial material layers 242. Each of the electrically conductive layers (146, 246) may comprise a combination of a respective metallic barrier liner 46A and a respective metallic fill material portion 46B containing a respective seam S therein. Each metallic barrier liner 46A is a patterned portion of the metallic barrier liner material, and each metallic fill material portion 46B is a patterned portion of the metallic fill material.

In one embodiment, each of the electrically conductive layers (146, 246) comprises a respective laterally-extending seam S; the first cavities in a first subset of the memory openings 49 are in direct contact with a respective subset of the seams S of the electrically conductive layers (146, 246); and each vertical stack of sacrificial memory opening fill structures (147, 247) is not in direct contact with any seam S in the electrically conductive layers (146, 246).

The first cavities in the first subset of the memory openings 49 can be located within first rows of the memory openings 49 that laterally extend along the first horizontal direction hd1; the vertical stacks of sacrificial memory opening fill structures (147, 247) in the second subset of the memory openings 49 can be located within second rows of the memory openings 49 that laterally extend along the first horizontal direction hd1; and the first rows and the second rows are interlaced along a second horizontal direction hd2 that is perpendicular to the first horizontal direction hd1. In one embodiment, each vertical stack of sacrificial isolation opening fill structures (177, 277) is not in direct contact with any of the laterally-extending seams S.

The set of all electrically conductive layers (146 or 246) located at a same level (i.e., at a same vertical distance from the substrate 8) constitutes a conductive layer set (146, or 246). An alternating stack {(132, 146), (232, 246)} of insulating layers (132, 232) and conductive layer sets (146 or 246) can be formed over the substrate 8. Each of the conductive layer sets (146 or 246) comprises a respective plurality of electrically conductive layers (146, 246) that laterally extend along a first horizontal direction hd1 and spaced apart from each other along a second horizontal direction hd2. In one embodiment, each of the electrically conductive layers (146, 246) comprises a combination of a respective metallic barrier liner 46A and a respective metallic fill material portion 46B containing a respective one of the seams S. In one embodiment, each of finned dielectric wall structures 76 is not in direct contact with any of the laterally-extending seams S.

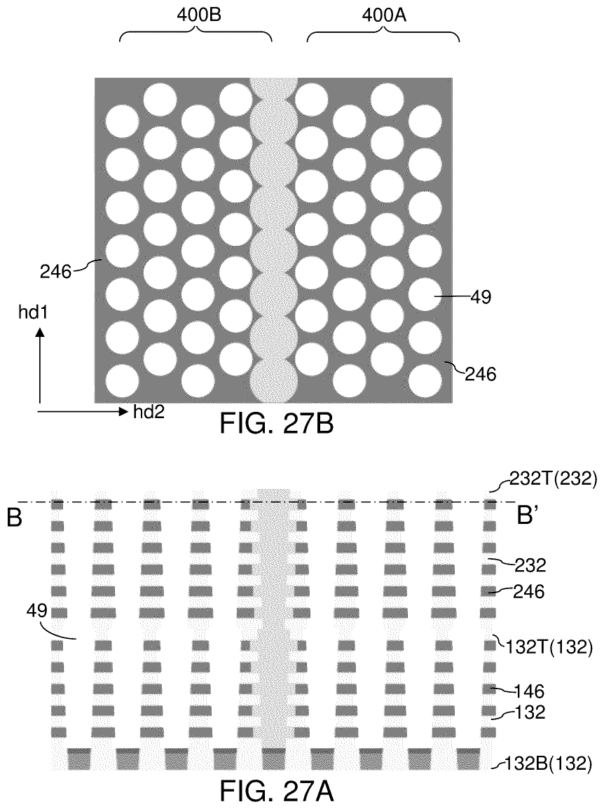

Referring to FIGS. 27A and 27B, the remaining vertical stacks of sacrificial isolation opening fill structures (177, 277) located in the second subset of the memory openings 49 and support openings 29 is selectively removed by selective etching or ashing, as described above with respect to FIG. 10, without removing the finned dielectric wall structures 76.

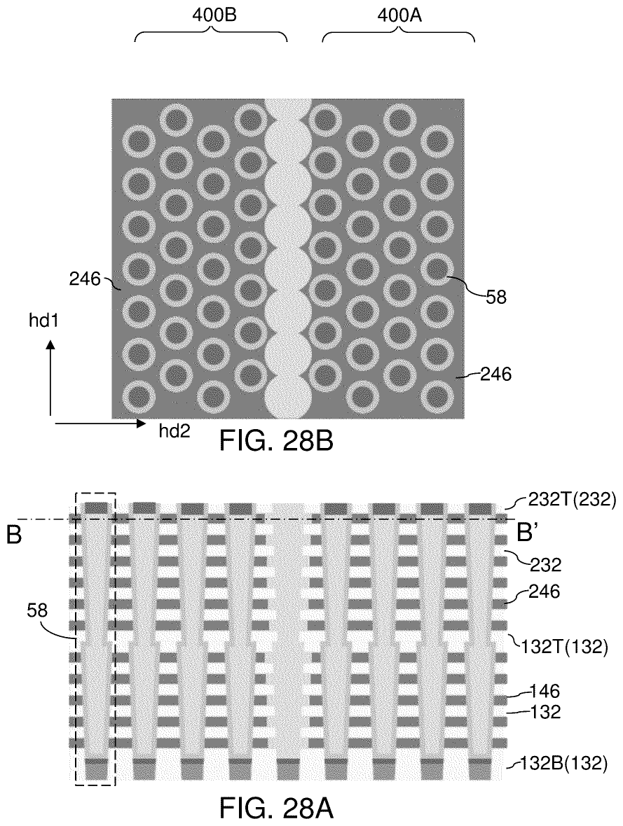

Referring to FIGS. 28A and 28B, the memory opening fill structures 58 and the support pillar structures 20 (not shown), as formed in the respective memory openings 49 and support openings, as described above with respect to FIGS. 11-16B.

Subsequently, the steps described above with respect to FIG. 17 may be performed to form various contact via structures and bit lines. Additional metal interconnect structures (not shown) embedded in additional dielectric material layers (not shown) can be formed. The additional metal interconnect structures may be referred to as upper-level metal interconnect structures or memory-side metal interconnect structures. Bonding pads (which may be referred to as memory-side bonding pads) may be formed at the topmost level of the dielectric material layers. Optionally, a logic die including a peripheral circuit configurated to control operation of the three-dimensional memory array in the first exemplary structure and logic-side bonding pads may be provided. In this case, the logic-side bonding pads may be bonded to the memory-side bonding pads, for example, by metal-to-metal bonding. In case the lower-level dielectric material layers 660 and the semiconductor material layer 10 are omitted, the substrate 8 may be removed to expose a bottom surface of the bottommost first insulating layer 132B, and a source layer can be formed on the bottom side of the alternating stack {(132, (146, 142S), (232, (246, 242S))}.

Referring to all figures and according to various embodiments of the present disclosure, a memory device comprises: an alternating stack {(132, (146, 142S), (232, (246, 242S)} of insulating layers (132, 232) and composite layers {(142S, 146), (242S, 246)}, wherein each of the composite layers {(142S, 146), (242S, 246)} comprises a respective laterally alternating sequence of electrically conductive layers (146, 246) and dielectric material strips {(142S, 242S), 76S}, wherein the dielectric material strips laterally extend along a first horizontal direction hd1; memory openings 49 vertically extending through the alternating stack; and memory opening fill structures 58 located in the respective memory openings 49, wherein each memory opening fill structure includes a respective vertical stack of memory elements (e.g., portions of the memory film 50) and a respective vertical semiconductor channel 60.

In one embodiment, each of the electrically conductive layers (146, 246) comprises a respective laterally-extending seam S; a first subset 58A of the memory opening fill structures 58 is in direct contact with a respective subset of the seams S of the electrically conductive layers (146, 246); and a second subset 58B of the memory opening fill structures 58 is not in direct contact with any of the seams S of the electrically conductive layers (146, 246).

In one embodiment, the first subset 58A of the memory opening fill structures 58 is located within first rows of the memory openings 49 that laterally extend along the first horizontal direction hd1; the second subset 58B of the memory opening fill structures 58 is located within second rows of the memory openings 49 that laterally extend along the first horizontal direction hd1; and the first rows and the second rows are interlaced along a second horizontal direction hd2 that is perpendicular to the first horizontal direction hd1.

In the first embodiment, a third subset of the memory openings 49 comprises isolation openings 79 which are adjoined to a vertical stack of a respective subset of the dielectric material strips (142S, 242S). A third subset 58C of the memory opening fill structures 58 located in the isolation openings 79 May comprise electrically-inactive memory opening fill structures.

In the first embodiment, a vertical stack of the dielectric material strips (142S, 242S) and insulating layers (132, 232) located between two neighboring rows of isolation openings 79 forms a dielectric wall 176 extending in the first horizontal direction hd1. The dielectric wall 176 is located between two adjacent memory blocks (400A, 400B) which are separated along a second horizontal direction hd2 which is perpendicular to the first horizontal direction hd1, and the dielectric wall 176 electrically isolates the two adjacent memory blocks from each other.

In the second embodiment, the memory device also comprises finned dielectric wall structures 76. In the second embodiment, each laterally neighboring pair of the electrically conductive layers (146, 246) is laterally spaced apart from each other along a second horizontal direction hd2 that is perpendicular to the first horizontal direction hd1 by a respective one of the finned dielectric wall structures 76. Adjacent memory blocks (400A, 400B) are laterally isolated from each other by the respective one of the finned dielectric wall structures 76.

In the second embodiment, each of the finned dielectric wall structures 76 comprises dielectric pillars 76P containing laterally protruding fins 76F that are separated from each other along a vertical direction. The dielectric material strips 76S are formed by the fins 76F of adjacent ones of the dielectric pillars 76P that laterally contact each other. Each of the dielectric material strips 76S comprises a respective row of vertically-straight and laterally-convex surface segments that are adjoined to each other and contact a set of vertically-straight and laterally-concave surface segments of a respective one of the electrically conductive layers (146, 246).

In one embodiment, each of the finned dielectric wall structures 76 continuously extends from a bottommost surface of the alternating stack {(132, 146), (232, 246)} to a topmost surface of the alternating stack {(132, 146), (232, 246)}. In one embodiment, each of finned dielectric wall structures 76 is not in direct contact with any of the laterally-extending seams S.

In one embodiment, each of the electrically conductive layers (146, 246) comprises a combination of a respective metallic barrier liner 46A and a respective metallic fill material portion 46B containing a respective one of the seams S; and an entirety of each interface between the electrically conductive layers (146, 246) and the second subset of the memory opening fill structures 58 consists of an interface between a respective one of the metallic barrier liners 46A and a respective memory opening fill structure 58 of the second subset of the memory opening fill structures 58.

In one embodiment, each interface between the electrically conductive layers (146, 246) and the first subset of the memory opening fill structures 58 comprises: an interface between a respective one of the metallic barrier liners 46A and a respective memory opening fill structure 58 of the first subset of the memory opening fill structures 58; and an interface between a respective one of the metallic fill material portions 46B and the respective memory opening fill structure 58 of the first subset of the memory opening fill structures 58.

The various embodiments of the present disclosure may be employed to provide lateral isolation structures (e.g., dielectric wall structures) that are self-aligned to boundaries of adjacent memory blocks in a three-dimensional memory device. The self-aligned isolation structures may include the dielectric material strips (142S, 242S), or may include the finned dielectric wall structures 76. In a non-limiting example, the methods and structures of the embodiments of the present disclosure may be employed to form a three-dimensional NAND device including self-aligned block isolation structures that provide electrical isolation between neighboring blocks within the three-dimensional NAND device. The embodiments of the present disclosure may also reduce the size of the memory device, while reducing the processing cost.

Although the foregoing refers to particular embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment using a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A memory device, comprising:
an alternating stack of insulating layers and composite layers, wherein each of the composite layers comprises a respective laterally alternating sequence of electrically conductive layers and dielectric material strips, wherein the dielectric material strips laterally extend along a first horizontal direction;
memory openings vertically extending through the alternating stack; and
memory opening fill structures located in the respective memory openings, wherein each memory opening fill structure includes a respective vertical stack of memory elements and a respective vertical semiconductor channel;
wherein:
each of the electrically conductive layers comprises a respective laterally-extending seam;
a first subset of the memory opening fill structures is in direct contact with a respective subset of the seams of the electrically conductive layers; and
a second subset of the memory opening fill structures is not in direct contact with any of the seams of the electrically conductive layers.

2. The memory device of claim 1, wherein:
the first subset of the memory opening fill structures is located within first rows of the memory openings that laterally extend along the first horizontal direction;
the second subset of the memory opening fill structures is located within second rows of the memory openings that laterally extend along the first horizontal direction; and
the first rows and the second rows are interlaced along a second horizontal direction that is perpendicular to the first horizontal direction.

3. The memory device of claim 1, wherein a subset of the memory openings comprises isolation openings which are adjoined to a vertical stack of a respective subset of the dielectric material strips.

4. The memory device of claim 3, wherein a third subset of the memory opening fill structures located in the isolation openings comprise electrically-inactive memory opening fill structures.

5. The memory device of claim 3, wherein a vertical stack of the dielectric material strips and insulating layers located between two neighboring rows of isolation openings forms a dielectric wall extending in the first horizontal direction.

6. The memory device of claim 5, wherein the dielectric wall is located between two adjacent memory blocks which are separated along a second horizontal direction which is perpendicular to the first horizontal direction.

7. The memory device of claim 6, wherein the dielectric wall electrically isolates the two adjacent memory blocks from each other.

8. The memory device of claim 2, further comprising finned dielectric wall structures.

9. The memory device of claim 8, wherein each laterally neighboring pair of the electrically conductive layers is laterally spaced apart from each other along a second horizontal direction that is perpendicular to the first horizontal direction by a respective one of the finned dielectric wall structures, and adjacent memory blocks are laterally isolated from each other by the respective one of the finned dielectric wall structures.

10. The memory device of claim 8, wherein:
each of the finned dielectric wall structures comprises dielectric pillars containing laterally protruding fins that are separated from each other along a vertical direction;
the dielectric material strips are formed by the fins of adjacent ones of the dielectric pillars that laterally contact each other; and
each of the dielectric material strips comprises a respective row of vertically-straight and laterally-convex surface segments that are adjoined to each other and contact a set of vertically-straight and laterally-concave surface segments of a respective one of the electrically conductive layers.

11. The memory device of claim 8, wherein:
each of the finned dielectric wall structures continuously extends from a bottommost surface of the alternating stack to a topmost surface of the alternating stack; and
each of finned dielectric wall structures is not in direct contact with any of the laterally-extending seams.

12. The memory device of claim 8, wherein:
each of the electrically conductive layers comprises a combination of a respective metallic barrier liner and a respective metallic fill material portion containing a respective one of the seams; and
an entirety of each interface between the electrically conductive layers and the second subset of the memory opening fill structures consists of an interface between a respective one of the metallic barrier liners and a respective memory opening fill structure of the second subset of the memory opening fill structures.

13. The memory device of claim 12, wherein each interface between the electrically conductive layers and the first subset of the memory opening fill structures comprises:
an interface between a respective one of the metallic barrier liners and a respective memory opening fill structure of the first subset of the memory opening fill structures; and
an interface between a respective one of the metallic fill material portions and the respective memory opening fill structure of the first subset of the memory opening fill structures.

14. A method of forming a three-dimensional memory device, comprising:
forming a vertically alternating sequence of insulating layers and sacrificial material layers over a substrate;
forming memory openings through the vertically alternating sequence, wherein the memory openings are arranged in rows of memory openings that laterally extend along a first horizontal direction;
forming sacrificial memory opening fill structures in the memory openings;
forming first cavities by removing a first subset of the sacrificial memory opening fill structures without removing a second subset of the sacrificial memory opening fill structures;
forming laterally-extending cavities by performing an isotropic etch process that laterally recesses the sacrificial material layers from around the first cavities selective to materials of the insulating layers and the second subset of the sacrificial memory opening fill structures;
forming electrically conductive layers in the laterally-extending cavities;
forming second cavities by removing the second subset of the sacrificial memory opening fill structures after forming the electrically conductive layers; and
forming memory opening fill structures in each of the first cavities and the second cavities, wherein each of the memory opening fill structures comprises a respective vertical stack of memory elements and a respective vertical semiconductor channel.

15. The method of claim 14, wherein:
each of the electrically conductive layers comprises a respective laterally-extending seam;
a first subset of the memory opening fill structures is in direct contact with a respective subset of the seams of the electrically conductive layers; and
a second subset of the memory opening fill structures is not in direct contact with any of the seams of the electrically conductive layers.

16. The method of claim 14, wherein:
the sacrificial material layers comprise a dielectric material;
a pattern of the first subset of the sacrificial memory opening fill structures and a duration of the isotropic etch process are selected such that remaining portions of the sacrificial material layers comprise dielectric material strips that laterally extend along the first horizontal direction and form a dielectric wall structure which laterally isolates adjacent memory blocks; and
each neighboring pair of laterally-extending cavities located between a vertically-neighboring pair of insulating layers of the insulating layers is laterally spaced from each other by a respective one of the dielectric material strips.

17. The method of claim 14, further comprising forming isolation openings through the vertically alternating sequence.

18. The method of claim 17, wherein:
the isolation openings are arranged in rows that laterally extend along a first horizontal direction;
the memory openings comprise clusters of memory openings, wherein each cluster of memory openings is located between respective neighboring sets of rows of the isolation openings; and
each of the laterally-extending cavities laterally surrounds a respective cluster of memory openings of the clusters of memory openings, and does not laterally encircle any of the isolation openings.

19. The method of claim 17, further comprising:
isotropically expanding the isolation openings at each level of the sacrificial material layers, wherein laterally-expanded portions of the isolation openings merge within each row of isolation openings to form a respective interconnected isolation cavity; and
forming finned dielectric wall structures in the interconnected isolation cavities, wherein each laterally neighboring pair of the electrically conductive layers is laterally spaced apart from each other along a second horizontal direction by a respective one of the finned dielectric wall structures, and adjacent memory blocks are laterally isolated from each other by the respective one of the finned dielectric wall structures.

20. The method of claim 19, wherein:
each of the finned dielectric wall structures comprises dielectric pillars containing laterally protruding fins that are separated from each other along a vertical direction;
the fins of adjacent dielectric pillars laterally contact each other to form dielectric material strips; and
each of the dielectric material strips comprises a respective row of vertically-straight and laterally-convex surface segments that are adjoined to each other and contact a set of vertically-straight and laterally-concave surface segments of a respective one of the electrically conductive layers.
